(19) United States
(12) Patent Application Publication
(10) Pub. No.: US 2023/0337462 A1
(43) Pub. Date: Oct. 19, 2023

(54) LIGHT-EMITTING DEVICE, FUNCTIONAL PANEL, LIGHT-EMITTING APPARATUS, DISPLAY DEVICE, ELECTRONIC DEVICE, AND LIGHTING DEVICE

(71) Applicant: Semiconductor Energy Laboratory Co., Ltd., Atsugi-shi, Kanagawa-ken (JP)

(72) Inventors: Airi UEDA, Zama (JP); Takeyoshi WATABE, Atsugi (JP); Yuta KAWANO, Yokohama (JP); Nobuharu OHSAWA, Zama (JP); Satoshi SEO, Sagamihara (JP)

(21) Appl. No.: 17/928,659

(22) PCT Filed: Jun. 15, 2021
(86) PCT No.: PCT/IB2021/055241

§ 371 Date: Nov. 30, 2022

(30) Foreign Application Priority Data
Jun. 26, 2020 (JP) 2020-110345

(51) Int. Cl. H10K 50/858; H10K 50/16; H10K 50/15

(52) U.S. Cl. CPC H10K 50/858; H10K 50/166; H10K 50/156; H10K 2101/30

(57) ABSTRACT

A novel light-emitting device that is highly convenient, useful, or reliable is provided. The light-emitting device includes a first electrode, a second electrode, a unit, and a first layer. The unit is positioned between the first electrode and the second electrode and includes a second layer, a third layer, and a fourth layer. The second layer is positioned between the third layer and the fourth layer and contains a light-emitting material. The third layer is positioned between the second layer and the second electrode, is in contact with the second layer, and contains a first material, and an organometallic complex of an alkali metal or an organometallic complex of an alkaline earth metal. The fourth layer is positioned between the first electrode and the second layer and contains a second material. The first layer is positioned between the first electrode and the unit and contains a second material and a material having an electron acceptor property. The second material has a first refractive index. The first refractive index is higher than or equal to 1.5 and lower than or equal to 1.75 in a wavelength range of 455 nm to 465 nm inclusive. The second material has a HOMO level. The HOMO level is higher than or equal to −5.7 eV and lower than or equal to −5.3 eV.

### TECHNICAL FIELD

One embodiment of the present invention relates to a light-emitting device, a functional panel, a light-emitting apparatus, a display device, an electronic device, or a lighting device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include a semiconductor device, a display device, a light-emitting apparatus, a power storage device, a memory device, a driving method thereof, and a manufacturing method thereof.

### BACKGROUND ART

Light-emitting devices (organic EL devices) including organic compounds and utilizing electroluminescence (EL) have been put into practical use. In the basic structure of such light-emitting devices, an organic compound layer containing a light-emitting material (an EL layer) is located between a pair of electrodes. Carriers (holes and electrons) are injected by application of voltage to the element, and recombination energy of the carriers is used, whereby light emission can be obtained from the light-emitting material.

Such light-emitting devices are of self-light-emitting type and thus have advantages over liquid crystal, such as high visibility and no need for backlight when used for pixels of a display, and are suitable as flat panel display elements. Displays using such light-emitting devices are also highly advantageous in that they can be fabricated to be thin and lightweight. Moreover, an extremely fast response speed is also a feature.

Since light-emitting layers of such light-emitting devices can be successively formed two-dimensionally, planar light emission can be achieved. This feature is difficult to realize with point light sources typified by incandescent lamps and light-emitting diodes or linear light sources typified by fluorescent lamps; thus, the light-emitting devices also have great potential as planar light sources, which can be applied to lighting and the like.

Displays or lighting devices using light-emitting devices can be suitably used for a variety of electronic devices as described above, and research and development of light-emitting devices have progressed for more favorable characteristics.

One of the problems often discussed in talking about an organic EL element is outcoupling efficiency being low. In particular, the attenuation due to reflection which is caused by a difference in refractive index between adjacent layers is a main cause of a reduction in element efficiency. In order to reduce this effect, a structure in which a layer formed of a low refractive index material is formed in an EL layer (see Non-Patent Document 1, for example) has been proposed.

Although a light-emitting device having this structure can have higher outcoupling efficiency, and thus higher external quantum efficiency than a light-emitting device having a conventional structure, it is not easy to form such a layer with a low refractive index inside an EL layer without adversely affecting other critical characteristics of the light-emitting device. This is because a low refractive index and a high carrier-transport property or reliability when the material is used for a light-emitting device have a trade-off relation. This is because the carrier-transport property and reliability of an organic compound largely depend on an unsaturated bond, and an organic compound having many unsaturated bonds tends to have a high refractive index.

### REFERENCE

### Patent Document

[Patent Document 1] Japanese Published Patent Application No. H11-282181
[Patent Document 2] Japanese Published Patent Application No. 2009-91304
[Patent Document 3] United States Patent Application Publication No. 2010/104969

### Non-Patent Document

[Non-Patent Document 1] Jaeho Lee and 12 others, “Synergetic electrode architecture for efficient graphene-based flexible organic light-emitting diodes”, nature COMMUNICATIONS, Jun. 2, 2016, DOI: 10.1038/ncomms 11791.

### SUMMARY OF THE INVENTION

### Problems to be Solved by the Invention

An object of one embodiment of the present invention is to provide a novel light-emitting device that is highly convenient, useful, or reliable. Another object is to provide a novel functional panel that is highly convenient, useful, or reliable. Another object is to provide a novel light-emitting apparatus that is highly convenient, useful, or reliable. Another object is to provide a novel display device that is highly convenient, useful, or reliable. Another object is to provide a novel electronic device that is highly convenient, useful, or reliable. Another object is to provide a novel lighting device that is highly convenient, useful, or reliable. Another object is to provide a novel light-emitting device, a novel functional panel, a novel light-emitting apparatus, a novel display device, a novel electronic device, or a novel lighting device.

Note that the description of these objects does not preclude the existence of other objects. One embodiment of the present invention does not have to achieve all these objects. Other objects will be apparent from the description of the specification, the drawings, the claims, and the like, and other objects can be derived from the description of the specification, the drawings, the claims, and the like.

### Means for Solving the Problems

(1) One embodiment of the present invention is a light-emitting device including a first electrode, a second electrode, a first unit, and a first layer.

The second electrode includes a region overlapping with the first electrode, the first unit includes a region positioned between the first electrode and the second electrode, and the first unit includes a second layer, a third layer, and a fourth layer.

The second layer includes a region positioned between the third layer and the fourth layer, and the second layer contains a light-emitting material. Note that in the description of this specification, “one layered structure includes a region positioned between two other layered structures” can be rephrased as “the one layered structure is positioned between the two other layered structures”.

The third layer includes a region positioned between the second layer and the second electrode, the third layer is in contact with the second layer, and the third layer contains a first material, and an organometallic complex of an alkali metal or an organometallic complex of an alkaline earth metal.

The fourth layer includes a region positioned between the first electrode and the second layer, and the fourth layer contains a second material HT1.

The first layer includes a region positioned between the first electrode and the first unit, and the first layer contains the second material HT1 and a material AM having an electron acceptor property.

The second material HT1 has a refractive index n1, and the refractive index n1 is higher than or equal to 1.5 and lower than or equal to 1.75 in the wavelength range of 455 nm to 465 nm inclusive.

A first HOMO level of the second material HT1 is higher than or equal to −5.7 eV and lower than or equal to −5.3 eV.

(2) One embodiment of the present invention is the above light-emitting device in which the fourth layer includes a first region and a second region.

The first region contains the second material HT1, the second region includes a portion positioned between the second layer and the first region, and the second region contains a third material HT2.

The third material HT2 has a second HOMO level, and the second HOMO level differs from the first HOMO level by −0.2 eV to 0 eV inclusive.

(3) One embodiment of the present invention is the above light-emitting device in which the first material has a refractive index n2. Note that the refractive index n2 is higher than or equal to 1.5 and lower than or equal to 1.75 in the wavelength range of 455 nm to 465 nm inclusive.

Accordingly, light emission efficiency can be increased. Alternatively, reliability as well as efficiency can be improved. Consequently, a novel light-emitting device that is highly convenient, useful, or reliable can be provided.

(4) One embodiment of the present invention is a light-emitting device including a first electrode, a second electrode, and a first unit.

The second electrode includes a region overlapping with the first electrode, the first unit includes a region positioned between the first electrode and the second electrode, and the first unit includes a first layer, a second layer, and a third layer.

The first layer includes a region positioned between the second layer and the third layer, and the first layer contains a light-emitting material.

The third layer includes a region positioned between the first layer and the second electrode, the third layer is in contact with the first layer, and the third layer includes a first material, and an organometallic complex of an alkali metal or an organometallic complex of an alkaline earth metal.

The first material has a refractive index n2, and the refractive index n2 is higher than or equal to 1.5 and lower than or equal to 1.75 in the wavelength range of 455 nm to 465 nm inclusive.

(5) One embodiment of the present invention is the above light-emitting device in which the first material has an electron mobility higher than or equal to 1×10⁻⁷ cm²/Vs and lower than or equal to 5×10⁻⁵ cm²/Vs when the square root of the electric field strength [V/cm] is 600.

Accordingly, light emission efficiency can be increased. Alternatively, reliability as well as efficiency can be improved. Consequently, a novel light-emitting device that is highly convenient, useful, or reliable can be provided.

(6) One embodiment of the present invention is a light-emitting device including a second unit and an intermediate layer.

The second unit includes a region positioned between the intermediate layer and the second electrode.

The intermediate layer includes a region positioned between the first unit and the second unit. The intermediate layer has a function of supplying holes to one of the first unit and the second unit and supplying electrons to the other.

(7) One embodiment of the present invention is a functional panel including a functional layer and a pixel.

The functional layer includes a pixel circuit, and the pixel includes the pixel circuit and the above light-emitting device.

The first electrode includes a region positioned between the functional layer and the second electrode, and the first electrode is electrically connected to the pixel circuit.

Thus, light emission of the light-emitting device can be controlled using the pixel circuit. Alternatively, image data can be displayed. As a result, a novel functional panel that is highly convenient, useful, or reliable can be provided.

(8) One embodiment of the present invention is the above functional panel in which the first electrode has a first transmittance, the second electrode has a second transmittance, and the second transmittance is higher than the first transmittance.

Thus, light emitted from the light-emitting device can be extracted without through the functional layer. Alternatively, light emitted from the light-emitting device can be extracted efficiently without being blocked.

(9) One embodiment of the present invention is the above functional panel in which the first electrode has a first transmittance, the second electrode has a second transmittance, and the second transmittance is lower than the first transmittance.

(10) One embodiment of the present invention is a light-emitting apparatus including the above light-emitting device, and a transistor or a substrate.

(11) One embodiment of the present invention is a display device including the above light-emitting device, and a transistor or a substrate.

(12) One embodiment of the present invention is a lighting device including the above light-emitting apparatus and a housing.

(13) One embodiment of the present invention is an electronic device including the above display device, and a sensor, an operation button, a speaker, or a microphone.

Although a block diagram in which components are classified by their functions and shown as independent blocks is shown in the drawing attached to this specification, it is difficult to completely separate actual components according to their functions and one component can relate to a plurality of functions.

Note that the light-emitting apparatus in this specification includes an image display device using a light-emitting element. Moreover, the light-emitting apparatus may also include a module in which a connector such as an anisotropic conductive film or a TCP (Tape Carrier Package) is connected to a light-emitting element, a module in which a printed wiring board is provided on the tip of a TCP, or a module in which an IC (integrated circuit) is directly mounted on a light-emitting element by a COG (Chip On Glass) method. Furthermore, in some cases, lighting equipment or the like includes the light-emitting apparatus.

### Effect of the Invention

According to one embodiment of the present invention, a novel light-emitting device that is highly convenient, useful, or reliable can be provided. Alternatively, a novel functional panel that is highly convenient, useful, or reliable can be provided. Alternatively, a novel light-emitting apparatus that is highly convenient, useful, or reliable can be provided. Alternatively, a novel display device that is highly convenient, useful, or reliable can be provided. Alternatively, a novel electronic device that is highly convenient, useful, or reliable can be provided. Alternatively, a novel lighting device that is highly convenient, useful, or reliable can be provided. Alternatively, a novel light-emitting device, a novel functional panel, a novel light-emitting apparatus, a novel display device, a novel electronic device, or a novel lighting device can be provided.

Note that the description of these effects does not preclude the existence of other effects. One embodiment of the present invention does not need to have all the effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A and FIG. 1B are diagrams illustrating a structure of a light-emitting device of an embodiment.

FIG. 2A and FIG. 2B are diagrams each illustrating a structure of a light-emitting device of an embodiment.

FIG. 3A and FIG. 3B are diagrams illustrating a structure of a functional panel of an embodiment.

FIG. 4A to FIG. 4C are diagrams illustrating a structure of a functional panel of an embodiment.

FIG. 5 is a circuit diagram illustrating a structure of a functional panel of an embodiment.

FIG. 6 is a cross-sectional view illustrating a structure of a functional panel of an embodiment.

FIG. 7A and FIG. 7B are cross-sectional views illustrating a structure of a functional panel of an embodiment.

FIG. 8A and FIG. 8B are cross-sectional views illustrating a structure of a functional panel of an embodiment.

FIG. 9A and FIG. 9B are cross-sectional views illustrating a structure of a functional panel of an embodiment.

FIG. 10A is a top view of an active matrix light-emitting apparatus, and FIG. 10B is a cross-sectional view.

FIG. 11A and FIG. 11B are cross-sectional views of active matrix light-emitting apparatuses.

FIG. 12 is a cross-sectional view of an active matrix light-emitting apparatus.

FIG. 13A is a perspective view of a passive matrix light-emitting apparatus, and FIG. 13B is a cross-sectional view.

FIG. 14A is a cross-sectional view of a lighting device, and FIG. 14AB is a top view.

FIG. 15A, FIG. 15B1, FIG. 15B2, and FIG. 15C are diagrams illustrating electronic devices.

FIG. 16A to FIG. 16C are diagrams illustrating electronic devices.

FIG. 17 is a diagram illustrating a lighting device.

FIG. 18 is a diagram illustrating a lighting device.

FIG. 19 is a diagram illustrating in-vehicle display devices and lighting devices.

FIG. 20A to FIG. 20C are diagrams illustrating an electronic device.

FIG. 21A to FIG. 21C are diagrams illustrating structures of light-emitting devices of examples.

FIG. 22 is a graph showing wavelength-refractive index characteristics of materials of examples.

FIG. 23 is a graph showing current density-luminance characteristics of light-emitting devices of an example.

FIG. 24 is a graph showing luminance-current efficiency characteristics of light-emitting devices of an example.

FIG. 25 is a graph showing voltage-luminance characteristics of light-emitting devices of an example.

FIG. 26 is a graph showing voltage-current characteristics of light-emitting devices of an example.

FIG. 27 is a graph showing luminance-blue index characteristics of light-emitting devices of an example.

FIG. 28 is a graph showing emission spectra of light-emitting devices of an example.

FIG. 29 is a graph showing normalized luminance-temporal change characteristics of light-emitting devices of an example.

FIG. 30 is a graph showing current density-luminance characteristics of light-emitting devices of an example.

FIG. 31 is a graph showing luminance-current efficiency characteristics of light-emitting devices of an example.

FIG. 32 is a graph showing voltage-luminance characteristics of light-emitting devices of an example.

FIG. 33 is a graph showing voltage-current characteristics of light-emitting devices of an example.

FIG. 34 is a graph showing luminance-external quantum efficiency characteristics of light-emitting devices of an example.

FIG. 35 is a graph showing emission spectra of light-emitting devices of an example.

FIG. 36 is a graph showing normalized luminance-temporal change characteristics of light-emitting devices of an example.

### MODE FOR CARRYING OUT THE INVENTION

A light-emitting device of one embodiment of the present invention includes a first electrode, a second electrode, a unit, and a first layer. The unit is positioned between the first electrode and the second electrode, and the unit includes a second layer, a third layer, and a fourth layer. The second layer is positioned between the third layer and the fourth layer, and the second layer contains a light-emitting material. The third layer is positioned between the second layer and the second electrode, the third layer is in contact with the second layer, and the third layer contains a first material, and an organometallic complex of an alkali metal or an organometallic complex of an alkaline earth metal. The fourth layer is positioned between the first electrode and the second layer, and the fourth layer contains a second material. The first layer is positioned between the first electrode and the unit, and the first layer contains the second material and a material having an electron acceptor property. The second material has a first refractive index, and the first refractive index is higher than or equal to 1.5 and lower than or equal to 1.75 in the wavelength range of 455 nm to 465 nm inclusive. The second material has a HOMO level, and the HOMO level is higher than or equal to −5.7 eV and lower than or equal to −5.3 eV.

Accordingly, light emission efficiency can be increased. Alternatively, reliability as well as efficiency can be improved. Consequently, a novel light-emitting device that is highly convenient, useful, or reliable can be provided.

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments. Note that in structures of the invention described below, the same portions or portions having similar functions are denoted by the same reference numerals in different drawings, and a description thereof is not repeated.

### Embodiment 1

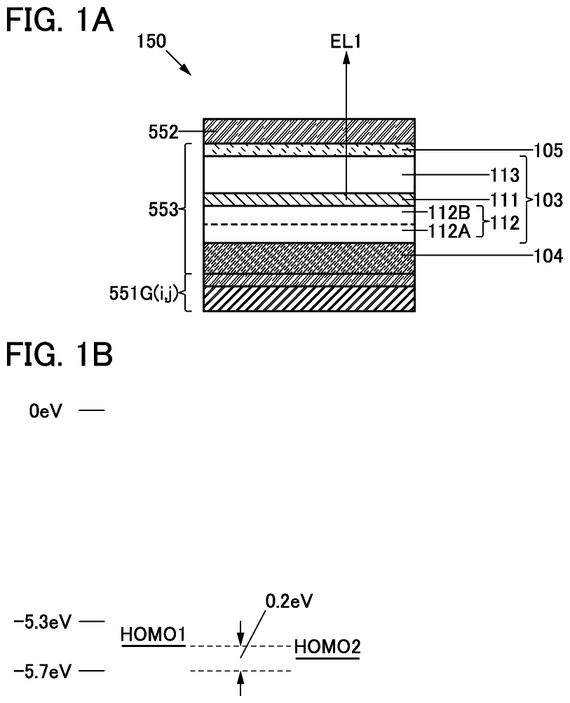

In this embodiment, a structure of a light-emitting device 150 of one embodiment of the present invention is described with reference to FIG. 1.

FIG. 1A is a diagram illustrating the structure of the light-emitting device of one embodiment of the present invention, and FIG. 1B is a diagram illustrating part of the structure in FIG. 1A.

### Structure Example 1 of Light-Emitting Device 150

The light-emitting device 150 described in this embodiment includes an electrode 551G(i,j), an electrode 552, and an EL layer 553 (see FIG. 1A). The electrode 552 includes a region overlapping with the electrode 551G(i,j). The EL layer 553 includes a unit 103.

### Structure Example of Unit 103

The unit 103 includes a region positioned between the electrode 551G(i,j) and the electrode 552. The unit 103 includes a layer 111, a layer 112, and a layer 113.

### Structure Example of Layer 111

The layer 111 includes a region positioned between the layer 112 and the layer 113, and the layer 111 contains a light-emitting material. The layer 111 contains the light-emitting material and a host material. The layer 111 can be referred to as a light-emitting layer.

The layer 111 is preferably provided in a region where holes and electrons are recombined. This allows efficient conversion of energy generated by recombination of carriers into light and emission of the light. Furthermore, the layer 111 is preferably provided apart from a metal used for the electrode or the like. In that case, a quenching phenomenon caused by the metal used for the electrode or the like can be inhibited.

For example, a fluorescent substance, a phosphorescent substance, or a substance exhibiting thermally activated delayed fluorescence (TADF) (also referred to as a TADF material) can be used as the light-emitting material. Thus, energy generated by recombination of carriers can be released as light EL1 from the light-emitting material.

### Structure Example 1 of Layer 113

The layer 113 includes a region positioned between the layer 111 and the electrode 552, the layer 113 is in contact with the layer 111, and the layer 113 contains a material ET, and an organometallic complex of an alkali metal or an organometallic complex of an alkaline earth metal.

A material having an electron-transport property, a material having an anthracene skeleton, a mixed material, or the like can be used as the material ET, for example. The layer 113 can be referred to as an electron-transport layer. A material having a wider band gap than the light-emitting material contained in the layer 111 is preferably used for the layer 113. Thus, energy transfer from excitons generated in the layer 111 to the layer 113 can be inhibited.

### Structure Example 1 of Layer 112

The layer 112 includes a region positioned between the electrode 551G(i,j) and the layer 111, and the layer 112 contains a material HT1.

A material having a hole-transport property can be used for the layer 112. The layer 112 can be referred to as a hole-transport layer. A material having a wider band gap than the light-emitting material contained in the layer 111 is preferably used for the layer 112. Thus, energy transfer from excitons generated in the layer 111 to the layer 112 can be inhibited.

The material HT1 has a refractive index n1, and the refractive index n1 is higher than or equal to 1.5 and lower than or equal to 1.75 in the wavelength range of 455 nm to 465 nm inclusive. Alternatively, the refractive index n1 is higher than or equal to 1.45 and lower than or equal to 1.70 at 633 nm.

For example, as the material HT1, a material which has a hole-transport property and an ordinary refractive index higher than or equal to 1.50 and lower than or equal to 1.75 in a blue light emission range (e.g., 455 nm to 465 nm) or an ordinary refractive index higher than or equal to 1.45 and lower than or equal to 1.70 with respect to 633-nm light, which is usually used for measurement of refractive indices, can be used.

In the case where the material has anisotropy, the refractive index with respect to an ordinary ray might differ from the refractive index with respect to an extraordinary ray. When a thin film to be measured is in such a state, anisotropy analysis can be performed to separately calculate the ordinary refractive index and the extraordinary refractive index. In this specification, when the measured material has both the ordinary refractive index and the extraordinary refractive index, the ordinary refractive index is used as an indicator.

### [Material Having Hole-Transport Property]

An example of the material having a hole-transport property is a monoamine compound including a first aromatic group, a second aromatic group, and a third aromatic group, in which the first aromatic group, the second aromatic group, and the third aromatic group are bonded to the same nitrogen atom.

In the monoamine compound, the proportion of carbon atoms each forming a bond by the sp3 hybrid orbitals in total carbon atoms in the molecule is preferably higher than or equal to 23% and lower than or equal to 55%. In addition, it is preferable that the integral value of signals at lower than 4 ppm exceed the integral value of signals at 4 ppm or higher in the results of ¹H-NMR measurement conducted on the monoamine compound.

The monoamine compound preferably has at least one fluorene skeleton. Any one or more of the first aromatic group, the second aromatic group, and the third aromatic group are preferably a fluorene skeleton.

Examples of the above-described material having a hole-transport property include organic compounds having structures represented by General Formulae (Gₕ₁1) to (Gₕ₁4) below.

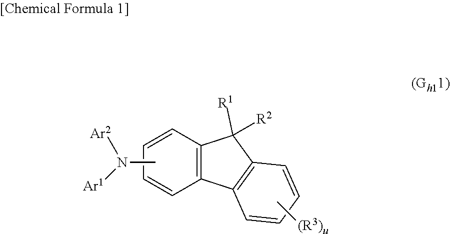

In General Formula (Gₕ₁1) above, Ar¹ and Ar² each independently represent a substituent with a benzene ring or a substituent in which two or three benzene rings are bonded to each other. Note that one or both of Ar¹ and Ar² have one or more hydrocarbon groups each having 1 to 12 carbon atoms each forming a bond only by the sp3 hybrid orbitals. The total number of carbon atoms contained in all of the hydrocarbon groups bonded to Ar¹ and Ar² is 8 or more and the total number of carbon atoms contained in all of the hydrocarbon groups bonded to Ar¹ or Ar² is 6 or more. Note that in the case where a plurality of straight-chain alkyl groups each having one or two carbon atoms are bonded to Ar¹ or Ar² as the hydrocarbon groups, the straight-chain alkyl groups may be bonded to each other to form a ring.

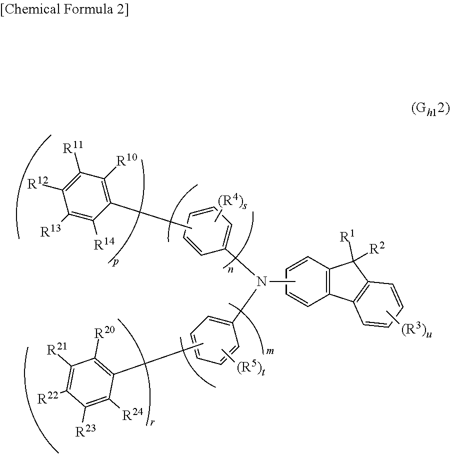

In General Formula (Gₕ₁2) above, m and r each independently represent 1 or 2 and m+r is 2 or 3. Furthermore, t represents an integer of 0 to 4 and is preferably 0. Moreover, R⁵ represents hydrogen or a hydrocarbon group having 1 to 3 carbon atoms. When m is 2, the kind of substituents, the number of substituents, and the position of bonds in one phenylene group may be the same as or different from those in the other phenylene group; and when r is 2, the kind of substituents, the number of substituents, and the position of bonds in one phenyl group may be the same as or different from those in the other phenyl group. In the case where t is an integer of 2 to 4, R⁵s may be the same or different from each other; and adjacent R⁵s may be bonded to each other to form a ring.

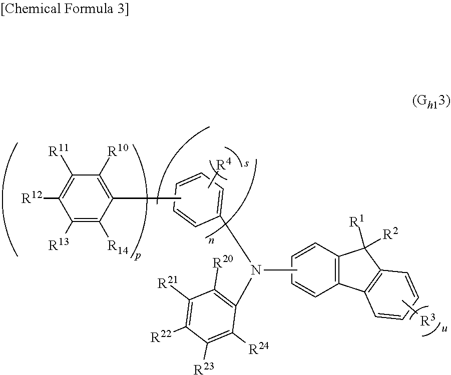

In General Formulae (Gₕ₁2) and (Gₕ₁3) above, n and p each independently represent 1 or 2 and n+p is 2 or 3. In addition, s represents an integer of 0 to 4 and is preferably 0. Moreover, R⁴ represents hydrogen or a hydrocarbon group having 1 to 3 carbon atoms. When n is 2, the kind of substituents, the number of substituents, and the position of bonds in one phenylene group may be the same as or different from those in the other phenylene group; and when p is 2, the kind of substituents, the number of substituents, and the position of bonds in one phenyl group may be the same as or different from those in the other phenyl group. In the case where s is an integer of 2 to 4, R⁴s may be the same or different from each other.

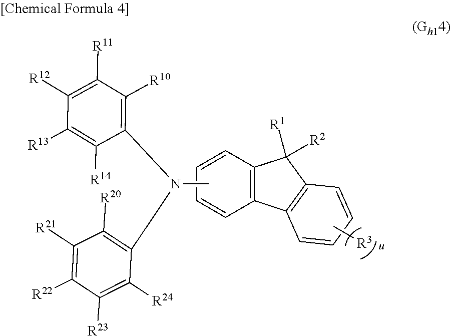

In General Formulae (Gₕ₁2) to (Gₕ₁4) above, R¹⁰ to R¹⁴ and R²⁰ to R²⁴ each independently represent hydrogen or a hydrocarbon group having 1 to 12 carbon atoms each forming a bond only by the sp3 hybrid orbitals. Note that at least three of R¹⁰ to R¹⁴ and at least three of R²⁰ to R²⁴ are preferably hydrogen. As the hydrocarbon group having 1 to 12 carbon atoms each forming a bond only by the sp3 hybrid orbitals, a tert-butyl group and a cyclohexyl group are preferable. Thus, the refractive index of a film containing the organic compound can be lowered. The total number of carbon atoms contained in R¹⁰ to R¹⁴ and R²⁰ to R²⁴ is 8 or more and the total number of carbon atoms contained in either R¹⁰ to R¹⁴ or R²⁰ to R²⁴ is 6 or more. Note that adjacent groups of R⁴, R¹⁰ to R¹⁴, and R²⁰ to R²⁴ may be bonded to each other to form a ring.

In General Formulae (Gₕ₁1) to (Gₕ₁4) above, u represents an integer of 0 to 4 and is preferably 0. Note that in the case where u is an integer of 2 to 4, R³s may be the same or different from each other. In addition, R¹, R², and R³ each independently represent an alkyl group having 1 to 4 carbon atoms and R¹ and R² may be bonded to each other to form a ring.

An arylamine compound that has at least one aromatic group having first to third benzene rings and at least three alkyl groups is preferable as one of the materials having a hole-transport property. Note that the first to third benzene rings are bonded in this order and the first benzene ring is directly bonded to nitrogen of amine.

The first benzene ring may further include a substituted or unsubstituted phenyl group and preferably includes an unsubstituted phenyl group. Furthermore, the second benzene ring or the third benzene ring may include a phenyl group substituted by an alkyl group.

Note that hydrogen is not directly bonded to carbon atoms at 1-posirion and 3-position in two or more of, preferably all of the first to third benzene rings, and the carbon atoms are bonded to any of the first to third benzene rings, the phenyl group substituted by the alkyl group, the at least three alkyl groups, and the nitrogen of the amine.

It is preferable that the arylamine compound further include a second aromatic group. It is preferable that the second aromatic group have an unsubstituted monocyclic ring or a substituted or unsubstituted bicyclic or tricyclic condensed ring; in particular, it is further preferable that the second aromatic group have a substituted or unsubstituted bicyclic or tricyclic condensed ring where the number of carbon atoms forming the ring is 6 to 13. It is still further preferable that the second aromatic group have a fluorene ring. Note that a dimethylfluorenyl group is preferable as the second aromatic group.

It is preferable that the arylamine compound further include a third aromatic group. The third aromatic group is a group having 1 to 3 substituted or unsubstituted benzene rings.

It is preferable that the at least three alkyl groups be each a chain alkyl group having 2 to 5 carbon atoms. It is preferable that the alkyl group substituted for the phenyl group be a chain alkyl group having 2 to 5 carbon atoms. In particular, the chain alkyl group having 2 to 5 carbon atoms is preferably a chain alkyl group having a branch formed of 3 to 5 carbon atoms, and is further preferably a t-butyl group.

Examples of the above-described material having a hole-transport property include organic compounds having structures represented by (Gₕ₂1) to (Gₕ₂3) below.

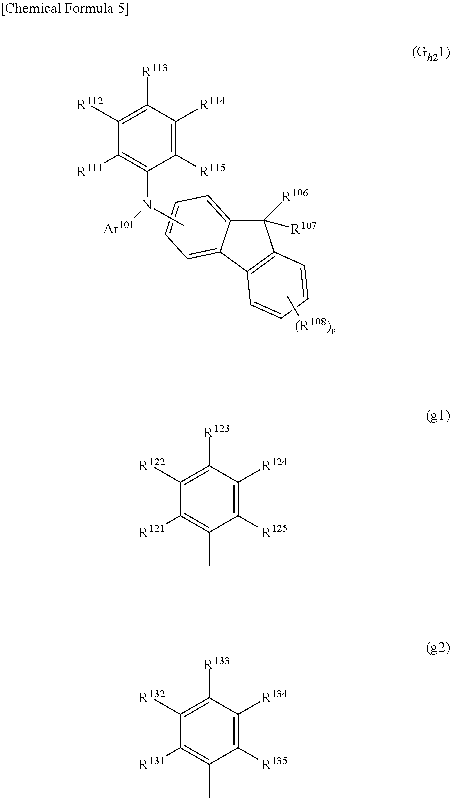

Note that in General Formula (Gₕ₂1) above, Ar¹⁰¹ represents a substituent with a substituted or unsubstituted benzene ring or a substituent in which two or three substituted or unsubstituted benzene rings are bonded to each other.

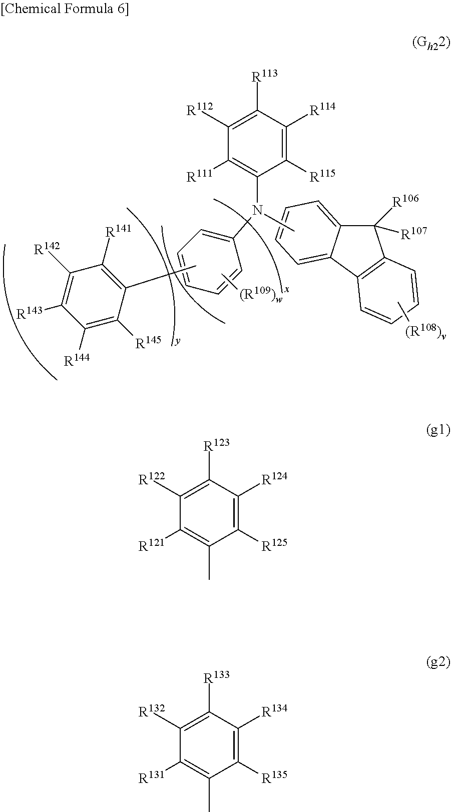

Note that in General Formula (Gₕ₂2) above, x and y each independently represent 1 or 2 and x+y is 2 or 3. Furthermore, R¹⁰⁹ represents an alkyl group having 1 to 4 carbon atoms, and w represents an integer of 0 to 4. Moreover, R¹⁴¹ to R¹⁴⁵ each independently represent any one of hydrogen, an alkyl group having 1 to 6 carbon atoms, and a cycloalkyl group having 5 to 12 carbon atoms. When w is an integer of 2 or more, R¹⁰⁹s may be the same or different from each other. When x is 2, the kind of substituents, the number of substituents, and the position of bonds in one phenylene group may be the same as or different from those in the other phenylene group. When y is 2, the kind of substituents and the number of substituents in one phenyl group including R¹⁴¹ to R¹⁴⁵ may be the same as or different from those in the other phenyl group including R¹⁴¹ to R¹⁴⁵.

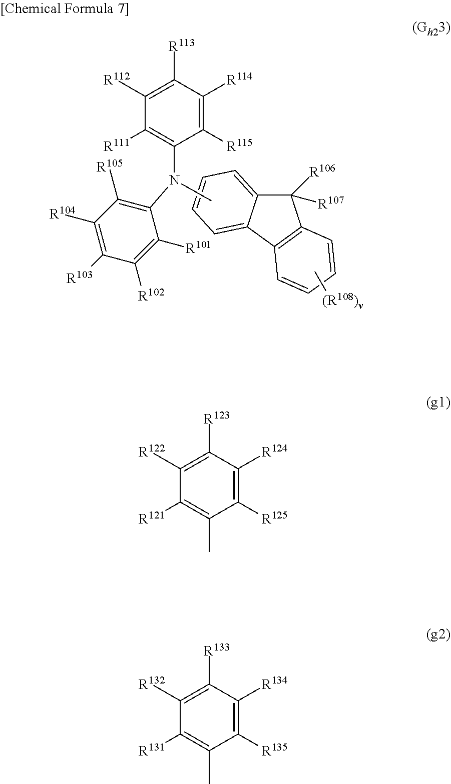

In General Formula (Gₕ₂3) above, R¹⁰¹ to R¹⁰⁵ each independently represent any one of hydrogen, an alkyl group having 1 to 6 carbon atoms, a cycloalkyl group having 6 to 12 carbon atoms, and a substituted or unsubstituted phenyl group.

In General Formulae (Gₕ₂1) to (Gₕ₂3) above, R¹⁰⁶, R¹⁰⁷, and R¹⁰⁸ each independently represent an alkyl group having 1 to 4 carbon atoms, and v represents an integer of 0 to 4. Note that when v is 2 or more, R¹⁰⁸s may be the same or different from each other. One of R¹¹¹ to R¹¹⁵ represents a substituent represented by General Formula (g1) above, and the others each independently represent any one of hydrogen, an alkyl group having 1 to 6 carbon atoms, and a substituted or unsubstituted phenyl group. In General Formula (g1) above, one of R¹²¹ to R¹²⁵ represents a substituent represented by General Formula (g2) above, and the others each independently represent any one of hydrogen, an alkyl group having 1 to 6 carbon atoms, and a phenyl group substituted by an alkyl group having 1 to 6 carbon atoms. In General Formula (g2) above, R¹³¹ to R¹³⁵ each independently represent any one of hydrogen, an alkyl group having 1 to 6 carbon atoms, and a phenyl group substituted by an alkyl group having 1 to 6 carbon atoms. Note that at least three of R¹¹¹ to R¹¹⁵, R¹²¹ to R¹²⁵, and R¹³¹ to R¹³⁵ are each an alkyl group having 1 to 6 carbon atoms; the number of substituted or unsubstituted phenyl groups in R¹¹¹ to R¹¹⁵ is one or less; and the number of phenyl groups substituted by an alkyl group having 1 to 6 carbon atoms in R¹²¹ to R¹²⁵ and R¹³¹ to R¹³⁵ is one or less. In at least two combinations of the three combinations R¹¹² and R¹¹⁴, R¹²² and R¹²⁴, and R¹³² and R¹³⁴, at least one R represents any of the substituents other than hydrogen.

Specifically, any of the following can be used as the material having a hole-transport property: NN-bis(4-cyclohexylphenyl)-N-(9,9-dimethyl-9H-fluoren-2yl)amine (abbreviation: dchPAF), N-(4-cyclohexylphenyl)-N-(3″,5″-ditertiarybutyl-1,1″-biphenyl-4-yl)-N-(9,9-dimethyl-9H-fluoren-2yl)amine (abbreviation: mmtBuBichPAF), N-(3,3″,5,5″-tetra-t-butyl-1,1′: 3,1″-terphenyl-5′-yl)-N-(4-cyclohexylphenyl)-9,9-dimethyl-9H-flu oren-2-amine (abbreviation: mmtBumTPchPAF), N-[(3,3′, 5′-t-butyl)-1,1′-biphenyl-5-yl]-N-(4-cyclohexylphenyl)-9,9-dimethyl-9H-fluoren-2-amin e (abbreviation: mmtBumBichPAF), N-(1,1′-biphenyl-2-yl)-N-[(3,3′, 5′-tri-t-butyl)-1,1′-biphenyl-5-yl]-9,9-dimethyl-9H-fluoren-2-ami ne (abbreviation: mmtBumBioFBi), N-(4-tert-butylphenyl)-N-(3,3″, 5,5″-tetra-t-butyl-1,1′: 3,1″-terphenyl-5′-yl)-9,9,-dimethyl-9H-fluo ren-2-amine (abbreviation: mmtBumTPtBuPAF), N-(1,1′-biphenyl-2-yl)-N-(3,3″, 5′,5″-tetra-t-butyl-1,1′: 3,1″-terphenyl-5-yl)-9,9-dimethyl-9H-fluor en-2-amine (abbreviation: mmtBumTPoFBi-02), N-(4-cyclohexylphenyl)-N-(3,3″, 5′,5″-tetra-t-butyl-1,1′: 3,1″-terphenyl-5-yl)-9,9-dimethyl-9H-flu oren-2-amine (abbreviation: mmtBumTPchPAF-02), N-(1,1′-biphenyl-2-yl)-N-(3″, 5′,5″-tri-t-butyl-1,1′: 3′,1″-terphenyl-5-yl)-9,9-dimethyl-9H-fluoren-2-amine (abbreviation: mmtBumTPoFBi-03), N-(4-cyclohexylphenyl)-N-(3″, 5′,5″-tri-t-butyl-1,1′: 3,1″-terphenyl-5-yl)-9,9-dimethyl-9H-fluoren-2-amine (abbreviation: mmtBumTPchPAF-03), and the like.

### Structure Example 2 of Light-Emitting Device 150

The light-emitting device 150 described in this embodiment includes a layer 104.

### Structure Example of Layer 104

The layer 104 includes a region positioned between the electrode 551G(i,j) and the unit 103, and the layer 104 contains the material HT1 and a material AM having an electron acceptor property. Note that the layer 104 can be referred to as a hole-injection layer. For example, a material having a hole-injection property can be used for the layer 104.

The material HT1 has a HOMO level HOMO1 (see FIG. 1). For example, a material having a HOMO level that is higher than or equal to −5.7 eV and lower than or equal to −5.3 eV, preferably a material having a HOMO level that is higher than or equal to −5.7 eV and lower than or equal to −5.35 eV can be used as the material HT1. Note that the HOMO level is an energy level of the highest occupied molecular orbital (HOMO).

### Structure Example 2 of Layer 112

The layer 112 includes a region 112A and a region 112B. The region 112A contains the material HT1.

The region 112B includes a portion positioned between the layer 111 and the region 112A, and the region 112B contains a material HT2.

The material HT2 has a HOMO level HOMO2 (see FIG. 1i). For example, a material having a HOMO level that differs from the HOMO level HOMO1 by −0.2 eV to 0 eV inclusive can be used as the material HT2.

### Structure Example 2 of Layer 113

The layer 113 contains the material ET. The material ET has a refractive index n2, and the refractive index n2 is higher than or equal to 1.5 and lower than or equal to 1.75 in the wavelength range of 455 nm to 465 nm inclusive. Alternatively, the refractive index n2 is higher than or equal to 1.45 and lower than or equal to 1.70 at 633 nm.

For example, as the material ET, a material which has an electron-transport property and an ordinary refractive index higher than or equal to 1.50 and lower than or equal to 1.75 in a blue light emission range (455 nm to 465 nm) or an ordinary refractive index higher than or equal to 1.45 and lower than or equal to 1.70 with respect to 633-nm light, which is usually used for measurement of refractive indices, can be used.

### [Material Having Electron-Transport Property]

An example of the material having an electron-transport property is an organic compound that includes at least one six-membered heteroaromatic ring having 1 to 3 nitrogen atoms, a plurality of aromatic hydrocarbon rings each of which has 6 to 14 carbon atoms forming a ring and at least two of which are benzene rings, and a plurality of hydrocarbon groups forming a bond by sp3 hybrid orbitals.

In the above organic compound, the proportion of carbon atoms forming a bond by sp3 hybrid orbitals in total carbon atoms in the molecule of the organic compound is preferably higher than or equal to 10% and lower than or equal to 60%, further preferably higher than or equal to 10% and lower than or equal to 50%. Alternatively, the integral value of signals at lower than 4 ppm is preferably ½ or more of the integral value of signals at 4 ppm or higher in the results of ¹H-NMR measurement conducted on the organic compound.

It is preferable that all the hydrocarbon groups forming a bond by sp3 hybrid orbitals in the above organic compound be bonded to the aromatic hydrocarbon rings each having 6 to 14 carbon atoms forming a ring, and the LUMO of the organic compound not be distributed in the aromatic hydrocarbon rings.

The organic compound having an electron-transport property is preferably an organic compound represented by General Formula (Gₑ₁1) or (Gₑ₁2) below.

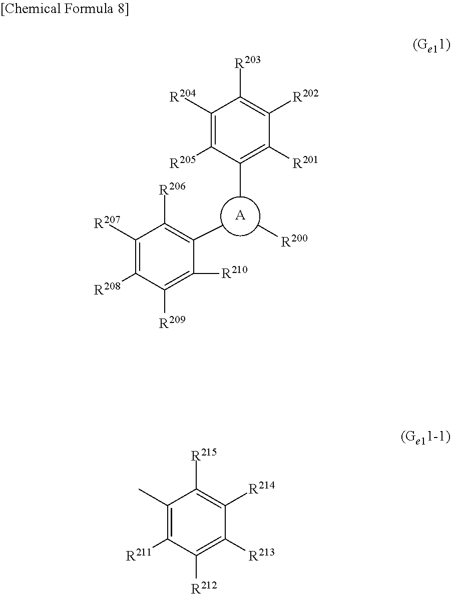

In the formula, A represents a six-membered heteroaromatic ring having 1 to 3 nitrogen atoms, and is preferably any of a pyridine ring, a pyrimidine ring, a pyrazine ring, a pyridazine ring, and a triazine ring.

In addition, R²⁰⁰ represents any of hydrogen, an alkyl group having 1 to 6 carbon atoms, an alicyclic group having 3 to 10 carbon atoms, and a substituent represented by Formula (Gₑ₁1-1).

At least one of R²⁰¹ to R²¹⁵ represents a phenyl group having a substituent and the others each independently represent any of hydrogen, an alkyl group having 1 to 6 carbon atoms, an alicyclic group having 3 to 10 carbon atoms, a substituted or unsubstituted aromatic hydrocarbon group having 6 to 14 carbon atoms forming a ring, and a substituted or unsubstituted pyridyl group. Note that R²⁰¹, R²⁰³, R²⁰s, R²⁰⁶, R²⁰s, R²¹⁰, R²¹¹, R²¹³, and R²¹⁵ are preferably hydrogen. The phenyl group having a substituent has one or two substituents, which each independently represent any of an alkyl group having 1 to 6 carbon atoms, an alicyclic group having 3 to 10 carbon atoms, and a substituted or unsubstituted aromatic hydrocarbon group having 6 to 14 carbon atoms forming a ring.

The organic compound represented by General Formula (Gel) above includes a plurality of hydrocarbon groups selected from an alkyl group having 1 to 6 carbon atoms and an alicyclic group having 3 to 10 carbon atoms, and carbon atoms forming a bond by sp3 hybrid orbitals account for higher than or equal to 10% and lower than or equal to 60% of total carbon atoms in a molecule of the organic compound.

The organic compound having an electron-transport property is preferably an organic compound represented by General Formula (Gₑ₁2) below.

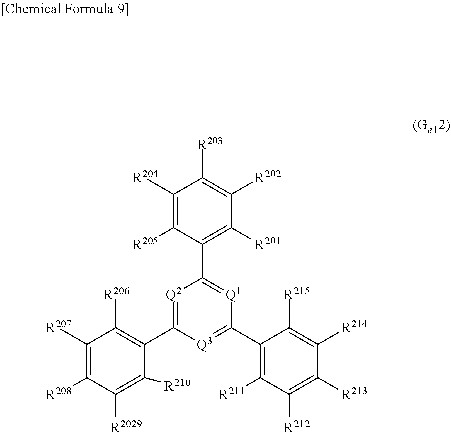

In the formula, two or three of Q¹ to Q³ represent N; in the case where two of Q¹ to Q³ are N, the rest represents CH.

At least any one of R²⁰¹ to R²¹⁵ represents a phenyl group having a substituent and the others each independently represent any of hydrogen, an alkyl group having 1 to 6 carbon atoms, an alicyclic group having 3 to 10 carbon atoms, a substituted or unsubstituted aromatic hydrocarbon group having 6 to 14 carbon atoms forming a ring, and a substituted or unsubstituted pyridyl group. Note that R²⁰¹, R²⁰³, R²⁰⁵s, R²⁰⁶, R²⁰⁸s, R²¹⁰, R²¹¹, R²¹³, and R²¹⁵ are preferably hydrogen. The phenyl group having a substituent has one or two substituents, which each independently represent any of an alkyl group having 1 to 6 carbon atoms, an alicyclic group having 3 to 10 carbon atoms, and a substituted or unsubstituted aromatic hydrocarbon group having 6 to 14 carbon atoms forming a ring.

The organic compound represented by General Formula (Gₑ₁2) above includes a plurality of hydrocarbon groups selected from an alkyl group having 1 to 6 carbon atoms and an alicyclic group having 3 to 10 carbon atoms, and carbon atoms forming a bond by sp3 hybrid orbitals preferably account for higher than or equal to 10% and lower than or equal to 60% of total carbon atoms in a molecule of the organic compound.

In the organic compound represented by General Formula (Gₑ₁1) or (Gₑ₁2) above, the phenyl group having a substituent is preferably a group represented by Formula (Gₑ₁1-2) below.

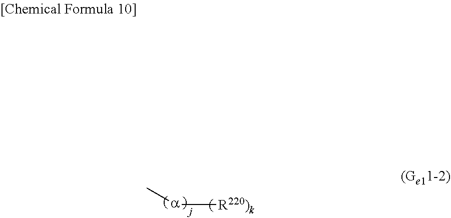

In the formula, a represents a substituted or unsubstituted phenylene group and is preferably a meta-substituted phenylene group. In the case where the meta-substituted phenylene group has a substituent, the substituent is also preferably meta-substituted. The substituent is preferably an alkyl group having 1 to 6 carbon atoms or an alicyclic group having 3 to 10 carbon atoms, further preferably an alkyl group having 1 to 6 carbon atoms, still further preferably a t-butyl group.

R²²⁰ represents an alkyl group having 1 to 6 carbon atoms, an alicyclic group having 3 to 10 carbon atoms, or a substituted or unsubstituted aromatic hydrocarbon group having 6 to 14 carbon atoms forming a ring.

In addition, j and k each represent 1 or 2. In the case where j is 2, αs may be the same or different from each other. In the case where k is 2, R²²⁰s may be the same or different from each other. Note that R²²⁰ is preferably a phenyl group, and is a phenyl group that has an alkyl group having 1 to 6 carbon atoms or an alicyclic group having 3 to 10 carbon atoms at one or both of the two meta-positons. The substituent at one or both of the two meta-positons of the phenyl group is preferably an alkyl group having 1 to 6 carbon atoms, further preferably a t-butyl group.

Specifically, any of the following can be used as the material having an electron-transport property: 2-{(3′,5′-di-tert-butyl)-1,1′-biphenyl-3-yl}-4,6-bis(3,5-di-tert-butylphenyl)-1,3,5-triazine (abbreviation: mmtBumBP-dmmtBuPTzn), 2-{(3′, 5′-di-tert-butyl)-1,1′-biphenyl-3-yl}-4,6-diphenyl-1,3,5-triazine (abbreviation: mmtBumBPTzn), 2-(3,3″, 5,5″-tetra-tert-butyl-1,1′: 3′,1″-phenyl-5′-yl)-4,6-diphenyl-1,3,5-triazine (abbreviation: mmtBumTPTzn), 2-{(3′, 5′-di-tert-butyl)-1,1′-biphenyl-3-yl}-4,6-bis(3,5-di-tert-butylphenyl)-1,3-pyrimidine (abbreviation: mmtBumBP-dmmtBuPPm), 2-(3,3″, 5′,5″-tetra-tert-butyl-1,1′: 3′,1″-terphenyl-5-yl)-4,6-diphenyl-1,3,5-triazine (abbreviation: mmtBumTPTzn-02), and the like.

Accordingly, light emission efficiency can be increased. Alternatively, reliability as well as efficiency can be improved. Consequently, a novel light-emitting device that is highly convenient, useful, or reliable can be provided.

For example, a material having an electron mobility higher than or equal to 1×10⁻⁷ cm²/Vs and lower than or equal to 5×10⁻⁵ cm²/Vs when the square root of the electric field strength [V/cm] is 600 can be used as the material ET. When the electron-transport property of the electron-transport layer is suppressed, the amount of electrons injected into a light-emitting layer can be controlled. Alternatively, the light-emitting layer can be prevented from having excess electrons.

Note that this embodiment can be combined with any of the other embodiments in this specification as appropriate.

### Embodiment 2

In this embodiment, the structure of the light-emitting device 150 of one embodiment of the present invention is described with reference to FIG. 1A.

### Structure Example of Light-Emitting Device 150

The light-emitting device 150 includes the electrode 551G(i,j), the electrode 552, and the unit 103.

### Structure Example of Unit 103

The unit 103 includes the layer 111, the layer 112, and the layer 113.

### Structure Example 1 of Layer 111

A light-emitting material can be used for the layer 111.

### [Fluorescent Substance]

A fluorescent substance can be used for the layer 111. For example, the following fluorescent substances can be used for the layer 111. Note that fluorescent substances that can be used for the layer 111 are not limited to the following, and a variety of known fluorescent substances can be used.

Specifically, any of the following can be used: 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N,N-triphenyl-1,4-phenylenedia mine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,N,N′,N′,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(1,1′-biphenyl-2-yl)-2-anthryl]-N,N,N-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone, (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylide ne}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethe nyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethe nyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl) ethenyl]-4H-pyran-4-ylidene}propanedinitrile (abbreviation: BisDCJTM), N,N-(pyrene-1,6-diyl)bis[(6,N-diphenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), and the like.

In particular, a condensed aromatic diamine compound typified by a pyrenediamine compound such as 1,6FLPAPrn, 1,6mMemFLPAPrn, or 1,6BnfAPrn-03 is preferable because of its high hole-trapping property, high emission efficiency, or high reliability.

### [Phosphorescent Substance 1]

A phosphorescent substance can be used for the layer 111. For example, the following phosphorescent substances can be used for the layer 111. Note that phosphorescent substances that can be used for the layer 111 are not limited to the following, and a variety of known phosphorescent substances can be used.

Specifically, an organometallic iridium complex having a 4H-triazole skeleton, or the like can be used for the layer 111. Specifically, tris{2-[5-(2-methylphenyl)-4-(2,6-dimethylphenyl)-4H-1,2,4-triazol-3-yl-xN2]phenyl-xC}iridiu m(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

Alternatively, for example, an organometallic iridium complex having a 1H-triazole skeleton, or the like can be used. Specifically, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato)iridium(III) (abbreviation: [Ir(Prptz1-Me)₃]), or the like can be used.

Alternatively, for example, an organometallic iridium complex having an imidazole skeleton, or the like can be used. Specifically, fac-tris[1-(2,6-diisopropylphenyl)-2-phenyl-1H-imidazole]iridium(III) (abbreviation: [Ir(iPrpmi)₃]), tris[3-(2,6-dimethylphenyl)-7-methylimidazo[1,2-f]phenanthridinato]iridium(III) (abbreviation: [Ir(dmpimpt-Me)₃]), or the like can be used.

Alternatively, for example, an organometallic iridium complex having a phenylpyridine derivative with an electron-withdrawing group as a ligand, or the like can be used. Specific examples include bis[2-(4′,6′-difluorophenyl)pyridinato-N,C²]iridium(III) tetrakis(1-pyrazolyl)borate (abbreviation: FIr6), bis[2-(4′,6′-difluorophenyl)pyridinato-N,C²]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF3ppy)₂(pic)]), and bis[2-(4′,6′-difluorophenyl)pyridinato-N,C^{2′}]iridium(III) acetylacetonate (abbreviation: FIracac).

Note that these are compounds exhibiting blue phosphorescence, and are compounds having an emission wavelength peak at 440 nm to 520 nm.

### [Fluorescent Substance 2]

For example, an organometallic iridium complex having a pyrimidine skeleton, or the like can be used for the layer 111. Specifically, any of the following can be used: tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), and the like.

For example, an organometallic iridium complex having a pyrazine skeleton, or the like can be used. Specifically, any of the following can be used: (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), and the like.

For example, an organometallic iridium complex having a pyridine skeleton, or the like can be used. Specifically, any of the following can be used: tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), [2-d3-methyl-(2-pyridinyl-κN)benzofuro[2,3-b]pyridine-xC]bis[2-(5-d3-methyl-2-pyridyl-xN2)p henyl-x]iridium(III) (abbreviation: [Ir(5mppy-d3)₂(mbfpypy-d3)]), [2-d3-methyl-(2-pyridinyl-κN)benzofuro[2,3-b]pyridine-xC]bis[2-(2-pyridinyl-κN)phenyl-xC]iri dium(III) (abbreviation: [Ir(ppy)₂(mbfpypy-d3)]), and the like.

For example, a rare earth metal complex or the like can be used. Specifically, tris(acetylacetonato) (monophenanthroline)terbium(III) (abbreviation: [Tb(acac)₃(Phen)]) or the like can be given.

Note that these are compounds mainly exhibiting green phosphorescence, and have an emission wavelength peak at 500 nm to 600 nm. Note that an organometallic iridium complex having a pyrimidine skeleton is particularly preferable because of its distinctively high reliability or emission efficiency.

### [Fluorescent Substance 3]

For example, an organometallic iridium complex having a pyrimidine skeleton, or the like can be used for the layer 111. Specifically, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato] (dipivaloylmethanato)iridium(III) (abbreviation: [Ir(dlnpm)₂(dpm)]), or the like can be used.

For example, an organometallic iridium complex having a pyrazine skeleton, or the like can be used. Specifically, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

For example, an organometallic iridium complex having a pyridine skeleton or a quinoline skeleton, or the like can be used. Specifically, tris(1-phenylisoquinolinato-N,C²′)iridium(III) (abbreviation: [Ir(piq)₃]), bis(1-phenylisoquinolinato-N,C²′)iridium(III) acetylacetonate (abbreviation: [Ir(piq)₂(acac)]), or the like can be used.

For example, a platinum complex or the like can be used. Specifically, 2,3,7,8,12,13,17,18-octaethyl-21H,23H-porphyrin platinum(II) (abbreviation: PtOEP) or the like can be used.

For example, a rare earth metal complex or the like can be used. Specifically, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato](monophenanthroline)europium(III) (abbreviation: [Eu(TTA)₃(Phen)]), or the like can be used.

Note that these are compounds exhibiting red phosphorescence, and have an emission peak at 600 nm to 700 nm. Furthermore, from the organometallic iridium complex having a pyrazine skeleton, red light emission with chromaticity favorably used for display devices can be obtained.

### [Substance Exhibiting Thermally Activated Delayed Fluorescence (TADF)]

A variety of known TADF materials can be used as the light-emitting material.

A TADF material has a small difference between the energy level in the lowest singlet excited state (S1) and the energy level in the lowest triplet excited state (T1), and can convert the triplet excitation energy into the singlet excitation energy by reverse intersystem crossing. Thus, it is possible to upconvert triplet excitation energy into singlet excitation energy (reverse intersystem crossing) using a little thermal energy and to efficiently generate a singlet excited state. In addition, the triplet excitation energy can be converted into light emission.

An exciplex whose excited state is formed by two kinds of substances has an extremely small difference between the S1 level and the T1 level and has a function of a TADF material that can convert triplet excitation energy into singlet excitation energy.

Note that a phosphorescent spectrum observed at low temperatures (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between S1 and T1 of the TADF material is preferably less than or equal to 0.3 eV, further preferably less than or equal to 0.2 eV.

When the TADF material is used as a light-emitting substance, the S1 level of the host material is preferably higher than the S1 level of the TADF material. In addition, the T1 level of the host material is preferably higher than the T1 level of the TADF material.

For example, a fullerene, a derivative thereof, an acridine, a derivative thereof, an eosin derivative, or the like can be used as the TADF material. Furthermore, porphyrin containing a metal such as magnesium (Mg), zinc (Zn), cadmium (Cd), tin (Sn), platinum (Pt), indium (In), or palladium (Pd) can be used as the TADF material.

Specifically, any of the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

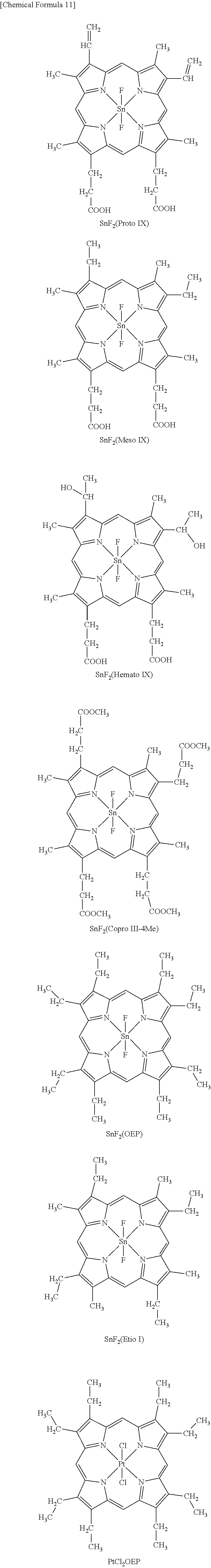

Furthermore, a heterocyclic compound including one or both of a π-electron rich heteroaromatic ring and a Tc-electron deficient heteroaromatic ring can be used, for example, as the TADF material.

Specifically, any of the following materials whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazine-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

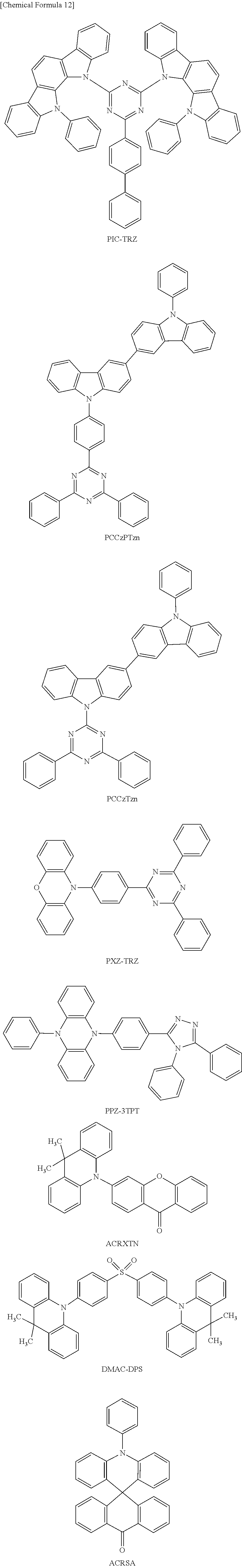

These heterocyclic compounds are preferable because of having both a high electron-transport property and a high hole-transport property owing to the π-electron rich heteroaromatic ring and the π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are particularly preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and reliability.

Among skeletons having a Tc-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. Note that a dibenzofuran skeleton and a dibenzothiophene skeleton are preferable as the furan skeleton and the thiophene skeleton, respectively. As the pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which a π-electron rich heteroaromatic ring and a π-electron deficient heteroaromatic ring are directly bonded to each other is particularly preferable because the electron-donating property of the π-electron rich heteroaromatic ring and the electron-accepting property of the π-electron deficient heteroaromatic ring are both increased and the energy difference between the S1 level and the T1 level becomes small, and thus thermally activated delayed fluorescence can be obtained efficiently. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a boron-containing skeleton such as phenylborane or boranthrene, an aromatic ring or a heteroaromatic ring having a nitrile group or a cyano group, such as benzonitrile or cyanobenzene, a carbonyl skeleton such as benzophenone, a phosphine oxide skeleton, a sulfone skeleton, or the like can be used.

As described above, a Tc-electron deficient skeleton and a Tc-electron rich skeleton can be used instead of at least one of the Tc-electron deficient heteroaromatic ring and the Tc-electron rich heteroaromatic ring.

### Structure Example 2 of Layer 111

A material having a carrier-transport property can be used as the host material. For example, a material having a hole-transport property, a material having an electron-transport property, a substance exhibiting thermally activated delayed fluorescence, a material having an anthracene skeleton, or a mixed material can be used as the host material.

### [Material Having Hole-Transport Property]

The material having a hole-transport property preferably has a hole mobility of 1×10⁻⁶ cm²/Vs or more.

The material having a hole-transport property is preferably an amine compound or an organic compound having a T-electron rich heteroaromatic ring skeleton. For example, a compound having an aromatic amine skeleton, a compound having a carbazole skeleton, a compound having a thiophene skeleton, a compound having a furan skeleton, or the like can be used.

The following are examples that can be used as a compound having an aromatic amine skeleton: 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]spiro-9,9′-bifluoren-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), or the like can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As a compound having a furan skeleton, for example, 4,4′,4″-(benzene-1,3,5-triyl)tri(dibenzofuran) (abbreviation: DBF3P-II), 4-{3-[3-(9-phenyl-9H-fluoren-9-yl)phenyl]phenyl}dibenzofuran (abbreviation: mmDBFFLBi-II), or the like can be used.

Among the above, the compound having an aromatic amine skeleton and the compound having a carbazole skeleton are preferable because these have favorable reliability, have high hole-transport properties, and contribute to a reduction in driving voltage.

### [Material Having Electron-Transport Property]

As the material having an electron-transport property, a metal complex or an organic compound having a π-electron deficient heteroaromatic ring skeleton is preferably used. As examples of the organic compound having a π-electron deficient heteroaromatic ring skeleton, a heterocyclic compound having a polyazole skeleton, a heterocyclic compound having a diazine skeleton, and a heterocyclic compound having a pyridine skeleton are preferable. In particular, the heterocyclic compound having a diazine skeleton or the heterocyclic compound having a pyridine skeleton has favorable reliability and thus is preferable. Furthermore, the heterocyclic compound having a diazine (pyrimidine or pyrazine) skeleton has a high electron-transport property and contributes to a reduction in driving voltage.

As the metal complex, bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), bis[2-(2-benzothiazolyl)phenolato]zinc(II) (abbreviation: ZnBTZ), or the like can be used, for example.

As the heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or the like can be used, for example.

As the heterocyclic compound having a diazine skeleton, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,8-bis[3-(dibenzothiophen-4-yl)phenyl]benzo[h]quinazoline (abbreviation: 4,8mDBtP2Bqn), or the like can be used, for example.

As the heterocyclic compound having a pyridine skeleton, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), or the like can be used, for example.

As the heterocyclic compound having a triazine skeleton, 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)−2-yl]-1,3,5-triazine (abbreviation: BP-SFTzn), 2-{3-[3-(benzo[b]naphtho[1,2-d]furan-8-yl)phenyl]phenyl}−4,6-diphenyl-1,3,5-triazine (abbreviation: mBnfBPTzn), or 2-{3-[3-(benzo[b]naphtho[1,2-d]furan-6-yl)phenyl]phenyl}−4,6-diphenyl-1,3,5-triazine (abbreviation: mBnfBPTzn-02) can be used, for example.

### [Substance Exhibiting Thermally Activated Delayed Fluorescence (TADF)]

A variety of known TADF materials can be used as the host material.

When the TADF material is used as the host material, triplet excitation energy generated in the TADF material is converted into singlet excitation energy by reverse intersystem crossing and transferred to the light-emitting substance, whereby the emission efficiency of the light-emitting device can be increased. At this time, the TADF material functions as an energy donor, and the light-emitting substance functions as an energy acceptor.

This is very effective in the case where the light-emitting substance is a fluorescent substance. In that case, the S1 level of the TADF material is preferably higher than the S1 level of the fluorescent substance in order to achieve high emission efficiency. Furthermore, the T1 level of the TADF material is preferably higher than the S1 level of the fluorescent substance. Therefore, the T1 level of the TADF material is preferably higher than the T1 level of the fluorescent substance.

It is also preferable to use a TADF material that exhibits light emission overlapping with the wavelength of a lowest-energy-side absorption band of the fluorescent substance. This enables smooth transfer of excitation energy from the TADF material to the fluorescent substance and accordingly enables efficient light emission, which is preferable.

In order that singlet excitation energy is efficiently generated from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that causes light emission) of the fluorescent substance. As the protective group, a substituent having no n bond and saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituent having no π bond has a poor carrier-transport property; thus, the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a n bond, further preferably includes an aromatic ring, still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, a phenothiazine skeleton, and the like. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

For example, the TADF material that can be used as the light-emitting material can be used as the host material.

### [Material Having Anthracene Skeleton]

In the case of using a fluorescent substance as the light-emitting substance, a material having an anthracene skeleton is particularly suitable for the host material. The use of a substance having an anthracene skeleton as a host material for a fluorescent substance makes it possible to achieve a light-emitting layer with favorable emission efficiency and durability.

As the substance having an anthracene skeleton that is used as the host material, a substance having a diphenylanthracene skeleton, in particular, a substance having a 9,10-diphenylanthracene skeleton, is preferable because of its chemical stability.

The host material preferably has a carbazole skeleton because the hole-injection and hole-transport properties are improved. In particular, the host material having a dibenzocarbazole skeleton is preferable because its HOMO level is shallower than that of carbazole by approximately 0.1 eV so that holes enter the host material easily, the hole-transport property is improved, and the heat resistance is increased. Thus, a substance having both of a 9,10-diphenylanthracene skeleton and a carbazole skeleton (or a benzocarbazole skeleton or a dibenzocarbazole skeleton) is preferable as the host material. Note that in terms of the hole-injection and hole-transport properties described above, instead of a carbazole skeleton, a benzofluorene skeleton or a dibenzofluorene skeleton may be used.

Examples of the substance having an anthracene skeleton include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), and 9-(1-naphthyl)-10-[4-(2-naphthyl)phenyl]anthracene (abbreviation: aN-PNPAnth).

In particular, CzPA, cgDBCzPA, 2mBnfPPA, and PCzPA have excellent characteristics.

### Structure Example 1 of Mixed Material

A material in which a plurality of kinds of substances are mixed can be used as the host material. For example, a material in which a material having an electron-transport property and a material having a hole-transport property are mixed can be favorably used as the host material. When the material having an electron-transport property is mixed with the material having a hole-transport property, the carrier-transport property of the layer 111 can be easily adjusted. A recombination region can also be controlled easily. The weight ratio of the material having a hole-transport property to the material having an electron-transport property in the mixed material is the material having a hole-transport property: the material having an electron-transport property=1:19 to 19:1.

### Structure Example 2 of Mixed Material

In addition, a material mixed with a phosphorescent substance can be used as the host material. When a fluorescent substance is used as the light-emitting substance, a phosphorescent substance can be used as an energy donor for supplying excitation energy to the fluorescent substance.

A mixed material containing a material to form an exciplex can be used as the host material. For example, a material in which an emission spectrum of a formed exciplex overlaps with a wavelength of the absorption band on the lowest energy side of the light-emitting substance can be used as the host material. This enables smooth energy transfer and improves emission efficiency. Alternatively, the driving voltage can be reduced.

Note that at least one of the materials forming an exciplex may be a phosphorescent substance. In this case, triplet excitation energy can be efficiently converted into singlet excitation energy by reverse intersystem crossing.

A combination of a material having an electron-transport property and a material having a hole-transport property whose HOMO level is higher than or equal to the HOMO level of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

Note that the formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side), observed by comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed by comparison of the transient EL of the material having a hole-transport property, the transient EL of the material having an electron-transport property, and the transient EL of the mixed film of these materials.

### Structure Example 1 of Layer 113

A material having an electron-transport property can be used for the layer 113.

### [Material Having Electron-Transport Property]

For example, a material having an electron-transport property that can be used for the layer 111 can be used for the layer 113. Specifically, a material having an electron-transport property that can be used as the host material can be used for the layer 113.

### [Material Having Anthracene Skeleton]

An organic compound having an anthracene skeleton can be used for the layer 113. In particular, an organic compound having both an anthracene skeleton and a heterocyclic skeleton can be suitably used.

For example, it is possible to use an organic compound having both an anthracene skeleton and a nitrogen-containing five-membered ring skeleton or an organic compound having both an anthracene skeleton and a nitrogen-containing six-membered ring skeleton. Alternatively, it is possible to use an organic compound having both an anthracene skeleton and a nitrogen-containing five-membered ring skeleton where two heteroatoms are included in a ring or an organic compound having a nitrogen-containing six-membered ring skeleton where two heteroatoms are included in a ring. Specifically, it is preferable to use, as the heterocyclic skeleton, a pyrazole ring, an imidazole ring, an oxazole ring, a thiazole ring, a pyrazine ring, a pyrimidine ring, a pyridazine ring, or the like.

### Structure Example of Mixed Material

A material in which a plurality of kinds of substances are mixed can be used for the layer 113. Specifically, a material in which a substance having an electron-transport property and any of an alkali metal, an alkali metal compound, and an alkali metal complex are mixed can be used. For example, 2-phenyl-3-{4-[10-(3-pyridyl)-9-anthryl]phenyl}quinoxaline (abbreviation: PyA1PQ) can be used as the substance having an electron-transport property in the material in which a plurality of kinds of substances are mixed. In particular, PyA1PQ can be suitably used in the case where the layer 104 includes a composite material and the composite material contains a substance having a relatively deep HOMO level that is higher than or equal to −5.7 eV and lower than or equal to −5.4 eV. It is further preferable that the HOMO level of the material having an electron-transport property be −6.0 eV or higher. As a result, the reliability of the light-emitting device can be increased.

For example, an 8-hydroxyquinolinato structure is preferably included as the metal complex. Note that in the case where the 8-hydroxyquinolinato structure is included, a methyl-substituted product (e.g., a 2-methyl-substituted product or a 5-methyl-substituted product) thereof or the like can also be used. Specific examples include 8-hydroxyquinolinato-lithium (abbreviation: Liq) and 8-hydroxyquinolinato-sodium (abbreviation: Naq). In particular, a complex of a monovalent metal ion, especially a complex of lithium is preferable, and Liq is further preferable.

The concentration of the alkali metal, the elemental alkali metal, the alkali metal compound, or the alkali metal complex preferably differs in the thickness direction of the layer 113 (including the case where the concentration is 0).

### Structure Example of Layer 112

A material having a hole-transport property can be used for the layer 112.

### [Material Having Hole-Transport Property]

The material having a hole-transport property preferably has a hole mobility of 1×10⁻⁶ cm²/Vs or more.

For example, a material having a hole-transport property that can be used for the layer 111 can be used for the layer 112. Specifically, a material having a hole-transport property that can be used as the host material can be used for the layer 112.

Note that this embodiment can be combined with any of the other embodiments in this specification as appropriate.

### Embodiment 3

In this embodiment, the structure of the light-emitting device 150 of one embodiment of the present invention is described with reference to FIG. 1A.

### Structure Example of Light-Emitting Device 150

The light-emitting device 150 includes the electrode 551G(i,j), the electrode 552, and the unit 103. Furthermore, the light-emitting device 150 includes the layer 104 and a layer 105.

### Structure Example of Electrode 551G(i,j)

A conductive material can be used for the electrode 551G(i,j), for example. Specifically, a metal, an alloy, a conductive compound, a mixture of these, or the like can be used for the electrode 551G(i,j). For example, a material having a work function higher than or equal to 4.0 eV can be suitably used.

For example, indium oxide-tin oxide (ITO: Indium Tin Oxide), indium oxide-tin oxide containing silicon or silicon oxide, indium oxide-zinc oxide, indium oxide containing tungsten oxide and zinc oxide (IWZO), or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (such as titanium nitride), or the like can be used. Alternatively, graphene can be used.

### Structure Example of Layer 104

The layer 104 includes a region positioned between the electrode 551G(i,j) and the unit 103.

For example, a material having a hole-injection property can be used for the layer 104. Specifically, a substance having an acceptor property and a composite material can be used for the layer 104. Note that an organic compound and an inorganic compound can be used as the substance having an acceptor property. The substance having an acceptor property can extract electrons from an adjacent hole-transport layer (or hole-transport material) by the application of an electric field.

### Example 1 of Material Having Hole-Injection Property

The substance having an acceptor property can be used as the material having a hole-injection property. This can facilitate injection of holes from the electrode 551G(i,j), for example. Alternatively, the driving voltage of the light-emitting device can be reduced.

For example, a compound having an electron-withdrawing group (a halogen group or a cyano group) can be used as the substance having an acceptor property. Note that an organic compound having an acceptor property is easily evaporated and deposited. As a result, the productivity of the light-emitting device can be increased.

Specifically, any of the following materials can be used as the material having a hole-injection property: 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylen-1,3,4,5,6,8,9,10-octafluoro-7H-pyren-2-ylidene)malononitrile, and the like.

A compound in which electron-withdrawing groups are bonded to a fused aromatic ring having a plurality of heteroatoms, such as HAT-CN, is particularly preferable because it is thermally stable.

Alternatively, a [3]radialene derivative including an electron-withdrawing group (in particular, a cyano group or a halogen group such as a fluoro group) is preferable because it has a very high electron-accepting property.

Specifically,
α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneac etonitrile], α,α′,α″-1,2,3-cyclopropanetriylidenetris[2,3,4,5,6-pentafluorobenzeneacetonitrile], or the like can be used.

As the substance having an acceptor property, molybdenum oxide, vanadium oxide, ruthenium oxide, tungsten oxide, manganese oxide, or the like can be used.

Alternatively, it is possible to use any of the following compounds: phthalocyanine-based complex compounds such as phthalocyanine (abbreviation: H₂Pc) and copper phthalocyanine (CuPc); and compounds having an aromatic amine skeleton such as 4,4′-bis[N-(4-diphenylaminophenyl)-N-phenylamino]biphenyl (abbreviation: DPAB) and N,N-bis{4-[bis(3-methylphenyl)amino]phenyl}-N,N′-diphenyl-(1,1′-biphenyl)-4,4′-diamine (abbreviation: DNTPD).

In addition, a high molecular compound such as poly(3,4-ethylenedioxythiophene)/poly(styrenesulfonic acid) (PEDOT/PSS), or the like can be used.

### Example 2 of Material Having Hole-Injection Property

A composite material can be used as the material having a hole-injection property. For example, a composite material in which a material having a hole-transport property contains the substance having an acceptor property can be used. Thus, selection of a material used to form an electrode can be carried out in a wide range regardless of the work function. Alternatively, besides a material having a high work function, a material having a low work function can also be used for the electrode 551G(i,j).

A variety of organic compounds can be used as a material having a hole-transport property in the composite material. As the material having a hole-transport property in the composite material, for example, a compound having an aromatic amine skeleton, a carbazole derivative, an aromatic hydrocarbon, a high molecular compound (such as an oligomer, a dendrimer, or a polymer), or the like can be used. A substance having a hole mobility of 1×10⁻⁶ cm²/Vs or higher can be favorably used.

Alternatively, for example, a substance having a relatively deep HOMO level that is higher than or equal to −5.7 eV and lower than or equal to −5.4 eV can be favorably used as the material having a hole-transport property in the composite material. Accordingly, hole injection to the hole-transport layer can be facilitated. Alternatively, reliability of the light-emitting device can be improved.

As the compound having an aromatic amine skeleton, for example, N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), N,N-bis{4-[bis(3-methylphenyl)amino]phenyl}-N,N-diphenyl-(1,1′-biphenyl)-4,4′-diamine (abbreviation: DNTPD), 1,3,5-tris[N-(4-diphenylaminophenyl)-N-phenylamino]benzene (abbreviation: DPA3B), or the like can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(N-carbazolyl)]phenyl-10-phenylanthracene (abbreviation: CzPA), 1,4-bis[4-(N-carbazolyl)phenyl]-2,3,5,6-tetraphenylbenzene, or the like can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, or the like can be used.

As an aromatic hydrocarbon having a vinyl group, for example, 4,4′-bis(2,2-diphenylvinyl)biphenyl (abbreviation: DPVBi), 9,10-bis[4-(2,2-diphenylvinyl)phenyl]anthracene (abbreviation: DPVPA), or the like can be used.

Other examples include pentacene and coronene.

As the high molecular compound, for example, poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), poly[N,N-bis(4-butylphenyl)-N,N-bis(phenyl)benzidine](abbreviation: Poly-TPD), or the like can be used.

Furthermore, a substance having any of a carbazole skeleton, a dibenzofuran skeleton, a dibenzothiophene skeleton, and an anthracene skeleton can be favorably used as the material having a hole-transport property in the composite material, for example. Moreover, a substance including any of the following can be used: an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance including an N,N-bis(4-biphenyl)amino group, reliability of the light-emitting device can be improved.

As the material having a hole-transport property in the composite material, for example, N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), NN-bis(4-biphenyl)benzo[b]naphtho[1,2-d]furan-6-amine (abbreviation: BBABnf(6)), NN-bis(4-biphenyl)benzo[b]naphtho[1,2-d]furan-8-amine (abbreviation: BBABnf(8)), NN-bis(4-biphenyl)benzo[b]naphtho[2,3-d]furan-4-amine (abbreviation: BBABnf(II)(4)), NN-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4 ∝0-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBAβN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBA βNαNB), 4,4′-diphenyl-4″-(5;2′-binaphthyl-1-yl)triphenylamine (abbreviation: BBA βNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenylyl)carbazole}triphenylamine (abbreviation: YGTBiβNB), N-[4-(9-phenyl-9Hcarbazol-3-yl)phenyl]-N-[4-(1-naphthyl)phenyl]-9,9′-spirobi(9H-fluoren)−2-a mine (abbreviation: PCBNBSF), NN-bis(4-biphenylyl)-9,9′-spirobi[9H-fluoren]-2-amine (abbreviation: BBASF), N,N-bis(1,1′-biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)−4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-9,9-dimethyl-N-[4-(9-phenyl-9H-carbazol-3-yl)phenyl]-9H-fluoren-2-ami ne (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, or the like can be used.

### Example 3 of Material Having Hole-Injection Property

A composite material containing the material having a hole-transport property, the substance having an acceptor property, and a fluoride of an alkali metal or an alkaline earth metal can be used as the material having a hole-injection property. In particular, a composite material in which the proportion of fluorine atoms is higher than or equal to 20% can be favorably used. Thus, the refractive index of the layer 104 can be reduced. Alternatively, a layer with a low refractive index can be formed inside the light-emitting device. Alternatively, the external quantum efficiency of the light-emitting device can be improved.

### Structure Example of Electrode 552

A conductive material can be used for the electrode 552, for example. Specifically, a metal, an alloy, an electrically conductive compound, a mixture of these, or the like can be used for the electrode 552. For example, a material having a lower work function than the electrode 551G(i,j) can be used for the electrode 552. Specifically, a material having a work function lower than or equal to 3.8 eV can be favorably used.

For example, an element belonging to Group 1 of the periodic table, an element belonging to Group 2 of the periodic table, a rare earth metal, or an alloy containing any of these elements can be used for the electrode 552.

Specifically, lithium (Li), cesium (Cs), or the like; magnesium (Mg), calcium (Ca), strontium (Sr), or the like; europium (Eu), ytterbium (Yb), or the like; or an alloy containing any of these (MgAg or AlLi) can be used for the electrode 552.

### Structure Example of Layer 105

A material having an electron-injection property can be used for the layer 105, for example. Specifically, a substance having a donor property can be used for the layer 105. Alternatively, a composite material in which a substance having a donor property is contained in the material having an electron-transport property can be used for the layer 105. This can facilitate injection of electrons from the electrode 552, for example. Alternatively, the driving voltage of the light-emitting device can be reduced. Alternatively, a variety of conductive materials can be used for the electrode 552 regardless of the work function. Specifically, Al, Ag, ITO, indium oxide-tin oxide containing silicon or silicon oxide, or the like can be used for the electrode 552.

### [Material Having Electron-Injection Property 1]

For example, an alkali metal, an alkaline earth metal, a rare earth metal, or a compound thereof can be used as the substance having a donor property. Alternatively, an organic compound such as tetrathianaphthacene (abbreviation: TTN), nickelocene, or decamethylnickelocene can be used as the substance having a donor property.

Specifically, an alkali metal compound (including an oxide, a halide, and a carbonate), an alkaline earth metal compound (including an oxide, a halide, and a carbonate), a rare earth metal compound (including an oxide, a halide, and a carbonate), or the like can be used as the material having an electron-injection property.

Specifically, lithium oxide, lithium fluoride (LiF), cesium fluoride (CsF), calcium fluoride (CaF₂), lithium carbonate, cesium carbonate, 8-hydroxyquinolinato-lithium (abbreviation: Liq), or the like can be used as the material having an electron-injection property.

### [Material Having Electron-Injection Property 2]

For example, a composite material that contains a substance having an electron-transport property and an alkali metal, an alkaline earth metal, or a compound thereof can be used as the material having an electron-injection property.

For example, a material having an electron-transport property usable for the unit 103 can be used as the material having an electron-injection property.

Furthermore, as the material having an electron-injection property, a material that includes a fluoride of an alkali metal in a microcrystalline state and a substance having an electron-transport property, or a material that includes a fluoride of an alkaline earth metal in a microcrystalline state and a substance having an electron-transport property can be used.

In particular, a material including a fluoride of an alkali metal or a fluoride of an alkaline earth metal at 50 wt % or higher can be suitably used. Alternatively, an organic compound having a bipyridine skeleton can be suitably used. Thus, the refractive index of the layer 105 can be reduced. Alternatively, the external quantum efficiency of the light-emitting device can be improved.

### [Material Having Electron-Injection Property 3]

Furthermore, electride can be used as the material having an electron-injection property. For example, a substance obtained by adding electrons at high concentration to an oxide where calcium and aluminum are mixed can be used, for example, as the material having an electron-injection property.

Note that this embodiment can be combined with any of the other embodiments in this specification as appropriate.

### Embodiment 4

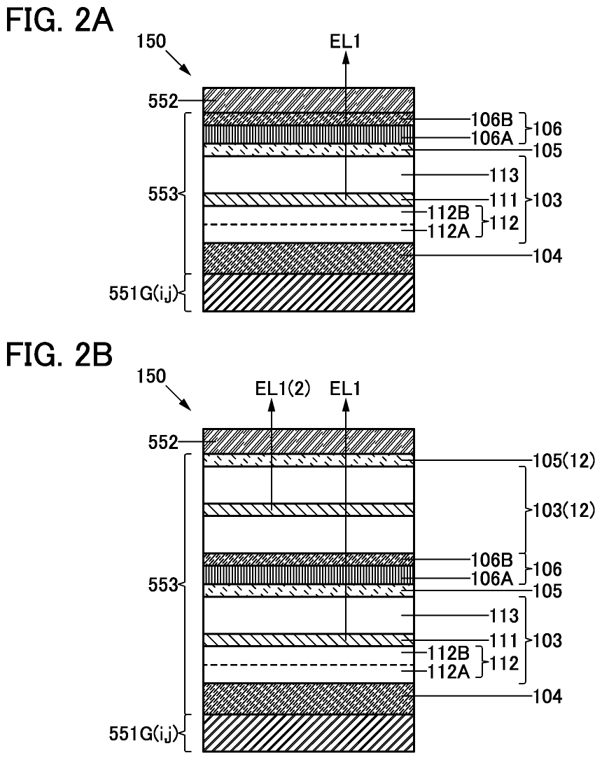

In this embodiment, the structure of the light-emitting device 150 of one embodiment of the present invention is described with reference to FIG. 2A.

FIG. 2A is a cross-sectional view illustrating a structure of a light-emitting device of one embodiment of the present invention, which is different from the structure illustrated in FIG. 1A.

### Structure Example of Light-Emitting Device 150

The light-emitting device 150 described in this embodiment includes the electrode 551G(i,j), the electrode 552, the unit 103, and an intermediate layer 106 (see FIG. 2A).

### Structure Example of Intermediate Layer 106

The intermediate layer 106 includes a region positioned between the unit 103 and the electrode 552, and the intermediate layer 106 includes a layer 106A and a layer 106B.

### Structure Example of Layer 106A

The layer 106A includes a region positioned between the unit 103 and the layer 106B. Note that the layer 106A can be referred to, for example, an electron-relay layer.

For example, a substance having an electron-transport property can be used for the electron-relay layer. Accordingly, a layer that is on the anode side and in contact with the electron-relay layer can be distanced from a layer that is on the cathode side and in contact with the electron-relay layer. Alternatively, interaction between the layer that is on the anode side and in contact with the electron-relay layer and the layer that is on the cathode side and in contact with the electron-relay layer can be reduced. Alternatively, electrons can be smoothly supplied to the layer that is on the anode side and in contact with the electron-relay layer.

For example, a substance having an electron-transport property can be favorably used for the electron-relay layer. Specifically, the following can be favorably used for the electron-relay layer: a substance whose LUMO level is positioned between the LUMO level of the substance having an acceptor property in the composite material given as the material having a hole-injection property and the LUMO level of the substance included in the layer that is on the cathode side and in contact with the electron-relay layer.

For example, a substance having an electron-transport property, which has a LUMO level in a range higher than or equal to −5.0 eV, preferably higher than or equal to −5.0 eV and lower than or equal to −3.0 eV, can be used for the electron-relay layer.

Specifically, a phthalocyanine-based material can be used for the electron-relay layer. Alternatively, a metal complex having a metal-oxygen bond and an aromatic ligand can be used for the electron-relay layer.

### Structure Example of Layer 106B

The layer 106B can be referred to, for example, as a charge-generation layer. The charge-generation layer has a function of supplying electrons to the anode side and supplying holes to the cathode side by applying voltages. Specifically, electrons can be supplied to the unit 103 that is positioned on the anode side.

For example, any of the composite materials exemplified as the material having a hole-injection property can be used for the charge-generation layer. In addition, for example, a stacked film in which a film including the composite material and a film including a material having a hole-transport property are stacked can be used as the charge-generation layer.

Note that this embodiment can be combined with any of the other embodiments in this specification as appropriate.

### Embodiment 5

In this embodiment, the structure of the light-emitting device 150 of one embodiment of the present invention is described with reference to FIG. 2B.

FIG. 2B is a cross-sectional view illustrating a structure of a light-emitting device of one embodiment of the present invention, which is different from the structures illustrated in FIG. 1A and FIG. 2A.

### Structure Example of Light-Emitting Device 150

The light-emitting device 150 described in this embodiment includes the electrode 551G(i,j), the electrode 552, the unit 103, the intermediate layer 106, and a unit 103(12) (see FIG. 2B). Furthermore, the light-emitting device 150 includes a layer 105(12). A structure including the intermediate layer 106 and a plurality of units is referred to as a stacked light-emitting device or a tandem light-emitting device in some cases. This structure enables high luminance emission while the current density is kept low. Alternatively, reliability can be improved. Alternatively, the driving voltage can be reduced in comparison with that of the light-emitting device with the same luminance. Alternatively, power consumption can be reduced.

### STRUCTURE EXAMPLE OF UNIT 103(12)

The unit 103(12) includes a region positioned between the intermediate layer 106 and the electrode 552.

The structure that can be used for the unit 103 can be employed for the unit 103(12). In other words, the light-emitting device 150 includes a plurality of units that are stacked. Note that the number of stacked units is not limited to two, and three or more units can be stacked.

The same structure as the unit 103 can be employed for the unit 103(12). Alternatively, a structure different from the unit 103 can be employed for the unit 103(12).

For example, a structure which exhibits a different emission color from the emission color of the unit 103 can be employed for the unit 103(12). Specifically, the unit 103 emitting red light and green light and the unit 103(12) emitting blue light can be employed. With this structure, a light-emitting device emitting light of a desired color can be provided. Alternatively, a light-emitting device emitting white light can be provided, for example.

### Structure Example of Intermediate Layer 106

The intermediate layer 106 has a function of supplying electrons to one of the unit 103 and the unit 103(12) and supplying holes to the other. For example, the intermediate layer 106 described in Embodiment 4 can be used.

### <Manufacturing Method of Light-Emitting Device 150>

For example, each layer of the electrode 551G(i,j), the electrode 552, the unit 103, the intermediate layer 106, and the unit 103(12) can be formed by a dry process, a wet process, an evaporation method, a droplet discharge method, a coating method, a printing method, or the like. A formation method may differ between components of the device.

Specifically, the light-emitting device 150 can be manufactured with a vacuum evaporation machine, an ink-jet machine, a coating machine such as a spin coater, a gravure printing machine, an offset printing machine, a screen printing machine, or the like.

For example, the electrode can be formed by a wet process or a sol-gel method using a paste of a metal material. Specifically, an indium oxide-zinc oxide film can be formed by a sputtering method using a target obtained by adding zinc oxide to indium oxide at 1 wt % to 20 wt %. Furthermore, an indium oxide film containing tungsten oxide and zinc oxide (IWZO) can be formed by a sputtering method using a target containing, with respect to indium oxide, tungsten oxide at 0.5 wt % to 5 wt % and zinc oxide at 0.1 wt % to 1 wt %.

Note that this embodiment can be combined with any of the other embodiments in this specification as appropriate.

### Embodiment 6

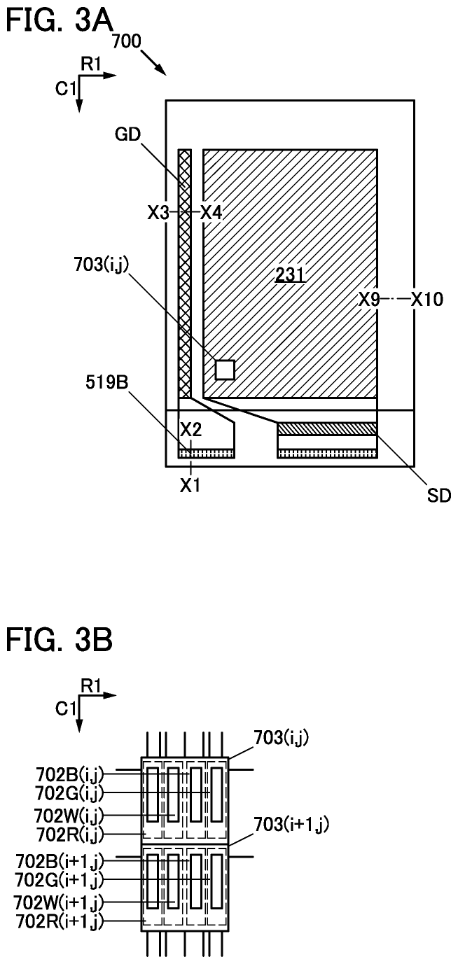

In this embodiment, a structure of a functional panel of one embodiment of the present invention is described with reference to FIG. 3 to FIG. 5.

FIG. 3A is a top view illustrating the structure of the functional panel of one embodiment of the present invention, and FIG. 3B is a diagram illustrating part of FIG. 3A.

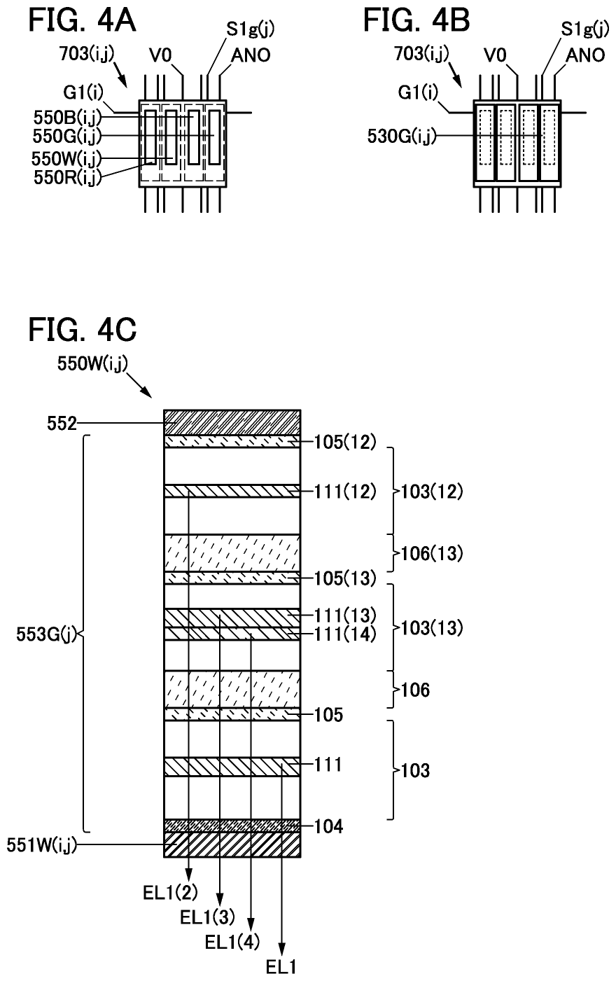

FIG. 4A is a diagram illustrating part of FIG. 3A. FIG. 4B is a diagram illustrating part of FIG. 4A, and FIG. 4C is a cross-sectional view illustrating another part of FIG. 4A.

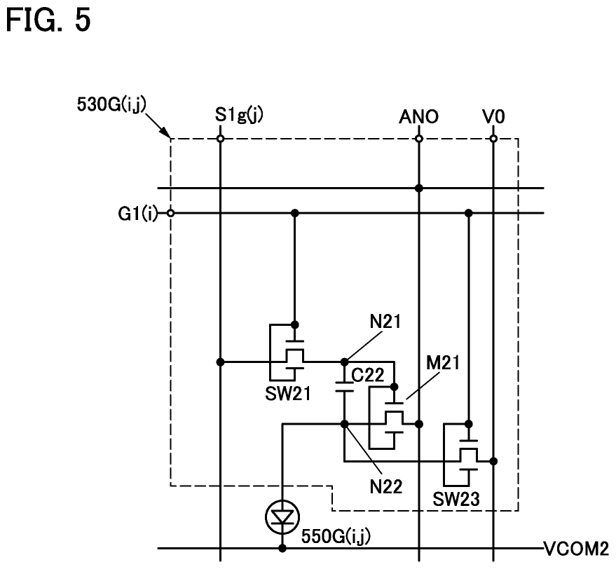

FIG. 5 is a circuit diagram illustrating a structure of a pixel circuit that can be used for the functional panel of one embodiment of the present invention.

### Structure Example 1 of Functional Panel 700

A functional panel 700 includes a region 231. The region 231 includes a pixel set 703(i,j) (see FIG. 3A).

The functional panel 700 includes a conductive film G1(i), a conductive film Slg(j), a conductive film ANO, and a conductive film VCOM2 (see FIG. 5). The functional panel 700 also includes a conductive film V0.

Note that the conductive film G1(i) is supplied with a first selection signal, and the conductive film Slg(j) is supplied with an image signal, for example.

### Structure Example 1 of Pixel 703(i,j)

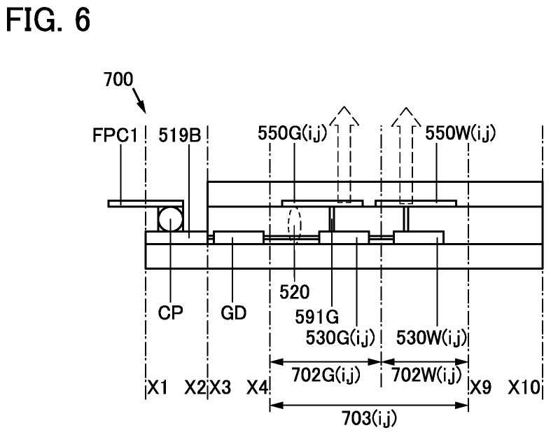

The pixel set 703(i,j) includes a pixel 702G(i,j) (see FIG. 3B). The pixel 702G(i,j) includes a pixel circuit 530G(i,j) and a light-emitting device 550G(i,j) (see FIG. 4A and FIG. 4B). In addition, the pixel set 703(i,j) includes a pixel 702B(i,j), a pixel 702R(i,j), and a pixel 702W(i,j), the pixel 702B(i,j) includes a light-emitting device 550B(i,j), and the pixel 702R(i,j) includes a light-emitting device 550R(i,j). The pixel 702W(i,j) includes a pixel circuit 530W(i,j) and a light-emitting device 550W(i,j) (see FIG. 6).

### Structure Example of Pixel Circuit 530G(i,j)

The pixel circuit 530G(i,j) is supplied with the first selection signal, and the pixel circuit 530G(i,j) obtains an image signal on the basis of the first selection signal. For example, the first selection signal can be supplied using the conductive film G1(i) (see FIG. 4B). The image signal can be supplied using the conductive film Slg(j). Note that the operation of supplying the first selection signal and making the pixel circuit 530G(i,j) obtain the image signal can be referred to as “writing”.

The pixel circuit 530G(i,j) includes a switch SW21, a transistor M21, a capacitor C22, and a node N21 (see FIG. 5). In addition, the pixel circuit 530G(i,j) includes a node N22 and a switch SW23.

The transistor M21 includes a gate electrode electrically connected to the node N21, a first electrode electrically connected to the light-emitting device 550G(i,j), and a second electrode electrically connected to the conductive film ANO.

The switch SW21 includes a first terminal electrically connected to the node N21 and a second terminal electrically connected to the conductive film Slg(j), and has a function of controlling the conduction state or the non-conduction state on the basis of a potential of the conductive film G1(i).

The capacitor C22 includes a conductive film electrically connected to the node N21 and a conductive film electrically connected to the first electrode of the transistor M21.

The switch SW23 includes a first terminal electrically connected to the conductive film V0 and a second terminal electrically connected to the first electrode of the transistor M21, and has a function of controlling the conduction state or the non-conduction state on the basis of the potential of the conductive film G1(i). Note that the first terminal of the switch SW23 is electrically connected to the node N22.

Thus, the image signal can be stored in the node N21. Alternatively, the potential of the node N22 can be initialized using the switch SW23. Alternatively, the intensity of light emitted from the light-emitting device 550G(i,j) can be controlled with the potential of the node N21. As a result, a novel functional panel that is highly convenient or reliable can be provided.

### Structure Example of Light-Emitting Device 550G(i,j)

The light-emitting device 550G(i,j) is electrically connected to the pixel circuit 530G(i,j) (see FIG. 4A and FIG. 5).

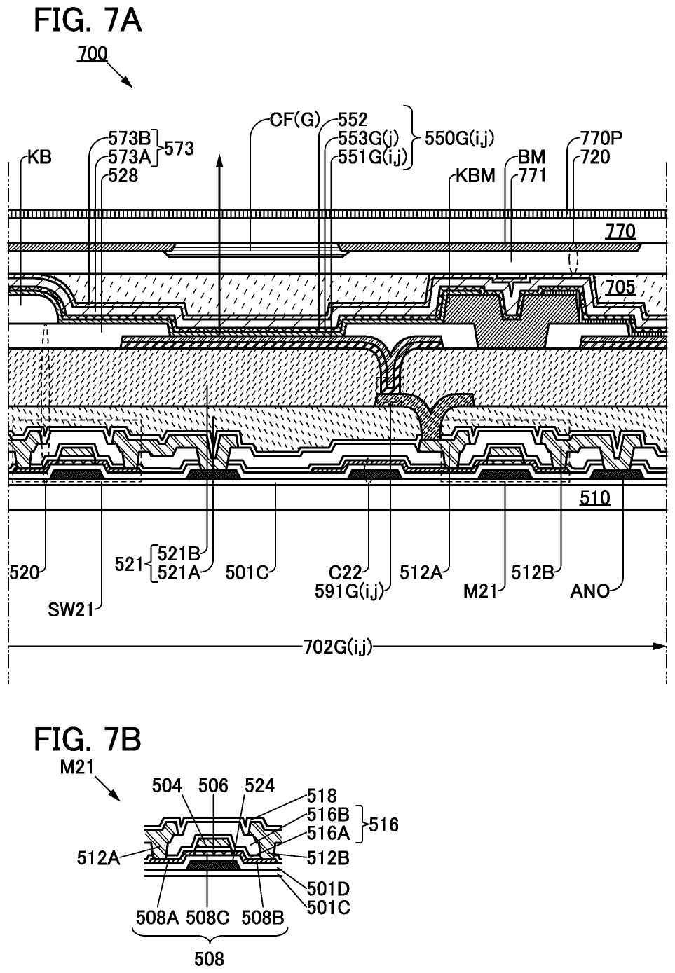

The light-emitting device 550G(i,j) includes the electrode 551G(i,j) electrically connected to the pixel circuit 530G(i,j), and the electrode 552 electrically connected to the conductive film VCOM2 (see FIG. 5 and FIG. 7A). Note that the light-emitting device 550G(i,j) has a function of operating on the basis of the potential of the node N21.

For example, an organic electroluminescence element, an inorganic electroluminescence element, a light-emitting diode, a QDLED (Quantum Dot LED), or the like can be used as the light-emitting device 550G(i,j).

Specifically, the structure described in any of Embodiment 1 to Embodiment 5 can be employed for the light-emitting device 550G(i,j).

### Structure Example 2 of Pixel 703(i,j)

A plurality of pixels can be used in the pixel 703(i,j). For example, a plurality of pixels capable of displaying colors with different hues can be used. Note that the plurality of pixels can be referred to as subpixels. A set of subpixels can be referred to as a pixel.

This enables additive mixture of colors displayed by the plurality of pixels. It is possible to display a color of a hue that an individual pixel cannot display.

Specifically, the pixel 702B(i,j) displaying blue, the pixel 702G(i,j) displaying green, and the pixel 702R(i,j) displaying red can be used in the pixel 703(i,j). The pixel 702B(i,j), the pixel 702G(i,j), and the pixel 702R(i,j) can each be referred to as a subpixel (see FIG. 3B).

The pixel 702W(i,j) displaying white or the like can be used in addition to the above set in the pixel 703(i,j), for example. A pixel displaying cyan, a pixel displaying magenta, and a pixel displaying yellow can be used in the pixel 703(i,j).

A pixel emitting infrared rays can be used in addition to the above set in the pixel 703(i,j), for example. Specifically, a pixel that emits light including light with a wavelength greater than or equal to 650 nm and less than or equal to 1000 nm can be used in the pixel 703(i,j).

### Structure Example 2 of Functional Panel 700

The functional panel described in this embodiment includes a driver circuit GD and a driver circuit SD (see FIG. 3A).

### Structure Example of Driver Circuit GD

The driver circuit GD has a function of supplying the first selection signal. For example, the driver circuit GD is electrically connected to the conductive film G1(i) and supplies the first selection signal.

### Structure Example of Driver Circuit SD

The driver circuit SD is electrically connected to the conductive film Slg(j) and supplies the image signal.

Note that this embodiment can be combined with any of the other embodiments in this specification as appropriate.

### Embodiment 7

In this embodiment, structures of the functional panel of one embodiment of the present invention are described with reference to FIG. 6 to FIG. 8.

FIG. 6 is a diagram illustrating a structure of the functional panel of one embodiment of the present invention and is a cross-sectional view taken along cutting lines X1-X2, X3-X4, and X9-X10 in FIG. 3A and in the pixel set 703(i,j).

FIG. 7A is a diagram illustrating a structure of the functional panel of one embodiment of the present invention and is a cross-sectional view of the pixel 702G(i,j) illustrated in FIG. 3B. FIG. 7B is a cross-sectional view illustrating part of FIG. 7A.

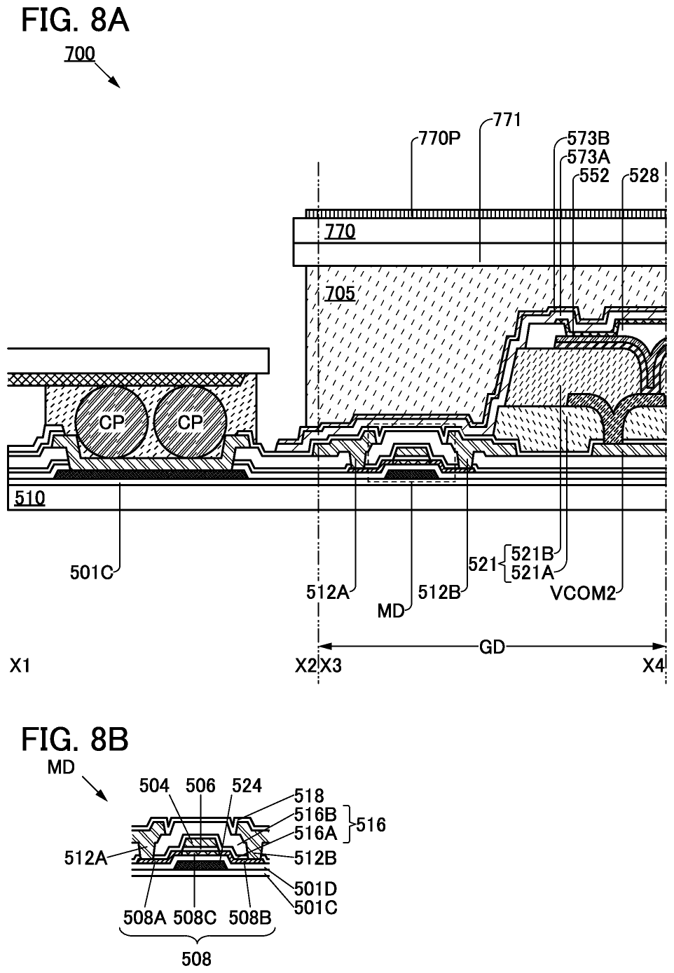

FIG. 8A is a diagram illustrating a structure of the functional panel of one embodiment of the present invention and is a cross-sectional view taken along the cutting line X1-X2 and the cutting line X3-X4 in FIG. 3A. FIG. 8B is a diagram illustrating part of FIG. 8A.

### Structure Example 1 of Functional Panel 700

The functional panel described in this embodiment includes a functional layer 520 (see FIG. 6).

### Structure Example 1 of Functional Layer 520

The functional layer 520 includes the pixel circuit 530G(i,j) and the pixel circuit 530W(i,j) (see FIG. 6). The functional layer 520 includes, for example, the transistor M21 used in the pixel circuit 530G(i,j) (see FIG. 5 and FIG. 7A).

The functional layer 520 includes an opening portion 591G(i,j). The pixel circuit 530G(i,j) is electrically connected to the light-emitting device 550G(i,j) through the opening portion 591G(i,j) (see FIG. 6).

Thus, the pixel circuit 530G(i,j) can be formed in the pixel 702G(i,j). As a result, a novel functional panel that is highly convenient, useful, or reliable can be provided.

### Structure Example 2 of Functional Layer 520

The functional layer 520 includes the driver circuit GD (see FIG. 3A and FIG. 6). The functional layer 520 includes, for example, a transistor MD used in the driver circuit GD (see FIG. 6 and FIG. 8A).

Thus, the semiconductor film used in the driver circuit GD can be formed in the step of forming the semiconductor film used in the pixel circuit 530G(i,j), for example. Alternatively, the semiconductor film used in the driver circuit GD can be formed in a step different from the step of forming the semiconductor film used in the pixel circuit 530G(i,j). Alternatively, the manufacturing process of the functional panel can be simplified. As a result, a novel functional panel that is highly convenient, useful, or reliable can be provided.

### Structure Example of Transistor

A bottom-gate transistor, a top-gate transistor, or the like can be used in the functional layer 520. Specifically, a transistor can be used as a switch.

The transistor includes a semiconductor film 508, a conductive film 504, a conductive film 512A, and a conductive film 512B (see FIG. 7B).

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C, and the conductive film 504 has a function of a gate electrode.

An insulating film 506 includes a region positioned between the semiconductor film 508 and the conductive film 504. The insulating film 506 has a function of a gate insulating film.

The conductive film 512A has one of a function of a source electrode and a function of a drain electrode, and the conductive film 512B has the other of the function of the source electrode and the function of the drain electrode.

A conductive film 524 can be used for the transistor. The semiconductor film 508 is positioned between a region of the conductive film 524 and the conductive film 504. The conductive film 524 has a function of a second gate electrode.

### Structure Example 1 of Semiconductor Film 508

A semiconductor containing a Group 14 element can be used for the semiconductor film 508, for example. Specifically, a semiconductor containing silicon can be used for the semiconductor film 508.

### [Hydrogenated Amorphous Silicon]

For example, hydrogenated amorphous silicon can be used for the semiconductor film 508. Alternatively, microcrystalline silicon or the like can be used for the semiconductor film 508. Thus, a functional panel having less display unevenness than a functional panel using polysilicon for the semiconductor film 508, for example, can be provided. The size of the functional panel can be easily increased.

### [Polysilicon]

For example, polysilicon can be used for the semiconductor film 508. In this case, the field-effect mobility of the transistor can be higher than that of a transistor using hydrogenated amorphous silicon for the semiconductor film 508, for example. The driving capability can be higher than that of a transistor using hydrogenated amorphous silicon for the semiconductor film 508, for example. The aperture ratio of the pixel can be higher than that in the case of using a transistor that uses hydrogenated amorphous silicon for the semiconductor film 508, for example.

The reliability of the transistor can be higher than that of a transistor using hydrogenated amorphous silicon for the semiconductor film 508, for example.

The temperature required for manufacture of the transistor can be lower than that required for a transistor using single crystal silicon, for example.

The semiconductor film used in the transistor of the driver circuit can be formed in the same step as the semiconductor film used in the transistor of the pixel circuit. The driver circuit can be formed over the same substrate where the pixel circuit is formed. The number of components included in an electronic device can be reduced.

### [Single Crystal Silicon]

For example, single crystal silicon can be used for the semiconductor film 508. In this case, a functional panel can have higher resolution than a functional panel using hydrogenated amorphous silicon for the semiconductor film 508, for example. A functional panel having less display unevenness than a functional panel using polysilicon for the semiconductor film 508, for example, can be provided. Smart glasses or a head-mounted display can be provided, for example.

### Structure Example 2 of Semiconductor Film 508

For example, a metal oxide can be used for the semiconductor film 508. In this case, the pixel circuit can hold an image signal for a longer time than a pixel circuit utilizing a transistor using amorphous silicon for a semiconductor film. Specifically, a selection signal can be supplied at a frequency of lower than 30 Hz, preferably lower than 1 Hz, further preferably less than once per minute with the suppressed occurrence of flickers. Consequently, fatigue accumulation in a user of a data processing device can be reduced. Moreover, power consumption for driving can be reduced.

A transistor using an oxide semiconductor can be used, for example. Specifically, an oxide semiconductor containing indium, an oxide semiconductor containing indium, gallium, and zinc, or an oxide semiconductor containing indium, gallium, zinc, and tin can be used for the semiconductor film.

A transistor having a lower leakage current in an off state than a transistor using amorphous silicon for a semiconductor film can be used, for example. Specifically, a transistor using an oxide semiconductor for a semiconductor film can be used as a switch or the like. In that case, a potential of a floating node can be held for a longer time than in a circuit in which a transistor using amorphous silicon is used as a switch.

A 25-nm-thick film containing indium, gallium, and zinc can be used as the semiconductor film 508, for example.

A conductive film in which a 10-nm-thick film containing tantalum and nitrogen and a 300-nm-thick film containing copper are stacked can be used as the conductive film 504, for example. Note that the film containing tantalum and nitrogen is positioned between a region of the film containing copper and the insulating film 506.

A stacked film in which a 400-nm-thick film containing silicon and nitrogen and a 200-nm-thick film containing silicon, oxygen, and nitrogen are stacked can be used as the insulating film 506, for example. Note that the film containing silicon, oxygen, and nitrogen is positioned between a region of the film containing silicon and nitrogen and the semiconductor film 508.

A conductive film in which a 50-nm-thick film containing tungsten, a 400-nm-thick film containing aluminum, and a 100-nm-thick film containing titanium are stacked in this order can be used as the conductive film 512A or the conductive film 512B, for example. Note that the film containing tungsten includes a region in contact with the semiconductor film 508.

A manufacturing line for a bottom-gate transistor using amorphous silicon for a semiconductor can be easily remodeled into a manufacturing line for a bottom-gate transistor using an oxide semiconductor for a semiconductor, for example. Furthermore, a manufacturing line for a top-gate transistor using polysilicon for a semiconductor can be easily remodeled into a manufacturing line for a top-gate transistor using an oxide semiconductor for a semiconductor, for example. In either remodeling, an existing manufacturing line can be effectively utilized.

Accordingly, flickering of a display can be inhibited. Power consumption can be reduced. A moving image with quick movements can be smoothly displayed. A photograph and the like can be displayed with a wide range of grayscale. Thus, a novel functional panel that is highly convenient, useful, or reliable can be provided.

### Structure Example 3 of Semiconductor Film 508

For example, a compound semiconductor can be used for the semiconductor of the transistor. Specifically, a semiconductor containing gallium arsenide can be used.

For example, an organic semiconductor can be used for the semiconductor of the transistor. Specifically, an organic semiconductor containing any of polyacenes or graphene can be used for the semiconductor film.

### Structure Example of Capacitor

A capacitor includes one conductive film, a different conductive film, and an insulating film. The insulating film includes a region positioned between the one conductive film and the different conductive film.

For example, a conductive film used as the source electrode or the drain electrode of the transistor, a conductive film used as the gate electrode, and an insulating film used as the gate insulating film can be used for the capacitor.

### Structure Example 3 of Functional Layer 520

The functional layer 520 includes an insulating film 521, an insulating film 518, an insulating film 516, the insulating film 506, an insulating film 501C, and the like (see FIG. 7A and FIG. 7B).

The insulating film 521 includes a region positioned between the pixel circuit 530G(i,j) and the light-emitting device 550G(i,j).

The insulating film 518 includes a region positioned between the insulating film 521 and the insulating film 501C.

The insulating film 516 includes a region positioned between the insulating film 518 and the insulating film 501C.

The insulating film 506 includes a region positioned between the insulating film 516 and the insulating film 501C.

### [Insulating Film 521]

An insulating inorganic material, an insulating organic material, or an insulating composite material containing an inorganic material and an organic material can be used for the insulating film 521.

Specifically, an inorganic oxide film, an inorganic nitride film, an inorganic oxynitride film, or the like, or a stacked-layer material in which a plurality of films selected from these films are stacked can be used as the insulating film 521. For example, a film in which an insulating film 521A and an insulating film 521B are stacked can be used as the insulating film 521.

For example, a film including a silicon oxide film, a silicon nitride film, a silicon oxynitride film, an aluminum oxide film, or the like, or a film including a stacked-layer material in which a plurality of films selected from these films are stacked can be used as the insulating film 521. Note that the silicon nitride film is a dense film and has an excellent function of inhibiting diffusion of impurities.

For example, for the insulating film 521, polyester, polyolefin, polyamide, polyimide, polycarbonate, polysiloxane, an acrylic resin, or the like, or a stacked-layer material, a composite material, or the like of a plurality of resins selected from these resins can be used. Note that polyimide is excellent in thermal stability, insulating property, toughness, low dielectric constant, low coefficient of thermal expansion, chemical resistance, and other properties compared with other organic materials. Accordingly, in particular, polyimide can be suitably used for the insulating film 521 or the like.

The insulating film 521 may be formed using a photosensitive material. Specifically, a film formed using photosensitive polyimide, a photosensitive acrylic resin, or the like can be used as the insulating film 521.

Thus, the insulating film 521 can eliminate a step due to various components overlapping with the insulating film 521, for example.

### [Insulating Film 518]

The material that can be used for the insulating film 521, for example, can be used for the insulating film 518.

For example, a material having a function of inhibiting diffusion of oxygen, hydrogen, water, an alkali metal, an alkaline earth metal, and the like can be used for the insulating film 518. Specifically, a nitride insulating film can be used as the insulating film 518. For example, silicon nitride, silicon nitride oxide, aluminum nitride, aluminum nitride oxide, or the like can be used for the insulating film 518. Thus, diffusion of impurities into the semiconductor film of the transistor can be inhibited.

### [Insulating Film 516]

The material that can be used for the insulating film 521, for example, can be used for the insulating film 516. For example, a film in which an insulating film 516A and an insulating film 516B are stacked can be used as the insulating film 516.

Specifically, a film formed by a manufacturing method different from that of the insulating film 518 can be used as the insulating film 516.

### [Insulating Film 506]

The material that can be used for the insulating film 521, for example, can be used for the insulating film 506.

Specifically, a film including a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film can be used as the insulating film 506.

### [Insulating Film 501D]

An insulating film 501D includes a region positioned between the insulating film 501C and the insulating film 516.

The material that can be used for the insulating film 506, for example, can be used for the insulating film 501D.

### [Insulating Film 501C]

The material that can be used for the insulating film 521, for example, can be used for the insulating film 501C. Specifically, a material containing silicon and oxygen can be used for the insulating film 501C. Thus, diffusion of impurities into the pixel circuit, the light-emitting device 550G(i,j), or the like can be inhibited.

### Structure Example 4 of Functional Layer 520

The functional layer 520 includes a conductive film, a wiring, and a terminal. A material having conductivity can be used for the wiring, an electrode, the terminal, the conductive film, and the like.

### [Wiring and the Like]

For example, an inorganic conductive material, an organic conductive material, a metal, a conductive ceramic, or the like can be used for the wiring and the like.

Specifically, a metal element selected from aluminum, gold, platinum, silver, copper, chromium, tantalum, titanium, molybdenum, tungsten, nickel, iron, cobalt, palladium, and manganese, or the like can be used for the wiring and the like. Alternatively, an alloy containing the above-described metal element, or the like can be used for the wiring and the like. In particular, an alloy of copper and manganese is suitable for microfabrication using a wet etching method.

Specifically, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure of a titanium film, an aluminum film stacked over the titanium film, and a titanium film further formed thereover, or the like can be used for the wiring and the like.

Specifically, a conductive oxide such as indium oxide, indium tin oxide, indium zinc oxide, zinc oxide, or zinc oxide to which gallium is added can be used for the wiring and the like.

Specifically, a film containing graphene or graphite can be used for the wiring and the like.

For example, a film containing graphene oxide is formed and the film containing graphene oxide is reduced, so that a film containing graphene can be formed. As a reducing method, a method with application of heat, a method using a reducing agent, or the like can be given.

For example, a film including a metal nanowire can be used for the wiring and the like. Specifically, a nanowire containing silver can be used.

Specifically, a conductive polymer can be used for the wiring and the like.

Note that a terminal 519B can be electrically connected to a flexible printed circuit FPC1 using a conductive material, for example (see FIG. 6). Specifically, the terminal 519B can be electrically connected to the flexible printed circuit FPC1 using a conductive material CP.

### Structure Example 2 of Functional Panel 700

The functional panel 700 includes a base material 510, a base material 770, and a sealant 705 (see FIG. 7A). In addition, the functional panel 700 includes a structure body KB.

### <<Base Material 510 and Base Material 770>>

A material having a light-transmitting property can be used for the base material 510 or the base material 770.

For example, a flexible material can be used for the base material 510 or the base material 770. Thus, a flexible functional panel can be provided.

For example, a material with a thickness smaller than or equal to 0.7 mm and larger than or equal to 0.1 mm can be used. Specifically, a material polished to a thickness of approximately 0.1 mm can be used. Thus, the weight can be reduced.

A glass substrate of the 6th generation (1500 mm×1850 mm), the 7th generation (1870 mm×2200 mm), the 8th generation (2200 mm×2400 mm), the 9th generation (2400 mm×2800 mm), the 10th generation (2950 mm×3400 mm), or the like can be used as the base material 510 or the base material 770. Thus, a large-sized display device can be manufactured.

For the base material 510 or the base material 770, an organic material, an inorganic material, a composite material of an organic material and an inorganic material, or the like can be used.

For example, an inorganic material such as glass, ceramic, or a metal can be used. Specifically, non-alkali glass, soda-lime glass, potash glass, crystal glass, aluminosilicate glass, tempered glass, chemically tempered glass, quartz, sapphire, or the like can be used for the base material 510 or the base material 770. Aluminosilicate glass, tempered glass, chemically tempered glass, sapphire, or the like can be suitably used for the base material 510 or the base material 770 that is provided on the side close to a user of the functional panel. Thus, the functional panel can be prevented from being broken or damaged by the use thereof.

Specifically, an inorganic oxide film, an inorganic nitride film, an inorganic oxynitride film, or the like can be used. For example, a silicon oxide film, a silicon nitride film, a silicon oxynitride film, an aluminum oxide film, or the like can be used. Stainless steel, aluminum, or the like can be used for the base material 510 or the base material 770.

For example, a single crystal semiconductor substrate or a polycrystalline semiconductor substrate of silicon or silicon carbide, a compound semiconductor substrate of silicon germanium or the like, an SOI substrate, or the like can be used as the base material 510 or the base material 770. Thus, a semiconductor element can be formed on the base material 510 or the base material 770.

For example, an organic material such as a resin, a resin film, or plastic can be used for the base material 510 or the base material 770. Specifically, a material containing polyester, polyolefin, polyamide (e.g., nylon or aramid), polyimide, polycarbonate, polyurethane, an acrylic resin, an epoxy resin, or a resin having a siloxane bond, such as silicone, can be used for the base material 510 or the base material 770. For example, a resin film, a resin plate, a stacked-layer material, or the like containing any of these materials can be used. Thus, the weight can be reduced. The frequency of occurrence of breakage or the like due to dropping can be reduced, for example.

Specifically, polyethylene terephthalate (PET), polyethylene naphthalate (PEN), polyethersulfone (PES), a cycloolefin polymer (COP), a cycloolefin copolymer (COC), or the like can be used for the base material 510 or the base material 770.

For example, a composite material formed by attaching a metal plate, a thin glass plate, or a film of an inorganic material or the like and a resin film or the like to each other can be used for the base material 510 or the base material 770. For example, a composite material formed by dispersing a fibrous or particulate metal, glass, an inorganic material, or the like into a resin can be used for the base material 510 or the base material 770. For example, a composite material formed by dispersing a fibrous or particulate resin, an organic material, or the like into an inorganic material can be used for the base material 510 or the base material 770.

Furthermore, a single-layer material or a material in which a plurality of layers are stacked can be used for the base material 510 or the base material 770. For example, a material in which insulating films and the like are stacked can be used. Specifically, a material in which one or a plurality of films selected from a silicon oxide layer, a silicon nitride layer, a silicon oxynitride layer, and the like are stacked can be used. Thus, diffusion of impurities contained in the base materials can be prevented, for example. Diffusion of impurities contained in glass or a resin can be prevented. Diffusion of impurities that pass through a resin can be prevented.

Furthermore, paper, wood, or the like can be used for the base material 510 or the base material 770.

For example, a material having heat resistance high enough to withstand heat treatment in the manufacturing process can be used for the base material 510 or the base material 770. Specifically, a material having heat resistance to heat applied in the formation process of directly forming the transistor, the capacitor, or the like can be used for the base material 510 or the base material 770.

For example, a method in which an insulating film, a transistor, a capacitor, or the like is formed on a process substrate having heat resistance to heat applied in the manufacturing process, and the formed insulating film, transistor, capacitor, or the like is transferred to the base material 510 or the base material 770 can be used. Accordingly, an insulating film, a transistor, a capacitor, or the like can be formed on a flexible substrate, for example.

### <<Sealant 705>>

The sealant 705 includes a region positioned between the functional layer 520 and the base material 770 and has a function of bonding the functional layer 520 and the base material 770 together (see FIG. 7A).

An inorganic material, an organic material, a composite material of an inorganic material and an organic material, or the like can be used for the sealant 705.

For example, an organic material such as a thermally fusible resin or a curable resin can be used for the sealant 705.

For example, an organic material such as a reactive curable adhesive, a photocurable adhesive, a thermosetting adhesive, and/or an anaerobic adhesive can be used for the sealant 705.

Specifically, an adhesive containing an epoxy resin, an acrylic resin, a silicone resin, a phenol resin, a polyimide resin, an imide resin, a PVC (polyvinyl chloride) resin, a PVB (polyvinyl butyral) resin, an EVA (ethylene vinyl acetate) resin, or the like can be used for the sealant 705.

### <<Structure Body KB>>

The structure body KB includes a region positioned between the functional layer 520 and the base material 770. The structure body KB has a function of providing a predetermined space between the functional layer 520 and the base material 770.

Note that this embodiment can be combined with any of the other embodiments in this specification as appropriate.

### Embodiment 8

In this embodiment, a structure of a functional panel of one embodiment of the present invention is described with reference to FIG. 7.

### Structure Example 1 of Functional Panel 700

The functional panel 700 includes the light-emitting device 550G(i,j) (see FIG. 7).

### Structure Example 1 of Light-Emitting Device 550G(i,j)

The light-emitting device 550G(i,j) includes the electrode 551G(i,j), the electrode 552, and a layer 553G(j) containing a light-emitting material. The layer 553G(j) containing a light-emitting material includes a region positioned between the electrode 551G(i,j) and the electrode 552.

### Structure Example 1 of Layer 553G(U) Containing Light-Emitting Material

A stacked-layer material can be used for the layer 553G(j) containing a light-emitting material, for example.

For example, a material emitting blue light, a material emitting green light, or a material emitting red light can be used for the layer 553G(j) containing a light-emitting material. Furthermore, a material emitting infrared rays or a material emitting ultraviolet rays can be used for the layer 553G(j) containing a light-emitting material.

A stacked-layer material in which a layer containing a fluorescent substance and a layer containing a phosphorescent substance are stacked can be used for the layer 553G(j) containing a light-emitting material.

Specifically, the structure described in any of Embodiment 1 to Embodiment 5 can be employed for the light-emitting device 550G(i,j).

### Structure Example 2 of Layer 553G(U) Containing Light-Emitting Material

A stacked-layer material stacked to emit white light can be used for the layer 553G(j) containing a light-emitting material, for example.

Specifically, a plurality of materials emitting light with different hues can be used for the layer 553G(j) containing a light-emitting material. For example, a stacked-layer material in which a layer containing a material emitting blue light and a layer containing a material emitting yellow light are stacked can be used for the layer 553G(j) containing a light-emitting material. Alternatively, a stacked-layer material in which a layer containing a material emitting blue light, a layer containing a material emitting red light, and a layer containing a material emitting green light are stacked can be used for the layer 553G(j) containing a light-emitting material.

Note that the light-emitting device 550G(i,J) can be used with a coloring film CF(G) overlapping, for example. Thus, light of a predetermined hue can be extracted from white light, for example.

### Structure Example 3 of Layer 553G(j) Containing Light-Emitting Material

A stacked-layer material stacked to emit blue light or ultraviolet rays can be used for the layer 553G(j) containing a light-emitting material, for example.

Note that a color conversion layer can be used to overlap with the light-emitting device 550G(i,j). Thus, light of a predetermined hue can be extracted from blue light or ultraviolet rays, for example.

### Structure Example 4 of Layer 553G(j) Containing Light-Emitting Material

The layer 553G(j) containing a light-emitting material includes a light-emitting unit. The light-emitting unit includes one region where electrons injected from one side are recombined with holes injected from the other side. The light-emitting unit contains a light-emitting material, and the light-emitting material releases energy generated by recombination of electrons and holes as light.

A plurality of light-emitting units and an intermediate layer can be used for the layer 553G(j) containing a light-emitting material, for example. An intermediate layer includes a region positioned between two light-emitting units. The intermediate layer includes a charge-generation region, and the intermediate layer has functions of supplying holes to the light-emitting unit placed on the cathode side and supplying electrons to the light-emitting unit placed on the anode side. Furthermore, a structure including a plurality of light-emitting units and an intermediate layer is referred to as a tandem light-emitting element in some cases.

Accordingly, the current efficiency of light emission can be increased. The density of current flowing through the light-emitting element at the same luminance can be reduced. The reliability of the light-emitting element can be increased.

For example, a light-emitting unit containing a material emitting light with one hue and a light-emitting unit containing a material emitting light with a different hue can be stacked and used for the layer 553G(j) containing a light-emitting material. A light-emitting unit containing a material emitting light with one hue and a light-emitting unit containing a material emitting light with the same hue can be stacked and used for the layer 553G(j) containing a light-emitting material. Specifically, two light-emitting units each containing a material emitting blue light can be stacked and used.

For the layer 553G(j) containing a light-emitting material, a high molecular compound (e.g., an oligomer, a dendrimer, or a polymer), a middle molecular compound (a compound between a low molecular compound and a high molecular compound with a molecular weight greater than or equal to 400 and less than or equal to 4000), or the like can be used, for example.

### Structure Example 1 of Electrode 551G(Ij) and Electrode 552

The material that can be used for the wiring or the like, for example, can be used for the electrode 551G(i,j) or the electrode 552. Specifically, a material having a visible-light-transmitting property can be used for the electrode 551G(i,j) or the electrode 552.

For example, a conductive oxide, a conductive oxide containing indium, indium oxide, indium tin oxide, indium zinc oxide, zinc oxide, zinc oxide to which gallium is added, or the like can be used. Alternatively, a metal film thin enough to transmit light can be used. Alternatively, a material having a visible-light-transmitting property can be used.

For example, a metal film that transmits part of light and reflects another part of the light can be used for the electrode 551G(i,j) or the electrode 552. The distance between the electrode 551G(i,j) and the electrode 552 is adjusted using the layer 553G(j) containing a light-emitting material, for example.

Thus, a microcavity structure can be provided in the light-emitting device 550G(i,j). Light of a predetermined wavelength can be extracted more efficiently than other light. Light with a narrow half width of a spectrum can be extracted. Light of a bright color can be extracted.

A film that efficiently reflects light, for example, can be used for the electrode 551G(i,j) or the electrode 552. Specifically, a material containing silver, palladium, and the like or a material containing silver, copper, and the like can be used for the metal film.

The electrode 551G(i,j) is electrically connected to the pixel circuit 530G(i,j) in the opening portion 591G(i,j) (see FIG. 7A). For example, the electrode 551G(i,j) overlaps with an opening portion formed in the insulating film 528, and the insulating film 528 is at the periphery of the electrode 551G(i,j).

Thus, a short circuit between the electrode 551G(i,j) and the electrode 552 can be prevented.

### Structure Example 2 of Electrode 551G(i,j) and Electrode 552

The electrode 551G(i,j) has a transmittance T1 and the electrode 552 has a transmittance T2. The transmittance T2 is higher than the transmittance T1.

Thus, light emitted from the light-emitting device 550G(i,j) can be extracted without through the functional layer 520. Alternatively, light emitted from the light-emitting device 550G(i,j) can be extracted efficiently without being blocked.

### Structure Example 2 of Functional Panel 700

The functional panel 700 includes the insulating film 528 and an insulating film 573 (see FIG. 7A).

### Structure Example 1 of Insulating Film 528

The insulating film 528 includes a region positioned between the functional layer 520 and the base material 770, and the insulating film 528 has an opening portion in a region overlapping with the light-emitting device 550G(i,j) (see FIG. 7A).

The material that can be used for the insulating film 521, for example, can be used for the insulating film 528. Specifically, a silicon oxide film, a film containing an acrylic resin, a film containing polyimide, or the like can be used as the insulating film 528.

### <<Insulating Film 573>>

The insulating film 573 includes a region where the light-emitting device 550G(i,j) is positioned between the functional layer 520 and the insulating film 573 (see FIG. 7A).

For example, a single film or a stacked film in which a plurality of films are stacked can be used as the insulating film 573. Specifically, a stacked film including an insulating film 573A, which can be formed by a method that hardly damages the light-emitting device 550G(i,j), and a dense insulating film 573B with a few defects, can be used as the insulating film 573. For example, an organic material can be used for the insulating film 573A. Furthermore, an inorganic material can be used for the insulating film 573B.

Thus, diffusion of impurities into the light-emitting device 550G(i,j) can be inhibited. The reliability of the light-emitting device 550G(i,j) can be increased.

### Structure Example 3 of Functional Panel 700

The functional panel 700 includes a functional layer 720 (see FIG. 7A).

<<Functional layer 720>>

The functional layer 720 includes a light-blocking film BM, the coloring film CF(G), and an insulating film 771. A color conversion layer can also be used.

### <<Light-Blocking Film BM>>

The light-blocking film BM includes an opening portion in a region overlapping with the pixel 702G(i,j). A material of a dark color can be used for the light-blocking film BM, for example. Thus, the display contrast can be increased.

### <<Coloring Film CF(G)>>

The coloring film CF(G) includes a region positioned between the base material 770 and the light-emitting device 550G(i,j). A material that selectively transmits light of a predetermined color, for example, can be used for the coloring film CF(G). Specifically, a material that transmits red light, green light, or blue light can be used for the coloring film CF(G).

### Structure Example of Insulating Film 771

The insulating film 771 includes a region positioned between the base material 770 and the light-emitting device 550G(i,j).

The insulating film 771 includes a region where the light-blocking film BM and the coloring film CF(G) are positioned between the base material 770 and the insulating film 771. Thus, unevenness due to the thicknesses of the light-blocking film BM and the coloring film CF(G) can be reduced.

### <<Color Conversion Layer>>

The color conversion layer includes a region positioned between the base material 770 and the light-emitting device 550G(i,j). Alternatively, the color conversion layer includes a region positioned between the coloring film CF(G) and the light-emitting device 550G(i,j).

For example, a material that emits light with a wavelength longer than a wavelength of incident light can be used for the color conversion layer. For example, a material that absorbs blue light or ultraviolet rays, converts it into green light, and emits the green light, a material that absorbs blue light or ultraviolet rays, converts it into red light, and emits the red light, or a material that absorbs ultraviolet rays, converts it into blue light, and emits the blue light can be used for the color conversion layer.

Specifically, a quantum dot with a diameter of several nanometers can be used for the color conversion layer. Thus, light having a spectrum with a narrow half width can be emitted. Light with high saturation can be emitted.

### Structure Example 4 of Functional Panel 700

The functional panel 700 includes a light-blocking film KBM (see FIG. 7A).

<<Light-blocking film KBM>>

The light-blocking film KBM includes an opening portion in a region overlapping with the pixel 702G(i,j), and also includes an opening portion in a region overlapping with another pixel adjacent to the pixel 702G(i,j). Moreover, the light-blocking film KBM includes a region positioned between the functional layer 520 and the base material 770, and has a function of providing a predetermined space between the functional layer 520 and the base material 770. A material of a dark color can be used for the light-blocking film KBM, for example. Thus, stray light that would enter an adjacent pixel from the pixel 702G(i,j) can be reduced.

### Structure Example 5 of Functional Panel 700

The functional panel 700 includes a functional film 770P (see FIG. 7A).

### <<Functional Film 770P and the Like>>

The functional film 770P includes a region overlapping with the light-emitting device 550G(i,j). The functional film 770P includes a region where the base material 770 is positioned between the light-emitting device 550G(i,j) and the functional film 770P.

An anti-reflection film, a polarizing film, a retardation film, a light diffusion film, a condensing film, or the like can be used as the functional film 770P, for example.

For example, an anti-reflection film with a thickness less than or equal to 1 m can be used as the functional film 770P. Specifically, a stacked film in which three or more layers, preferably five or more layers, further preferably 15 or more layers of dielectrics are stacked can be used as the functional film 770P. This allows the reflectance to be as low as 0.5% or less, preferably 0.08% or less.

For example, a circularly polarizing film can be used as the functional film 770P.

Furthermore, an antistatic film inhibiting the attachment of a dust, a water repellent film inhibiting the attachment of a stain, an oil repellent film inhibiting the attachment of a stain, an antireflective film (anti-reflection film), a non-glare film (anti-glare film), a hard coat film inhibiting generation of a scratch in use, a self-healing film that self-heals from generated scratches, or the like can be used as the functional film 770P.

### Structure Example 6 of Functional Panel 700

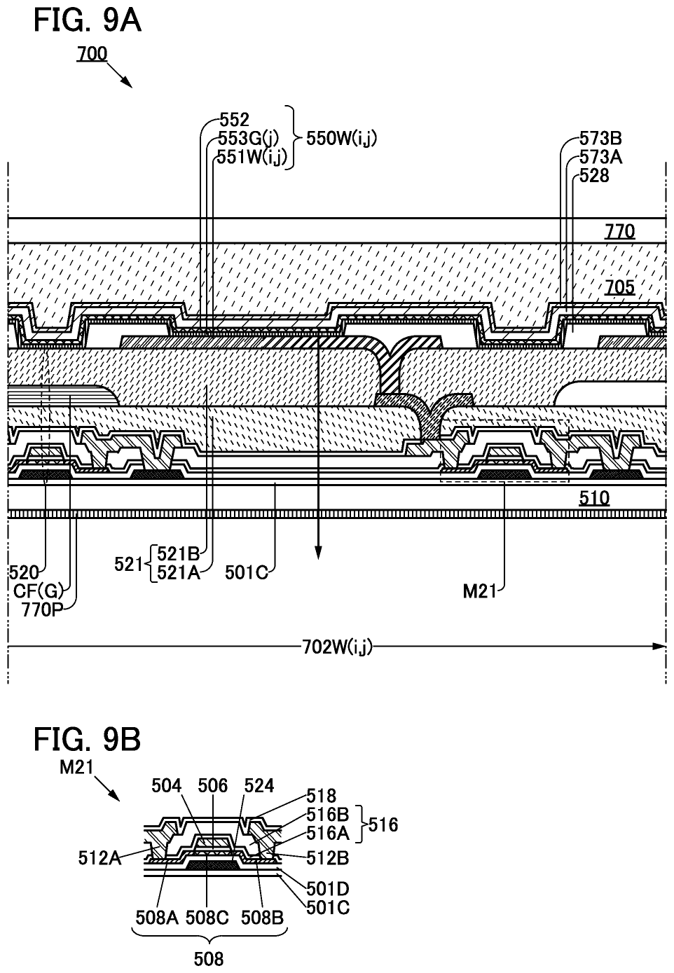

The functional panel 700 includes the insulating film 528 and the coloring film CF(G) (see FIG. 9A). The functional panel 700 includes the functional layer 520, and the functional layer 520 includes the transistor M21 (see FIG. 9A and FIG. 9B).

### Structure Example 2 of Insulating Film 528

The insulating film 528 includes a region positioned between the functional layer 520 and the base material 770, and the insulating film 528 includes an opening portion in a region overlapping with the light-emitting device 550W(i,j) (see FIG. 9A). The insulating film 528 includes an opening portion between the light-emitting device 550W(i,j) and another light-emitting device adjacent to the light-emitting device 550W(i,j). Thus, propagation of light emitted from the light-emitting device 550W(i,j) inside the insulating film 528 can be inhibited. Alternatively, stray light that would enter an adjacent pixel from the pixel 702W(i,j) can be reduced.

### Structure Example of Light-Emitting Device 550W(i,j)

The light-emitting device 550W(i,j) includes an electrode 551W(i,j), the electrode 552, and the layer 553G(j) (see FIG. 4C and FIG. 9A).

The electrode 551W(i,j) has the transmittance T1. The electrode 552 includes a region overlapping with the electrode 551W(i,j) and the electrode 552 has the transmittance T2. The transmittance T1 is higher than the transmittance T2. Note that the electrode 552 has a higher reflectance than the electrode 551W(i,j).

### Structure Example of Layer 553G(j)

The layer 553G(j) includes a region positioned between the electrode 551W(i,j) and the electrode 552.

The layer 553G(j) is different from the EL layer 553 described with reference to FIG. 2B in that a unit 103(13), a layer 105(13), and an intermediate layer 106(13) are provided between the intermediate layer 106 and the unit 103(12). For example, the structure that can be used for the unit 103 can be used for the unit 103(13), the structure that can be used for the layer 105 can be used for the layer 105(13), and the structure that can be used for the intermediate layer 106 can be used for the intermediate layer 106(13).

The layer 111 has a function of emitting the light EL1, a layer 111(12) has a function of emitting light EL1(2), a layer 111(13) has a function of emitting light EL1(3), and a layer 111(14) has a function of emitting light EL1(4).

For example, a light-emitting material that emits blue light can be used for the layer 111 and the layer 111(12). For example, a light-emitting material that emits yellow light can be used for the layer 111(13). For example, a light-emitting material that emits red light can be used for the layer 111(14).

Note that this embodiment can be combined with any of the other embodiments in this specification as appropriate.

### Embodiment 9

In this embodiment, a light-emitting apparatus including the light-emitting device described in any one of Embodiment 1 to Embodiment 5 is described.

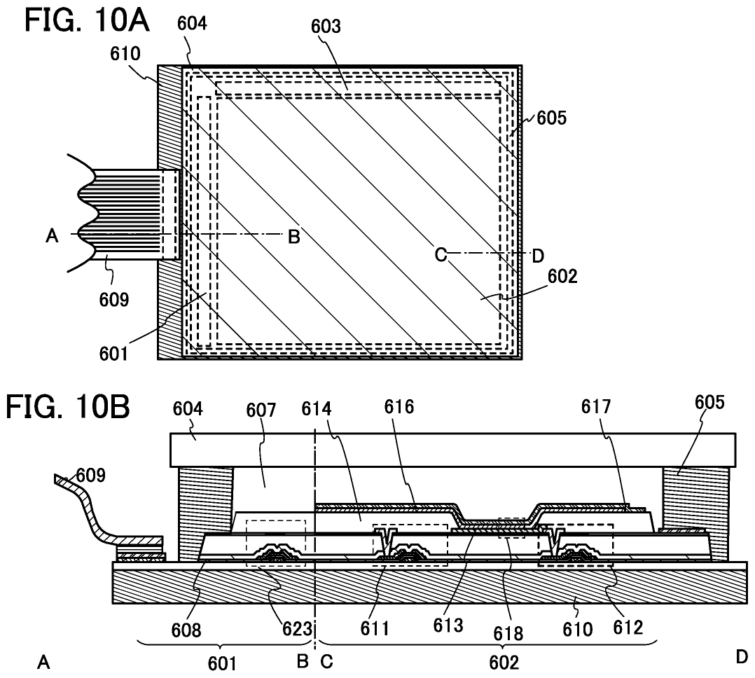

In this embodiment, a light-emitting apparatus fabricated using the light-emitting device described in any one of Embodiment 1 to Embodiment 5 is described with reference to FIG. 10. Note that FIG. 10A is a top view illustrating the light-emitting apparatus, and FIG. 10B is a cross-sectional view taken along A-B and C-D in FIG. 10A. This light-emitting apparatus includes a driver circuit portion (source line driver circuit 601), a pixel portion 602, and a driver circuit portion (gate line driver circuit 603), which are to control light emission of a light-emitting device and are illustrated with dotted lines. Furthermore, 604 denotes a sealing substrate, 605 denotes a sealant, and the inside surrounded by the sealant 605 is a space 607.

Note that a lead wiring 608 is a wiring for transmitting signals to be input to the source line driver circuit 601 and the gate line driver circuit 603 and receiving a video signal, a clock signal, a start signal, a reset signal, and the like from an FPC (flexible printed circuit) 609 serving as an external input terminal. Although only the FPC is illustrated here, a printed wiring board (PWB) may be attached to this FPC. The light-emitting apparatus in this specification includes not only the light-emitting apparatus itself but also the apparatus provided with the FPC or the PWB.

Next, a cross-sectional structure is described with reference to FIG. 10B. The driver circuit portion and the pixel portion are formed over an element substrate 610. Here, the source line driver circuit 601, which is the driver circuit portion, and one pixel of the pixel portion 602 are illustrated.

The element substrate 610 may be fabricated using a substrate containing glass, quartz, an organic resin, a metal, an alloy, a semiconductor, or the like, or a plastic substrate formed of FRP (Fiber Reinforced Plastic), PVF (polyvinyl fluoride), polyester, an acrylic resin, or the like.

There is no particular limitation on the structure of transistors used in pixels or driver circuits. For example, inverted staggered transistors or staggered transistors may be used. Furthermore, top-gate transistors or bottom-gate transistors may be used. There is no particular limitation on a semiconductor material used for the transistors, and for example, silicon, germanium, silicon carbide, gallium nitride, or the like can be used. Alternatively, an oxide semiconductor containing at least one of indium, gallium, and zinc, such as In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single-crystal semiconductor, and a semiconductor partly including crystal regions) may be used. A semiconductor having crystallinity is preferably used, in which case deterioration of the transistor characteristics can be suppressed.

Here, an oxide semiconductor is preferably used for semiconductor devices such as the transistors provided in the pixels or the driver circuits and transistors used for touch sensors described later, and the like. In particular, an oxide semiconductor having a wider band gap than silicon is preferably used. The use of an oxide semiconductor having a wider band gap than silicon can reduce the off-state current of the transistors.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such a material for the semiconductor layer makes it possible to achieve a highly reliable transistor in which a change in the electrical characteristics is reduced.

Charge accumulated in a capacitor through a transistor including the above-described semiconductor layer can be retained for a long time because of the low off-state current of the transistor. The use of such a transistor in pixels allows a driver circuit to stop while the gray level of an image displayed on each display region is maintained. As a result, an electronic apparatus with significantly reduced power consumption can be achieved.

For stable characteristics of the transistor or the like, a base film is preferably provided. The base film can be formed to be a single layer or a stacked layer using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film is not necessarily provided when not needed.

Note that an FET 623 is illustrated as a transistor formed in the source line driver circuit 601. The driver circuit can be formed using various circuits such as a CMOS circuit, a PMOS circuit, and an NMOS circuit. Although a driver-integrated type in which the driver circuit is formed over the substrate is described in this embodiment, the driver circuit is not necessarily formed over the substrate and can be formed outside.

The pixel portion 602 is formed with a plurality of pixels including a switching FET 611, a current control FET 612, and a first electrode 613 electrically connected to a drain of the current control FET 612; however, without being limited thereto, a pixel portion in which three or more FETs and a capacitor are combined may be employed.

Note that an insulator 614 is formed to cover an end portion of the first electrode 613. The insulator 614 can be formed using a positive photosensitive acrylic resin film here.

In order to improve the coverage with an EL layer or the like to be formed later, the insulator 614 is formed so as to have a curved surface with curvature at its upper end portion or lower end portion. For example, in the case where a positive photosensitive acrylic resin is used as a material for the insulator 614, only the upper end portion of the insulator 614 preferably has a curved surface with a curvature radius (greater than or equal to 0.2 μm and less than or equal to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material with a high work function is desirably used. For example, a single-layer film of an ITO film, an indium tin oxide film containing silicon, an indium oxide film containing zinc oxide at 2 wt % or higher and 20 wt % or lower, a titanium nitride film, a chromium film, a tungsten film, a Zn film, a Pt film, or the like, a stacked layer of a titanium nitride film and a film containing aluminum as its main component, a three-layer structure of a titanium nitride film, a film containing aluminum as its main component, and a titanium nitride film, or the like can be used. Note that the stacked-layer structure achieves low wiring resistance, a favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiment 1 to Embodiment 5. Alternatively, a material included in the EL layer 616 may be a low molecular compound or a high molecular compound (including an oligomer or a dendrimer).

As a material used for the second electrode 617, which is formed over the EL layer 616 and functions as a cathode, a material with a low work function (e.g., Al, Mg, Li, Ca, or an alloy or a compound thereof (e.g., MgAg, MgIn, or AlLi)) is preferably used. Note that in the case where light generated in the EL layer 616 passes through the second electrode 617, it is preferable to use, for the second electrode 617, a stacked layer of a thin metal film and a transparent conductive film (e.g., ITO, indium oxide containing zinc oxide at 2 wt % or higher and 20 wt % or lower, indium tin oxide containing silicon, or zinc oxide (ZnO)).

Note that a light-emitting device 618 is formed with the first electrode 613, the EL layer 616, and the second electrode 617. The light-emitting device is the light-emitting device described in any one of Embodiment 1 to Embodiment 5. A plurality of light-emitting devices are formed in the pixel portion, and the light-emitting apparatus of this embodiment may include both the light-emitting device described in any one of Embodiment 1 to Embodiment 5 and a light-emitting device having a different structure.

The sealing substrate 604 and the element substrate 610 are attached to each other using the sealant 605, so that a structure is employed in which a light-emitting device 618 is provided in the space 607 surrounded by the element substrate 610, the sealing substrate 604, and the sealant 605. The space 607 is filled with a filler; it is filled with an inert gas (e.g., nitrogen or argon) in some cases, and filled with the sealant in some cases. The structure of the sealing substrate in which a recessed portion is formed and a desiccant is provided is preferable because deterioration due to the influence of moisture can be inhibited.

Note that an epoxy resin or glass frit is preferably used for the sealant 605. Furthermore, these materials are preferably materials that transmit moisture and oxygen as little as possible. As the material used for the sealing substrate 604, in addition to a glass substrate and a quartz substrate, a plastic substrate formed of FRP (Fiber Reinforced Plastics), PVF (polyvinyl fluoride), polyester, an acrylic resin, or the like can be used.

Although not illustrated in FIG. 10, a protective film may be provided over the second electrode. The protective film may be formed using an organic resin film or an inorganic insulating film. The protective film may be formed so as to cover an exposed portion of the sealant 605. The protective film may be provided so as to cover surfaces and side surfaces of the pair of substrates and exposed side surfaces of a sealing layer, an insulating layer, and the like.

For the protective film, a material that is less likely to transmit an impurity such as water can be used. Thus, diffusion of an impurity such as water from the outside into the inside can be effectively inhibited.

As a material included in the protective film, an oxide, a nitride, a fluoride, a sulfide, a ternary compound, a metal, a polymer, or the like can be used; for example, it is possible to use a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like; a material containing aluminum nitride, hafnium nitride, silicon nitride, tantalum nitride, titanium nitride, niobium nitride, molybdenum nitride, zirconium nitride, gallium nitride, or the like; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method that enables favorable step coverage. One such method is an atomic layer deposition (ALD) method. A material that can be formed by an ALD method is preferably used for the protective film. With the use of an ALD method, a dense protective film with reduced defects such as cracks or pinholes or with a uniform thickness can be formed. Furthermore, damage caused to a process member in forming the protective film can be reduced.

By an ALD method, a uniform protective film with few defects can be formed even on a surface with a complex uneven shape or upper, side, and lower surfaces of a touch panel.

As described above, the light-emitting apparatus fabricated using the light-emitting device described in any one of Embodiment 1 to Embodiment 5 can be obtained.

For the light-emitting apparatus in this embodiment, the light-emitting device described in any one of Embodiment 1 to Embodiment 5 is used and thus a light-emitting apparatus having favorable characteristics can be obtained. Specifically, since the light-emitting device described in any one of Embodiment 1 to Embodiment 5 has favorable emission efficiency, the light-emitting apparatus with low power consumption can be obtained.

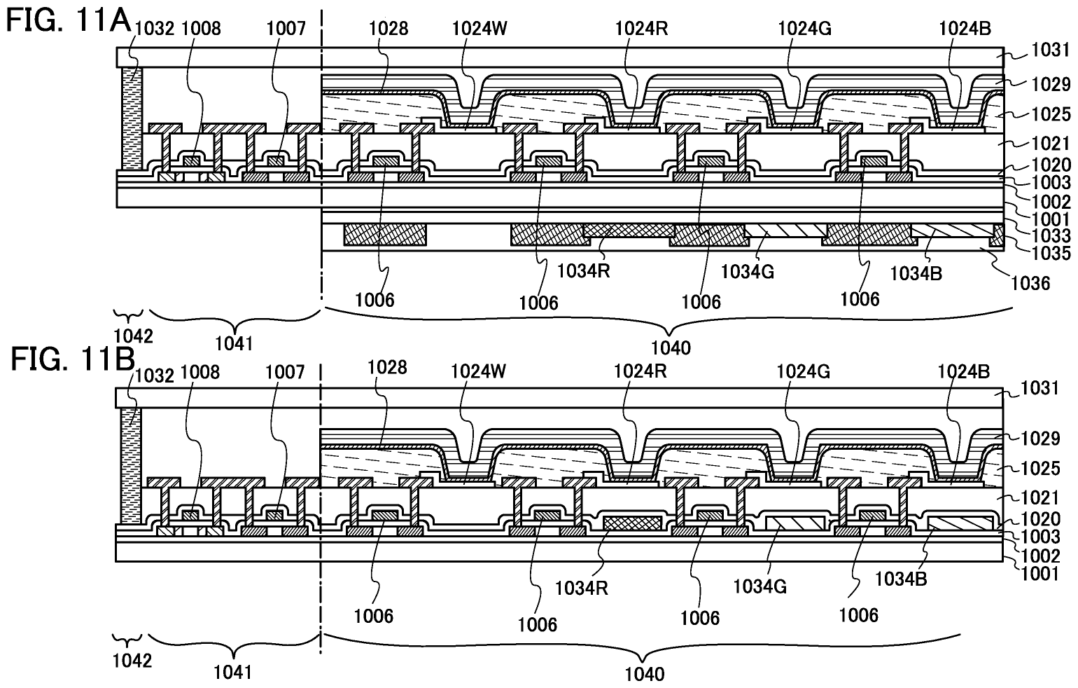

FIG. 11 illustrates examples of a light-emitting apparatus in which full color display is achieved by formation of a light-emitting device exhibiting white light emission and provision of coloring films (color filters) and the like. FIG. 11A illustrates a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of the light-emitting devices, a partition 1025, an EL layer 1028, a second electrode 1029 of the light-emitting devices, a sealing substrate 1031, a sealant 1032, and the like.

In FIG. 11A, coloring films (a red coloring film 1034R, a green coloring film 1034G, and a blue coloring film 1034B) are provided on a transparent base material 1033. A black matrix 1035 may be additionally provided. The transparent base material 1033 provided with the coloring films and the black matrix is positioned and fixed to the substrate 1001. Note that the coloring films and the black matrix 1035 are covered with an overcoat layer 1036. In FIG. 11A, a light-emitting layer from which light is emitted to the outside without passing through the coloring film and light-emitting layers from which light is emitted to the outside, passing through the coloring films of the respective colors are shown. Since light that does not pass through the coloring film is white and light that passes through the coloring film is red, green, or blue, an image can be expressed by pixels of the four colors.

FIG. 11B shows an example in which the coloring films (the red coloring film 1034R, the green coloring film 1034G, and the blue coloring film 1034B) are formed between the gate insulating film 1003 and the first interlayer insulating film 1020. The coloring films may be provided between the substrate 1001 and the sealing substrate 1031 in this manner.

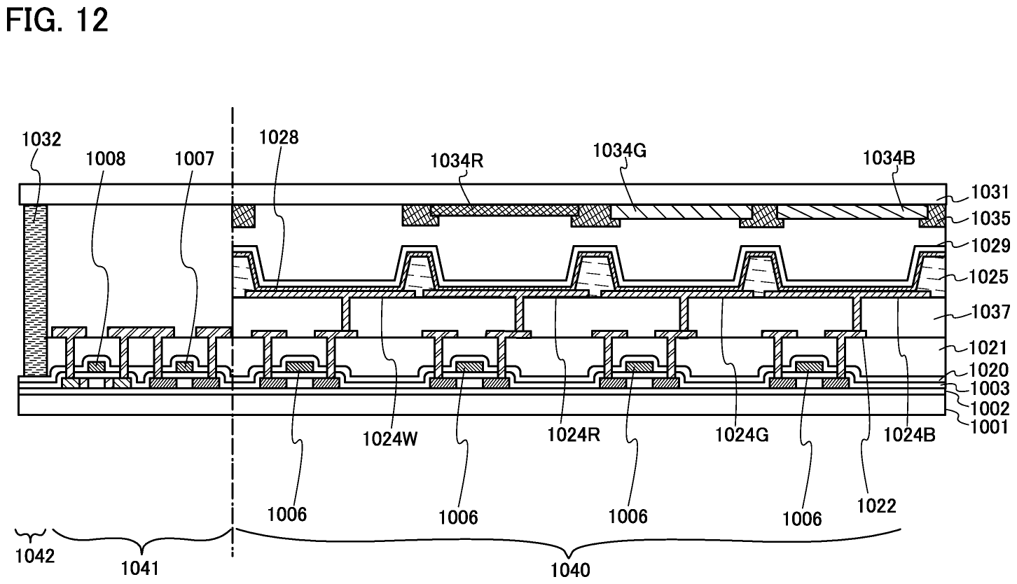

The above-described light-emitting apparatus is a light-emitting apparatus having a structure in which light is extracted to the substrate 1001 side where the FETs are formed (a bottom-emission type), but may be a light-emitting apparatus having a structure in which light emission is extracted to the sealing substrate 1031 side (a top-emission type). FIG. 12 shows a cross-sectional view of a top-emission light-emitting apparatus. In this case, a substrate that does not transmit light can be used as the substrate 1001. The top-emission light-emitting apparatus is formed in a manner similar to that of the bottom-emission light-emitting apparatus until a connection electrode which connects the FET and the anode of the light-emitting device is formed. Then, a third interlayer insulating film 1037 is formed to cover an electrode 1022. This insulating film may have a planarization function. The third interlayer insulating film 1037 can be formed using a material similar to that for the second interlayer insulating film or using any other known materials.

The first electrodes 1024W, 1024R, 1024G, and 1024B of the light-emitting devices are each an anode here, but may each be a cathode. Furthermore, in the case of the top-emission light-emitting apparatus illustrated in FIG. 12, the first electrodes are preferably reflective electrodes. The structure of the EL layer 1028 is such a structure as that of the unit 103 described in any one of Embodiment 1 to Embodiment 5, and an element structure with which white light emission can be obtained.

In the case of such a top-emission structure as in FIG. 12, sealing can be performed with the sealing substrate 1031 on which the coloring films (the red coloring film 1034R, the green coloring film 1034G, and the blue coloring film 1034B) are provided. The sealing substrate 1031 may be provided with the black matrix 1035 which is positioned between pixels. The coloring films (the red coloring film 1034R, the green coloring film 1034G, and the blue coloring film 1034B) or the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display may be performed using four colors of red, yellow, green, and blue or three colors of red, green, and blue.

In the top-emission-type light-emitting apparatus, a microcavity structure can be favorably employed. A light-emitting device with a microcavity structure can be obtained with the use of a reflective electrode as the first electrode and a semi-transmissive and semi-reflective electrode as the second electrode. The light-emitting device with a microcavity structure includes at least an EL layer between the reflective electrode and the semi-transmissive and semi-reflective electrode, which includes at least a light-emitting layer serving as a light-emitting region.

Note that the reflective electrode is a film having a visible light reflectivity of 40% to 100%, preferably 70% to 100%, and a resistivity of 1×10⁻² Ωcm or lower. In addition, the semi-transmissive and semi-reflective electrode is a film having a visible light reflectivity of 20% to 80%, preferably 40% to 70%, and a resistivity of 1×10⁻² Ωcm or lower.

Light emitted from the light-emitting layer included in the EL layer is reflected and resonated by the reflective electrode and the semi-transmissive and semi-reflective electrode.

In the light-emitting device, by changing thicknesses of the transparent conductive film, the above-described composite material, the carrier-transport material, or the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light); therefore, the optical path length between the reflective electrode and the light-emitting layer is preferably adjusted to (2n−1)λ/4 (n is a natural number of 1 or larger and λ is a wavelength of light emission to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer; for example, in combination with the structure of the above-described tandem light-emitting device, a plurality of EL layers each including a single or a plurality of light-emitting layer(s) may be provided in one light-emitting device with a charge-generation layer interposed between the EL layers.

With the microcavity structure, emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because a microcavity structure suitable for wavelengths of the corresponding color is employed in each subpixel, in addition to the effect of an improvement in luminance owing to yellow light emission.

For the light-emitting apparatus in this embodiment, the light-emitting device described in any one of Embodiment 1 to Embodiment 5 is used and thus a light-emitting apparatus having favorable characteristics can be obtained. Specifically, since the light-emitting device described in any one of Embodiment 1 to Embodiment 5 has favorable emission efficiency, the light-emitting apparatus with low power consumption can be obtained.

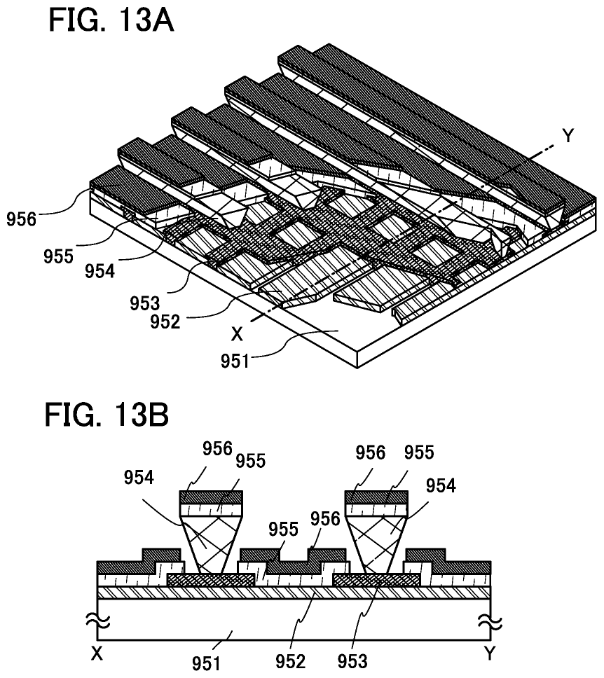

The active matrix light-emitting apparatus is described above, whereas a passive matrix light-emitting apparatus is described below. FIG. 13 illustrates a passive matrix light-emitting apparatus fabricated using the present invention. Note that FIG. 13A is a perspective view illustrating the light-emitting apparatus, and FIG. 13B is a cross-sectional view taken along X-Y in FIG. 13A. In FIG. 13, over a substrate 951, an EL layer 955 is provided between an electrode 952 and an electrode 956. An end portion of the electrode 952 is covered with an insulating layer 953. A partition layer 954 is provided over the insulating layer 953. Sidewalls of the partition layer 954 are aslope such that the distance between one sidewall and the other sidewall is gradually narrowed toward the surface of the substrate. That is, a cross section in the short side direction of the partition layer 954 is a trapezoidal shape, and the lower side (the side facing the same direction as the plane direction of the insulating layer 953 and touching the insulating layer 953) is shorter than the upper side (the side facing the same direction as the plane direction of the insulating layer 953, and not touching the insulating layer 953). By providing the partition layer 954 in this manner, defects of the light-emitting device due to static charge or the like can be prevented. The passive-matrix light-emitting apparatus also uses the light-emitting device described in any one of Embodiment 1 to Embodiment 5; thus, the light-emitting apparatus can have favorable reliability or low power consumption.

Since many minute light-emitting devices arranged in a matrix can each be controlled in the light-emitting apparatus described above, the light-emitting apparatus can be suitably used as a display device for displaying images.

This embodiment can be freely combined with any of the other embodiments.

### Embodiment 10

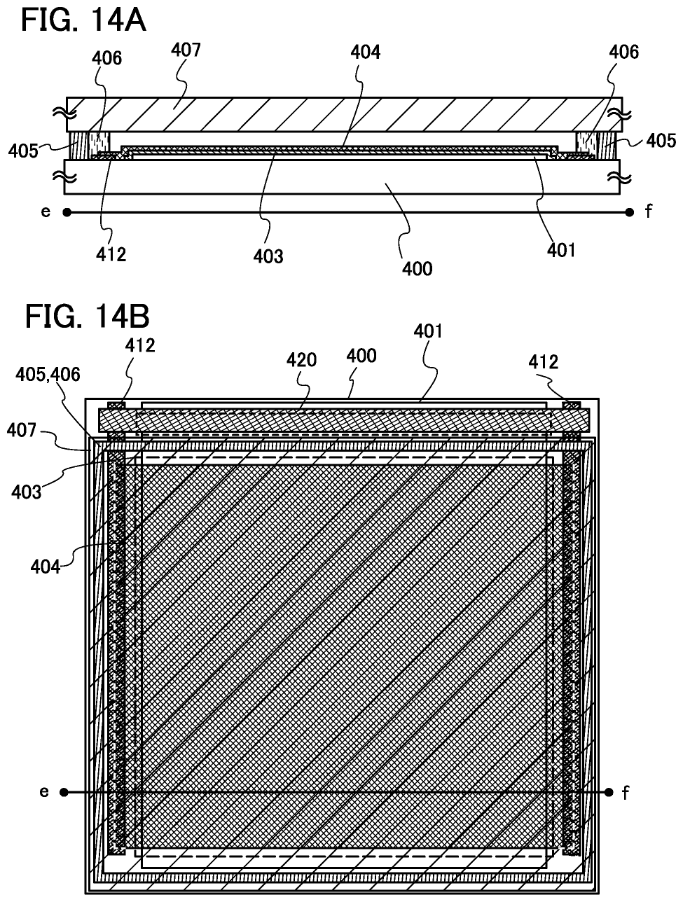

In this embodiment, an example in which the light-emitting device described in any one of Embodiment 1 to Embodiment 5 is used for a lighting device is described with reference to FIG. 14. FIG. 14B is a top view of the lighting device, and FIG. 14A is a cross-sectional view taken along e-f in FIG. 14B.

In the lighting device in this embodiment, a first electrode 401 is formed over a substrate 400 which is a support and has a light-transmitting property. The first electrode 401 corresponds to the first electrode 101 in any one of Embodiment 1 to Embodiment 5. In the case where light emission is extracted from the first electrode 401 side, the first electrode 401 is formed with a material having a light-transmitting property.

A pad 412 for supplying a voltage to a second electrode 404 is formed over the substrate 400.

An EL layer 403 is formed over the first electrode 401. The EL layer 403 has a structure corresponding to the structure of the unit 103 in any one of Embodiment 1 to Embodiment 5, the structure in which the unit 103(12) and the intermediate layer 106 are combined, or the like. Note that for these structures, the corresponding description can be referred to.

The second electrode 404 is formed to cover the EL layer 403. The second electrode 404 corresponds to the electrode 102 in any one of Embodiment 1 to Embodiment 5. In the case where light emission is extracted from the first electrode 401 side, the second electrode 404 is formed with a material having high reflectivity. The second electrode 404 is supplied with a voltage when connected to the pad 412.

As described above, the lighting device described in this embodiment includes a light-emitting device including the first electrode 401, the EL layer 403, and the second electrode 404. Since the light-emitting device is a light-emitting device with high emission efficiency, the lighting device in this embodiment can be a lighting device with low power consumption.

The substrate 400 over which the light-emitting device having the above structure is formed is fixed to a sealing substrate 407 with sealants 405 and 406 and sealing is performed, whereby the lighting device is completed. It is possible to use only either the sealant 405 or 406. In addition, the inner sealant 406 (not shown in FIG. 14B) can be mixed with a desiccant, which enables moisture to be adsorbed, resulting in improved reliability.

When parts of the pad 412 and the first electrode 401 are provided to extend to the outside of the sealants 405 and 406, those can serve as external input terminals. An IC chip 420 or the like mounted with a converter or the like may be provided over the external input terminals.

The lighting device described in this embodiment uses the light-emitting device described in any one of Embodiment 1 to Embodiment 5 as an EL element; thus, the light-emitting apparatus can have low power consumption.

### Embodiment 11

In this embodiment, examples of electronic devices each partly including the light-emitting device described in any one of Embodiment 1 to Embodiment 5 are described. The light-emitting device described in any one of Embodiment 1 to Embodiment 5 is a light-emitting device with favorable emission efficiency and low power consumption. As a result, the electronic devices described in this embodiment can be electronic devices each including a light-emitting portion with low power consumption.

Examples of electronic devices to which the light-emitting device is applied include a television devices (also referred to as TV or television receivers), monitors for computers and the like, digital cameras, digital video cameras, digital photo frames, mobile phones (also referred to as portable telephones or portable telephone devices), portable game machines, portable information terminals, audio playback devices, and large game machines such as pachinko machines. Specific examples of these electronic devices are shown below.

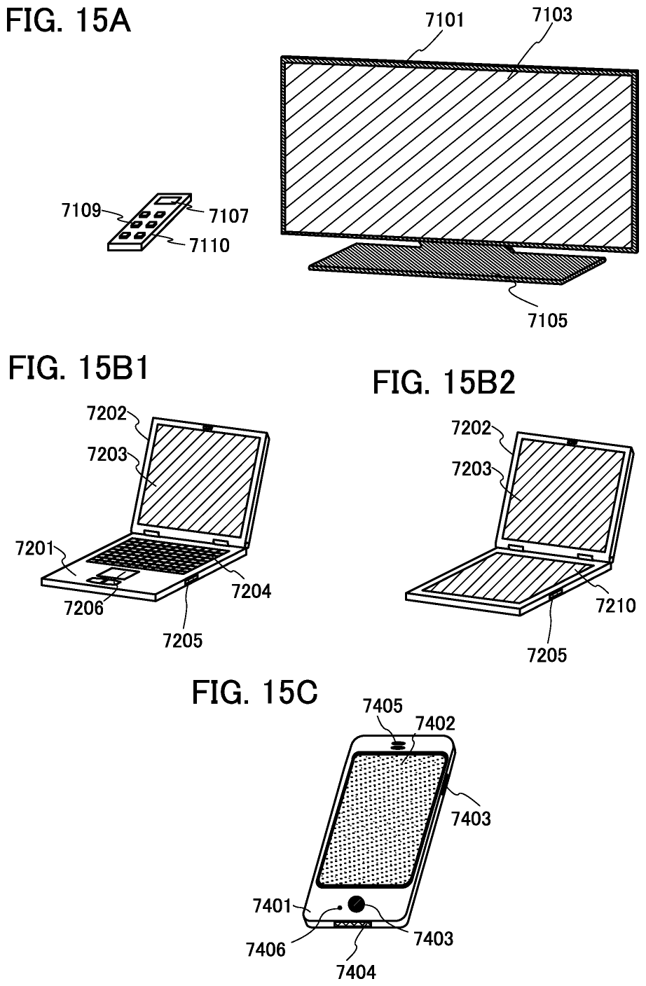

FIG. 15A shows an example of a television device. In the television device, a display portion 7103 is incorporated in a housing 7101. Here, a structure in which the housing 7101 is supported by a stand 7105 is shown. Images can be displayed on the display portion 7103, and the light-emitting devices described in any one of Embodiment 1 to Embodiment 5 are arranged in a matrix in the display portion 7103.

The television device can be operated with an operation switch of the housing 7101 or a separate remote controller 7110. With operation keys 7109 of the remote controller 7110, channels and volume can be operated and images displayed on the display portion 7103 can be operated. Furthermore, a structure may be employed in which the remote controller 7110 is provided with a display portion 7107 for displaying data output from the remote controller 7110.

Note that the television device has a structure of including a receiver, a modem, or the like. With the use of the receiver, a general television broadcast can be received, and moreover, when the television device is connected to a communication network with or without a wire via the modem, one-way (from a sender to a receiver) or two-way (between a sender and a receiver or between receivers) data communication can be performed.

FIG. 15B1 is a computer which includes a main body 7201, a housing 7202, a display portion 7203, a keyboard 7204, an external connection port 7205, a pointing device 7206, and the like. Note that this computer is fabricated using the light-emitting devices described in any one of Embodiment 1 to Embodiment 5 arranged in a matrix in the display portion 7203. The computer in FIG. 15B1 may be such a mode as illustrated in FIG. 15B2. The computer in FIG. 15B2 is provided with a second display portion 7210 instead of the keyboard 7204 and the pointing device 7206. The second display portion 7210 is of a touch-panel type, and input can be performed by operating display for input displayed on the second display portion 7210 with a finger or a dedicated pen. The second display portion 7210 can also display images other than the display for input. The display portion 7203 may also be a touch panel. Connecting the two screens with a hinge can prevent troubles such as a crack in or damage to the screens caused when the computer is stored or carried.

FIG. 15C shows an example of a portable terminal. A portable terminal includes operation buttons 7403, an external connection port 7404, a speaker 7405, a microphone 7406, and the like in addition to a display portion 7402 incorporated in a housing 7401. Note that a portable terminal includes the display portion 7402 which is fabricated by arranging the light-emitting devices described in any one of Embodiment 1 to Embodiment 5 in a matrix.

The portable terminal illustrated in FIG. 15C may have a structure in which information can be input by touching the display portion 7402 with a finger or the like. In this case, operations such as making a call and creating an e-mail can be performed by touching the display portion 7402 with a finger or the like.

The display portion 7402 has mainly three screen modes. The first one is a display mode mainly for displaying images, and the second one is an input mode mainly for inputting data such as text. The third one is a display+input mode in which two modes of the display mode and the input mode are combined.

For example, in the case of making a call or creating an e-mail, a text input mode mainly for inputting text is selected for the display portion 7402 so that an operation of inputting characters displayed on the screen may be performed. In this case, it is preferable to display a keyboard or number buttons on the entire screen of the display portion 7402.

When a sensing device including a sensor for sensing inclination, such as a gyroscope sensor or an acceleration sensor, is provided inside the portable terminal, screen display of the display portion 7402 can be automatically changed by determining the orientation of the portable terminal (vertically or horizontally).

The screen modes are changed by touching the display portion 7402 or operating the operation buttons 7403 of the housing 7401. Alternatively, the screen modes can be changed depending on the kind of image displayed on the display portion 7402. For example, when a signal of an image displayed on the display portion is moving image data, the screen mode is changed to the display mode, and when the signal is text data, the screen mode is changed to the input mode.

Moreover, in the input mode, when input by the touch operation of the display portion 7402 is not performed for a certain period while a signal sensed by an optical sensor in the display portion 7402 is sensed, the screen mode may be controlled so as to be changed from the input mode to the display mode.

The display portion 7402 can also function as an image sensor. For example, an image of a palm print, a fingerprint, or the like is taken when the display portion 7402 is touched with the palm or the finger, whereby personal authentication can be performed. Furthermore, by using a backlight which emits near-infrared light or a sensing light source which emits near-infrared light in the display portion, an image of a finger vein, a palm vein, or the like can be taken.

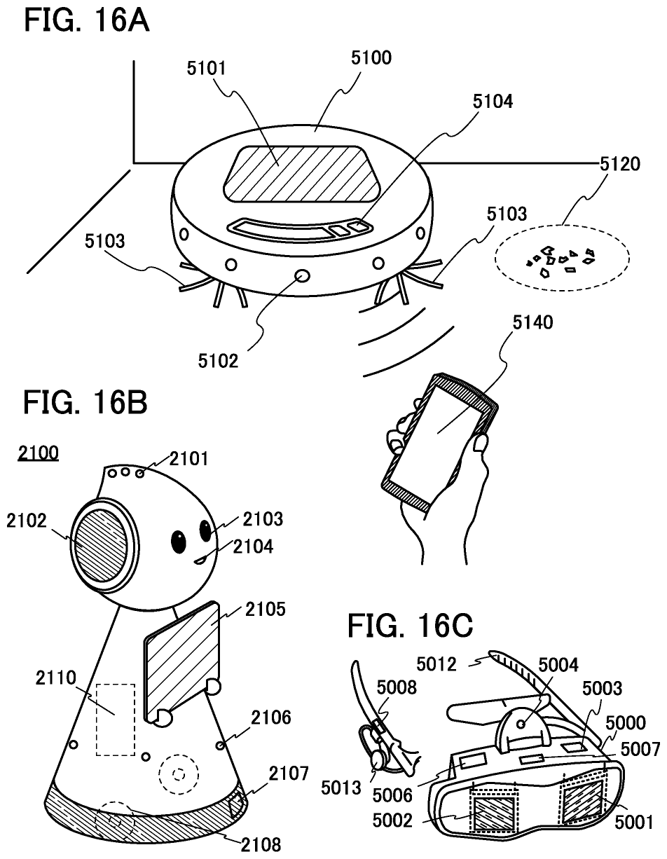

FIG. 16A is a schematic view showing an example of a cleaning robot.

A cleaning robot 5100 includes a display 5101 placed on its top surface, a plurality of cameras 5102 placed on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. In addition, the cleaning robot 5100 has a wireless communication means.

The cleaning robot 5100 is self-propelled, detects dust 5120, and sucks up the dust through the inlet provided on the bottom surface.

The cleaning robot 5100 can judge whether there is an obstacle such as a wall, furniture, or a step by analyzing images taken by the cameras 5102. When an object that is likely to be caught in the brush 5103, such as a wire, is detected by image analysis, the rotation of the brush 5103 can be stopped.

The display 5101 can display the remaining capacity of a battery, the amount of vacuumed dust, or the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. The portable electronic device 5140 can display images taken by the cameras 5102. Accordingly, an owner of the cleaning robot 5100 can monitor the room even from the outside. The display on the display 5101 can be checked by the portable electronic device such as a smartphone.

The light-emitting apparatus of one embodiment of the present invention can be used for the display 5101.

A robot 2100 illustrated in FIG. 16B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect the presence of an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 16C shows an example of a goggle-type display. The goggle-type display includes, for example, a housing 5000, a display portion 5001, a speaker 5003, an LED lamp 5004, operation keys (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, a chemical substance, sound, time, hardness, an electric field, current, voltage, power, radiation, flow rate, humidity, gradient, oscillation, odor, or infrared ray), a microphone 5008, a display portion 5002, a support 5012, and an earphone 5013.

The light-emitting apparatus of one embodiment of the present invention can be used for the display portion 5001 and the display portion 5002.

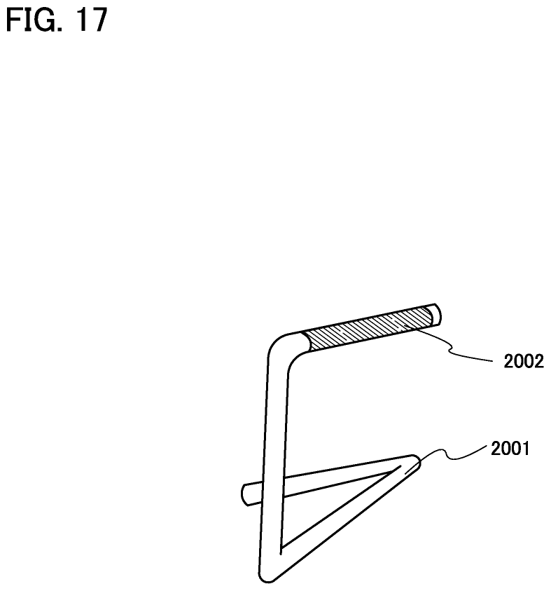

FIG. 17 shows an example in which the light-emitting device described in any one of Embodiment 1 to Embodiment 5 is used for a table lamp which is a lighting device. The table lamp illustrated in FIG. 17 includes a housing 2001 and a light source 2002, and the lighting device described in Embodiment 7 may be used for the light source 2002.

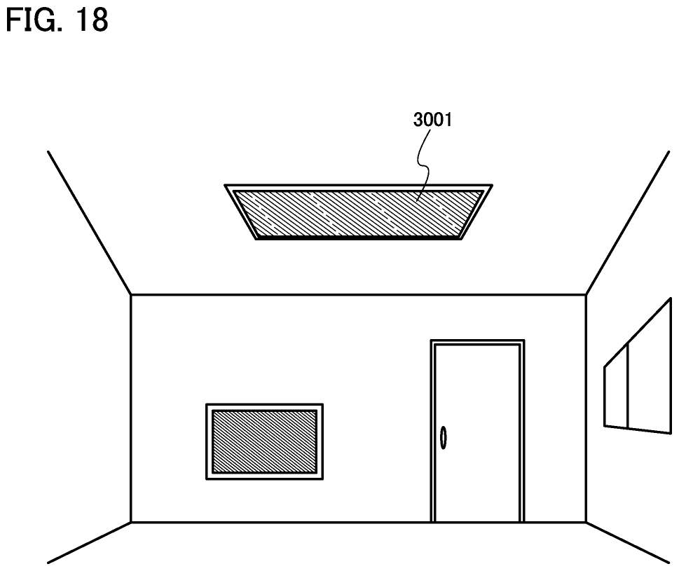

FIG. 18 shows an example in which the light-emitting device described in any one of Embodiment 1 to Embodiment 5 is used for an indoor lighting device 3001. Since the light-emitting device described in any one of Embodiment 1 to Embodiment 5 is a light-emitting device with high emission efficiency, the lighting device can have low power consumption. Furthermore, the light-emitting device described in any one of Embodiment 1 to Embodiment 5 can have a larger area, and thus can be used for a large-area lighting device. Furthermore, the light-emitting device described in any one of Embodiment 1 to Embodiment 5 is thin, and thus can be used for a lighting device having a reduced thickness.

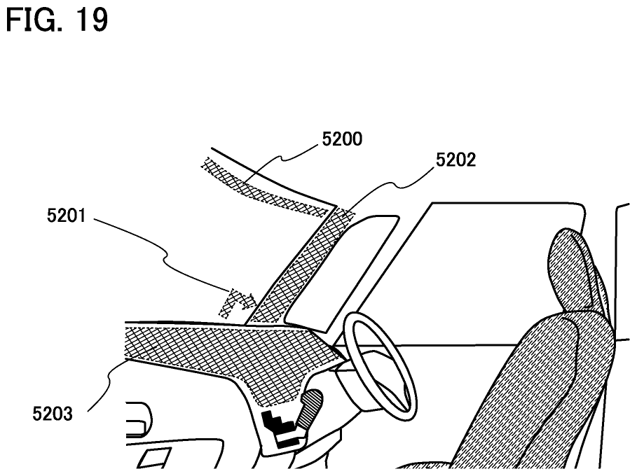

The light-emitting device described in any one of Embodiment 1 to Embodiment 5 can also be incorporated in an automobile windshield or an automobile dashboard. FIG. 19 illustrates one mode in which the light-emitting device described in any one of Embodiment 1 to Embodiment 5 is used for a windshield or a dashboard of an automobile. A display region 5200 to a display region 5203 are each display provided using the light-emitting device described in any one of Embodiment 1 to Embodiment 5.

The display region 5200 and the display region 5201 are display devices provided in the automobile windshield, in which the light-emitting devices described in any one of Embodiment 1 to Embodiment 5 are incorporated. When the light-emitting devices described in any one of Embodiment 1 to Embodiment 5 are fabricated using electrodes having light-transmitting properties as a first electrode and a second electrode, what is called see-through display devices, through which the opposite side can be seen, can be obtained. See-through display can be provided without hindering the vision even when being provided in the automobile windshield. Note that in the case where a driving transistor or the like is provided, a transistor having a light-transmitting property, such as an organic transistor using an organic semiconductor material or a transistor using an oxide semiconductor, is preferably used.

The display region 5202 is a display device provided in a pillar portion, in which the light-emitting devices described in any one of Embodiment 1 to Embodiment 5 are incorporated. The display region 5202 can compensate for the view hindered by the pillar by displaying an image taken by an imaging means provided on the car body. Similarly, the display region 5203 provided in the dashboard portion can compensate for the view hindered by the car body by displaying an image taken by an imaging means provided on the outside of the automobile. Thus, blind areas can be compensated for and the safety can be enhanced. Showing an image so as to compensate for the area that cannot be seen makes it possible to confirm safety more naturally and comfortably.

The display region 5203 can provide a variety of kinds of information by displaying navigation data, a speedometer, a tachometer, a mileage, a fuel meter, a gearshift state, air-condition setting, and the like. The content or layout of the display can be changed freely in accordance with the preference of a user. Note that such information can also be provided on the display region 5200 to the display region 5202. The display region 5200 to the display region 5203 can also be used as lighting devices.

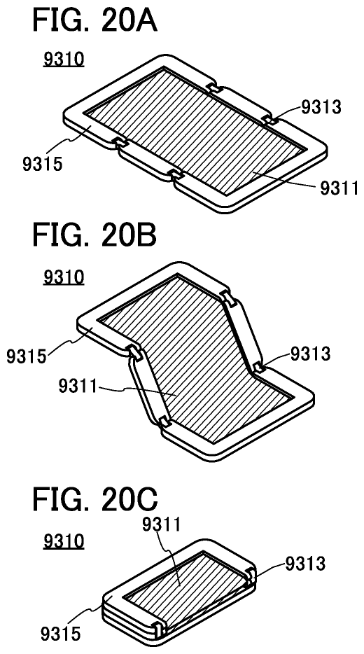

FIG. 20A to FIG. 20C illustrate a foldable portable information terminal 9310. FIG. 20A illustrates the portable information terminal 9310 that is opened. FIG. 20B illustrates the portable information terminal 9310 that is in the state of being changed from one of an opened state and a folded state to the other. FIG. 20C illustrates the portable information terminal 9310 that is folded. The portable information terminal 9310 is excellent in portability when folded, and is excellent in display browsability when opened because of a seamless large display region.

A functional panel 9311 is supported by three housings 9315 joined together by hinges 9313. Note that the functional panel 9311 may be a touch panel (an input/output device) including a touch sensor (an input device). By folding the functional panel 9311 at the hinges 9313 between two housings 9315, the portable information terminal 9310 can be reversibly changed in shape from the opened state to the folded state. A light-emitting apparatus of one embodiment of the present invention can be used for the functional panel 9311.

Note that the structures described in this embodiment can be combined with the structures described in any of Embodiment 1 to Embodiment 5 as appropriate.

As described above, the application range of the light-emitting apparatus including the light-emitting device described in any one of Embodiment 1 to Embodiment 5 is wide, so that this light-emitting apparatus can be applied to electronic devices in a variety of fields. With the use of the light-emitting device described in any one of Embodiment 1 to Embodiment 5, an electronic device with low power consumption can be obtained.

Note that this embodiment can be combined with any of the other embodiments in this specification as appropriate.

### Example 1

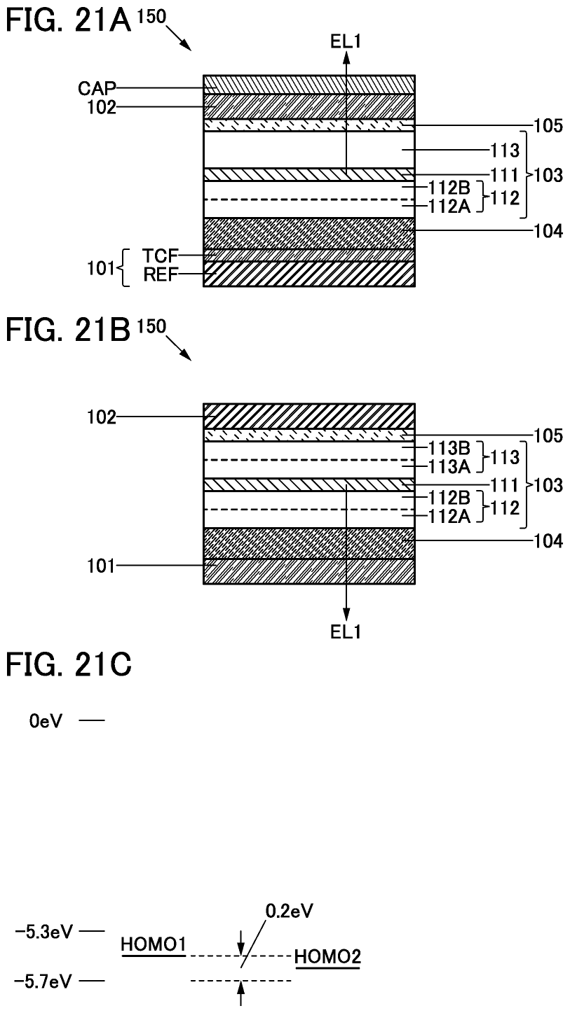

In this example, a structure of a light-emitting device of one embodiment of the present invention is described with reference to FIG. 21 to FIG. 29.

FIG. 21A to FIG. 21C are diagrams illustrating structures of light-emitting devices.

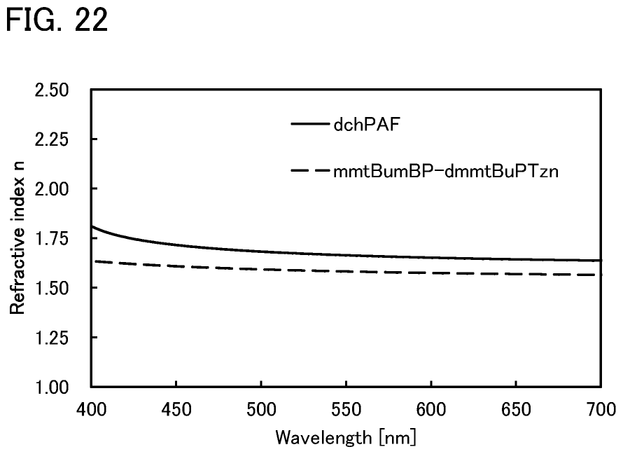

FIG. 22 is a graph showing wavelength-refractive index characteristics of materials.

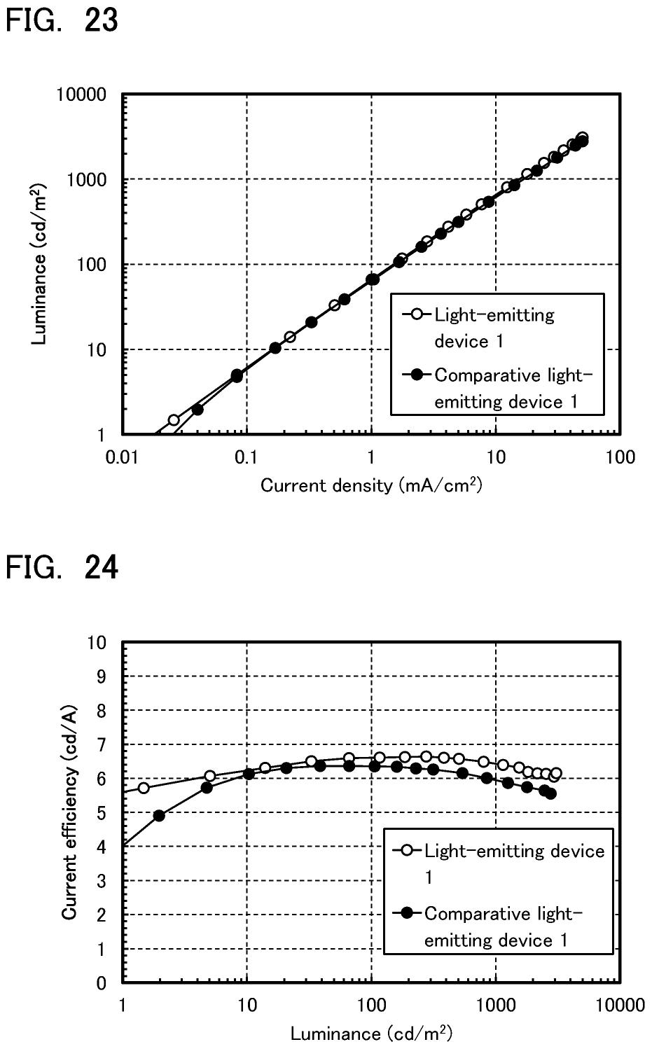

FIG. 23 is a graph showing current density-luminance characteristics of a light-emitting device 1 and a comparative light-emitting device 1.

FIG. 24 is a graph showing luminance-current efficiency characteristics of the light-emitting device 1 and the comparative light-emitting device 1.

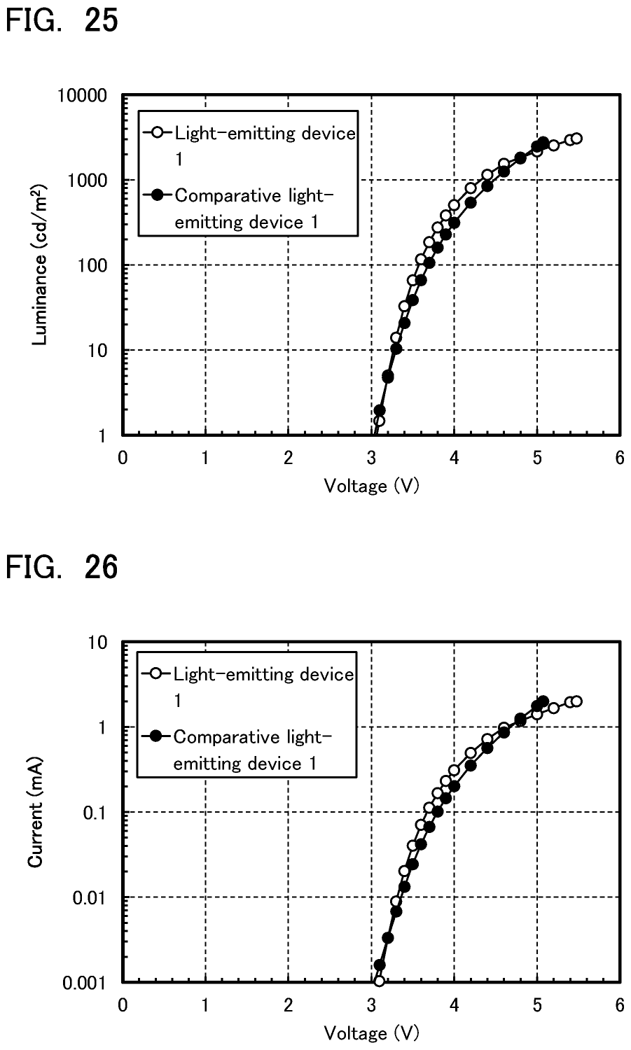

FIG. 25 is a graph showing voltage-luminance characteristics of the light-emitting device 1 and the comparative light-emitting device 1.

FIG. 26 is a graph showing voltage-current characteristics of the light-emitting device 1 and the comparative light-emitting device 1.

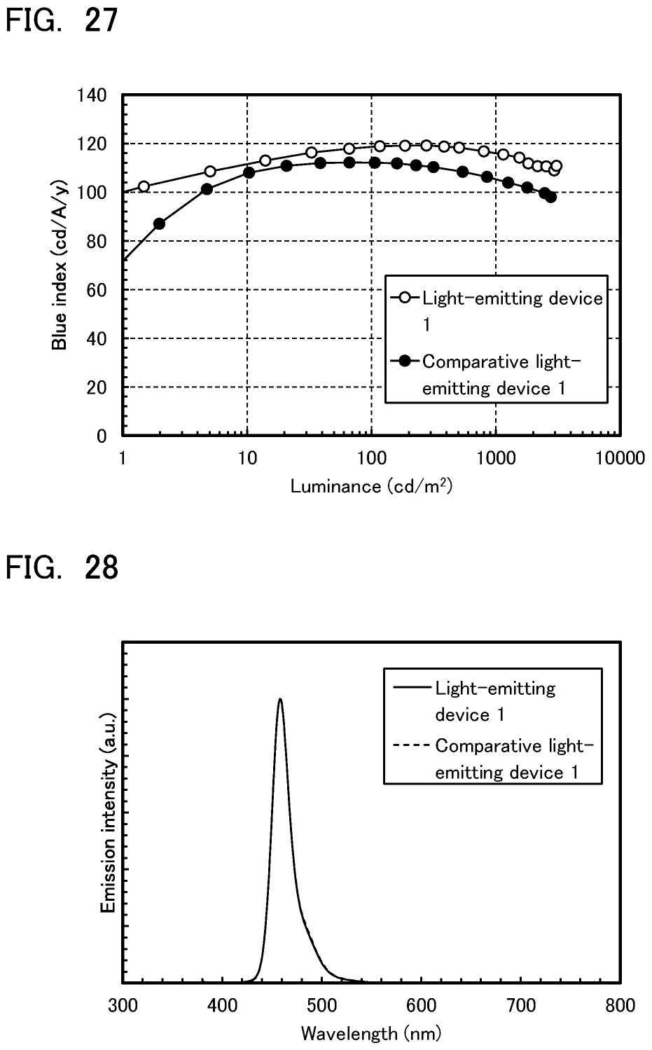

FIG. 27 is a graph showing luminance-blue index characteristics of the light-emitting device 1 and the comparative light-emitting device 1.

FIG. 28 is a graph showing emission spectra of the light-emitting device 1 and the comparative light-emitting device 1 each emitting light at a luminance of 1000 cd/m².

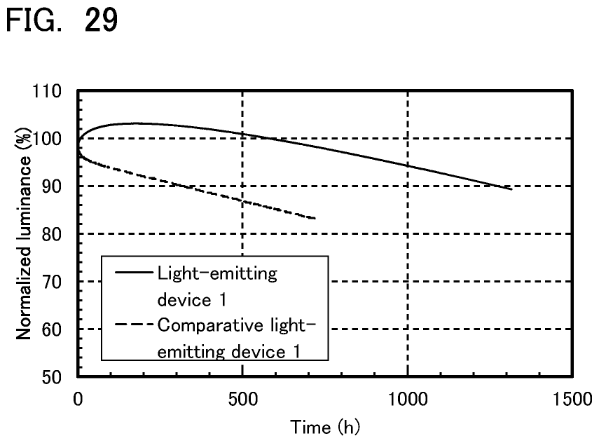

FIG. 29 is a graph showing normalized luminance-temporal change characteristics of the light-emitting device 1 and the comparative light-emitting device 1 each emitting light at a constant current density of 50 mA/cm².

### <Light-Emitting Device 1>

The fabricated light-emitting device 1, which is described in this example, has a structure similar to that of the light-emitting device 150 (see FIG. 21A).

The light-emitting device 150 includes the electrode 101, the electrode 102, and the unit 103. Note that the electrode 101 includes a light-transmitting conductive film TCF and a reflective film REF. The light-emitting device 150 includes the layer 105.

The electrode 102 includes a region overlapping with the electrode 101.

The unit 103 includes a region positioned between the electrode 101 and the electrode 102, and the unit 103 includes the layer 111, the layer 112, and the layer 113.

The layer 111 includes a region positioned between the layer 112 and the layer 113, and the layer 111 contains a light-emitting material.

The layer 113 includes a region positioned between the layer 111 and the electrode 102, and the layer 113 is in contact with the layer 111.

The layer 113 contains the material ET and an organometallic complex of an alkali metal or an organometallic complex of an alkaline earth metal.

The layer 112 includes a region positioned between the electrode 101 and the layer 111, and the layer 112 contains the material HT1.

The material HT1 has the refractive index n2, and the refractive index n2 is higher than or equal to 1.5 and lower than or equal to 1.75 in the wavelength range of 455 nm to 465 nm inclusive. Specifically, NN-bis(4-cyclohexylphenyl)-N-(9,9-dimethyl-9H-fluoren-2y1)amine (abbreviation: dchPAF) was used as the material HT1. FIG. 22 shows the refractive index of dchPAF. The ordinary refractive index of dchPAF was 1.65 at a wavelength of 633 nm. Note that a 50-nm-thick thin film was formed over a quartz substrate by a vacuum evaporation method, and the refractive index of the thin film was measured with a spectroscopic ellipsometer (M-2000U manufactured by J.A. Woollam Japan Corp.).

The light-emitting device 150 includes the layer 104. The layer 104 contains the material HT1 and the material AM having an electron acceptor property.

The material HT1 has the HOMO level HOMO1 (see FIG. 21C). Specifically, in CV measurement, the HOMO level of dchPAF was −5.36 eV. An electrochemical analyzer (manufactured by BAS Inc., model No. ALS model 600A or 600C) was used as a measurement apparatus.

The layer 112 includes the region 112A and the region 112B (see FIG. 21A).

The region 112A contains the material HT1. The region 112B includes a portion positioned between the layer 111 and the region 112A, and the region 112B contains the material HT2. Specifically, DBfBB1TP was used as the material HT2.

The material HT2 has the HOMO level HOMO2 (see FIG. 21C). Specifically, in CV measurement, the HOMO level of DBfBB1TP was −5.50 eV, which differed from the HOMO level of dchPAF by −0.14 eV.

<<Structure of light-emitting device 1>>

Table 1 shows the structure of the light-emitting device 1. Structural formulae of the materials used in the light-emitting device 1 described in this example, and a light-emitting device 2, the comparative light-emitting device 1, and a comparative light-emitting device 2, which are to be described later, are shown below.

TABLE 1

| | | | Compo- | Thick- |
|---|---|---|---|---|
| | Reference | | sition | ness/ |
| Structure | numeral | Material | ratio | nm |
| Layer | CAP | DBT3P-II | | 70 |
| Electrode | 102 | Ag:Mg | 10:1 | 15 |
| Layer | 105 | Liq | | 1 |
| Layer | 113 | ZADN:Liq | 1:1 | 30 |
| Layer | 111 | αN-βNPAnth:3, | 1:0.015 | 25 |
| | | 10PCA2Nbf(IV)-02 | | |
| Region | 112B | DBfBB1TP | | 10 |
| Region | 112A | dchPAF | | 30 |
| Layer | 104 | dchPAF:OCHD-001 | 1:0.05 | 10 |
| Conductive film | TCF | ITSO | | 85 |
| Reflective film | REF | APC | | 100 |

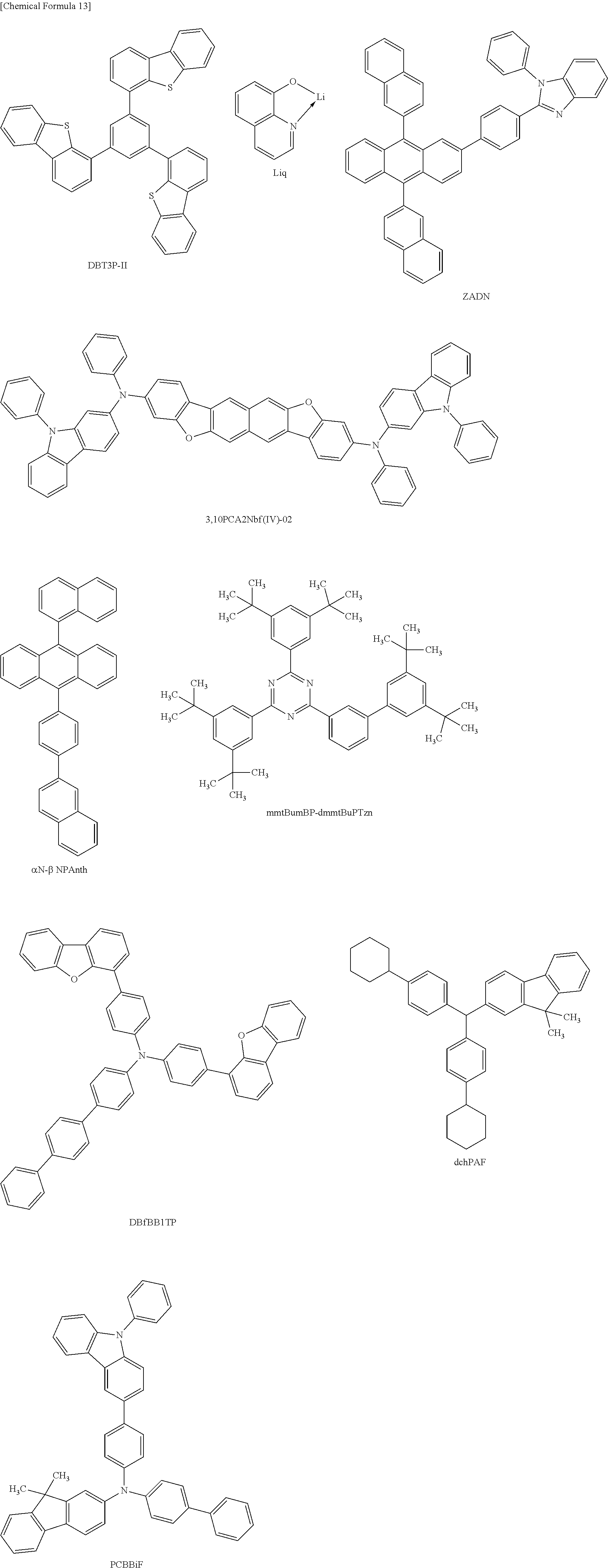

### <<Fabrication Method of Light-Emitting Device 1>>

The light-emitting device 1 described in this example was fabricated using a method including the following steps.

### [First Step]

In a first step, the reflective film REF was formed. Specifically, the reflective film REF was formed by a sputtering method using a silver alloy as a target.

Note that the reflective film REF contains silver, palladium, and copper, and has a thickness of 100 nm.

### [Second Step]

In a second step, the light-transmitting conductive film TCF was formed over the reflective film REF. Specifically, the light-transmitting conductive film TCF was formed by a sputtering method using indium oxide-tin oxide containing silicon or silicon oxide (ITSO) as a target.

Note that the light-transmitting conductive film TCF contains ITSO and has a thickness of 85 nm. The electrode 101 has an area of 4 mm² (2 mm×2 mm).

Next, a base material over which the electrode 101 was formed was washed with water, baked at 200° C. for an hour, and then subjected to UV ozone treatment for 370 seconds. Then, the substrate was transferred into a vacuum evaporation apparatus where the pressure was reduced to approximately 10⁻⁴ Pa, and vacuum baking was performed at 170° C. for 30 minutes in a heating chamber of the vacuum evaporation apparatus. Then, the substrate was cooled down for approximately 30 minutes.

### [Third Step]

In a third step, the layer 104 was formed over the electrode 101. Specifically, materials were co-deposited by a resistance-heating method.

The layer 104 contains dchPAF and an electron acceptor material (abbreviation: OCHD-001) at dchPAF:OCHD-001=1:0.05 (weight ratio), and has a thickness of 10 nm. Note that OCHD-001 has an acceptor property.

### [Fourth Step]

In a fourth step, the layered region 112A was formed over the layer 104. Specifically, a material was deposited by a resistance-heating method.

The region 112A contains dchPAF and has a thickness of 30 nm.

### [Fifth Step]

In a fifth step, the region 112B was formed over the region 112A. Specifically, a material was deposited by a resistance-heating method.

The region 112B contains DBfBB1TP and has a thickness of 10 nm.

### [Sixth Step]

In a sixth step, the layer 111 was formed over the region 112B. Specifically, materials were co-deposited by a resistance-heating method.

Note that the layer 111 contains aN-PNPAnth and 3,10PCA2Nbf(IV)-02 at aN-PNPAnth:3,10PCA2Nbf(IV)−02=1:0.015 (weight ratio) and has a thickness of 25 nm.

### [Seventh Step]

In a seventh step, the layer 113 was formed over the layer 111. Specifically, materials were co-deposited by a resistance-heating method.

Note that the layer 113 contains ZADN and Liq at ZADN:Liq=1:1 (weight ratio) and has a thickness of 30 nm.

### [Eighth Step]

In an eighth step, the layer 105 was formed over the layer 113. Specifically, a material was deposited by a resistance-heating method.

Note that the layer 105 contains Liq and has a thickness of 1 nm.

### [Ninth Step]

In a ninth step, the electrode 102 was formed over the layer 105. Specifically, materials were co-deposited by a resistance-heating method.

Note that the electrode 102 contains Ag and Mg at Ag:Mg=10:1 (volume ratio) and has a thickness of 15 nm.

### [Tenth Step]

In a tenth step, a layer CAP was formed over the electrode 102. Specifically, a material was deposited by a resistance-heating method.

The layer CAP contains DBT3P-II and has a thickness of 70 nm.

<<Operation characteristics of light-emitting device 1>>

When supplied with electric power, the light-emitting device 1 emitted the light EL1 (see FIG. 21A). Operation characteristics of the light-emitting device 1 were measured with a spectroradiometer (UR-UL1R produced by TOPCON TECHNOHOUSE CORPORATION) (see FIG. 23 to FIG. 28). Note that the measurement was performed at room temperature.

Table 2 shows main initial characteristics of the light-emitting device 1 emitting light at a luminance of approximately 1000 cd/m². Note that initial characteristics of other light-emitting devices are also shown in Table 2, and their structures will be described later.

Note that the blue index is a value obtained by further dividing current efficiency (cd/A) by chromaticity y, and is one of the indicators representing characteristics of blue light emission. As the chromaticity y is smaller, the color purity of blue light emission tends to be higher. With high color purity for blue light emission, a wide range of blue can be expressed even with a small number of luminance components; thus, using blue light emission with high color purity reduces the luminance needed for expressing blue, leading to lower power consumption. Thus, the blue index that is based on chromaticity y, which is one of the indicators of color purity of blue, is suitably used as a means for showing efficiency of blue light emission. The light-emitting device with a higher blue index can be regarded as a blue light-emitting device having more favorable efficiency for a display.

TABLE 2

| | | | Current | | | Current | |
|---|---|---|---|---|---|---|---|
| | Voltage | Current | density | Chromaticity | Chromaticity | efficiency | Blue index |
| | (V) | (mA) | (mA/cm2) | x | y | (cd/A) | (cd/A/y) |
| Light-emitting device 1 | 4.4 | 0.72 | 18.0 | 0.139 | 0.055 | 6.4 | 116.0 |
| Comparative light-emitting | 4.4 | 0.57 | 14.1 | 0.139 | 0.057 | 6.0 | 106.0 |
| device 1 | | | | | | | |

The light-emitting device 1 was found to have favorable characteristics. For example, the light-emitting device 1 showed higher current efficiency than the comparative light-emitting device 1 with the same driving voltage. Furthermore, a high blue index was exhibited. Furthermore, when the light-emitting device 1 kept emitting light at a constant current density of 50 mA/cm², the luminance of the light-emitting device 1 was less lowered than that of the comparative light-emitting device 1 (see FIG. 29). Specifically, improvement in a phenomenon of luminance reduction began right after start of light emission. For example, the light-emitting device 1 took 950 hours before an initial luminance of 3080 cd/m² decreased to 95% thereof. Note that the comparative light-emitting device 1 took 45 hours before an initial luminance of 2770 cd/m² decreased to 95% thereof. Thus, not only high efficiency but also improvement in reliability was achieved. As a result, a novel light-emitting device that was highly convenient, useful, or reliable was successfully provided.

### <<Measurement of Electron Mobility>>

The electron mobility of the material used for the layer 113 of the light-emitting device 1 was measured by impedance spectroscopy (IS method). Specifically, measurement was performed using an element in which a 200-nm-thick layer containing ZADN and Liq at ZADN:Liq=1:1 (weight ratio) was positioned between a pair of AI electrodes. Note that the element was fabricated in such a manner that the layer containing ZADN and Liq was formed over the first AI electrode by a co-deposition method and the second AI electrode having a thickness of 100 nm was formed thereover by a deposition method.

As the result of the measurement, the electron mobility of the material used for the layer 113 of the light-emitting device 1 was 3.5×10⁻⁶ cm²/Vs when the square root of the electric field strength (V/cm) was 600 (V/cm)¹¹².

### Reference Example 1

Table 1 shows the structure of the comparative light-emitting device 1. The fabricated comparative light-emitting device 1 described in this example is different from the light-emitting device 1 in that PCBBiF is used instead of dchPAF.

### <<Fabrication Method of Comparative Light-Emitting Devices 1>>

The comparative light-emitting device 1 was fabricated using a method including the following steps.

Note that the fabrication method of the comparative light-emitting device 1 is different from the fabrication method of the light-emitting device 1 in that PCBBiF is used instead of dchPAF in the third step of forming the layer 104 and the fourth step of forming the region 112A. Different portions are described in detail here, and the above description is referred to for portions formed by a similar method.

### [Third Step]

In the third step, the layer 104 was formed over the electrode 101. Specifically, materials were co-deposited by a resistance-heating method.

The layer 104 contains PCBBiF and OCHD-001 at PCBBiF:OCHD-001=1:0.05 (weight ratio), and has a thickness of 10 nm.

### [Fourth Step]

In the fourth step, the region 112A was formed over the layer 104. Specifically, a material was deposited by a resistance-heating method.

The region 112A contains PCBBiF and has a thickness of 30 nm.

### <<Operation Characteristics of Comparative Light-Emitting Devices 1>>

Operation characteristics of the comparative light-emitting device 1 were measured. Note that the measurement was performed at room temperature.

Table 2 shows main initial characteristics of the comparative light-emitting device 1.

### Example 2

In this example, a structure of a light-emitting device of one embodiment of the present invention is described with reference to FIG. 21 and FIG. 30 to FIG. 36.

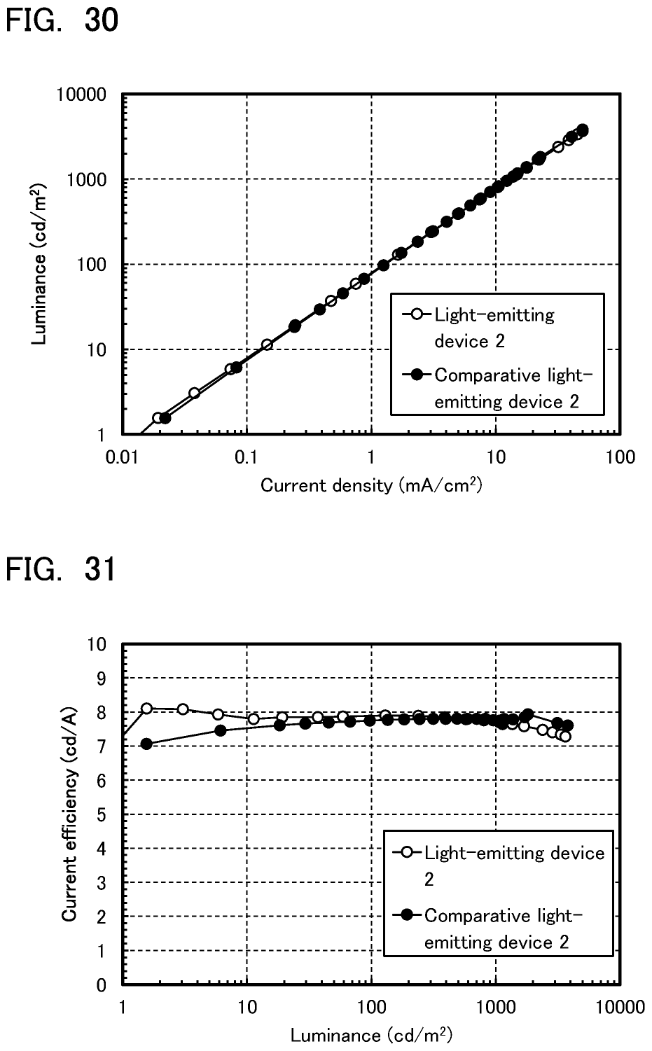

FIG. 30 is a graph showing current density-luminance characteristics of the light-emitting device 2 and the comparative light-emitting device 2.

FIG. 31 is a graph showing luminance-current efficiency characteristics of the light-emitting device 2 and the comparative light-emitting device 2.

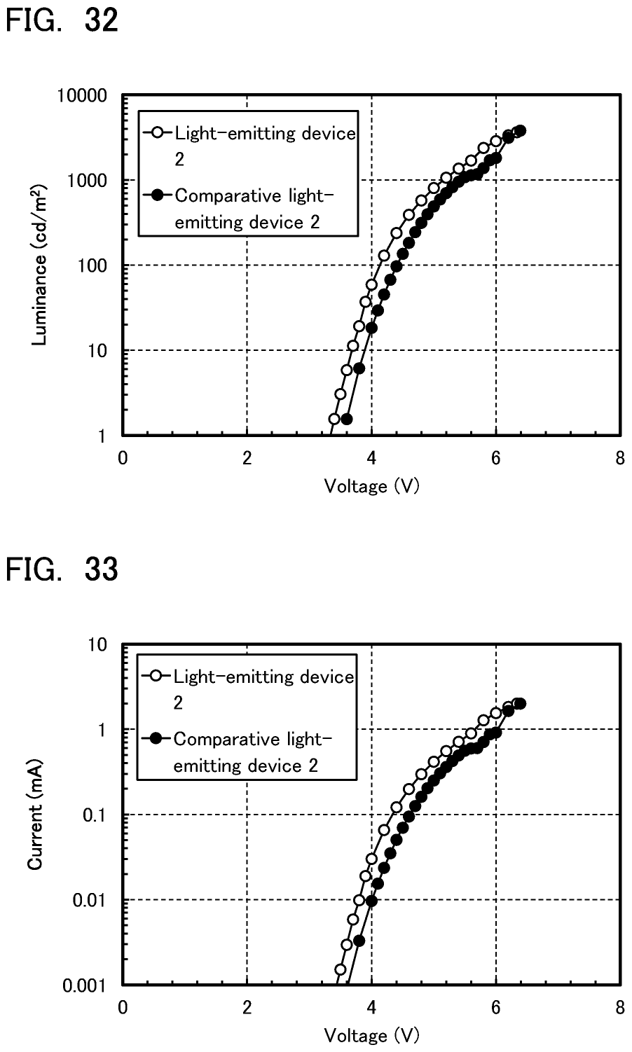

FIG. 32 is a graph showing voltage-luminance characteristics of the light-emitting device 2 and the comparative light-emitting device 2.

FIG. 33 is a graph showing voltage-current characteristics of the light-emitting device 2 and the comparative light-emitting device 2.

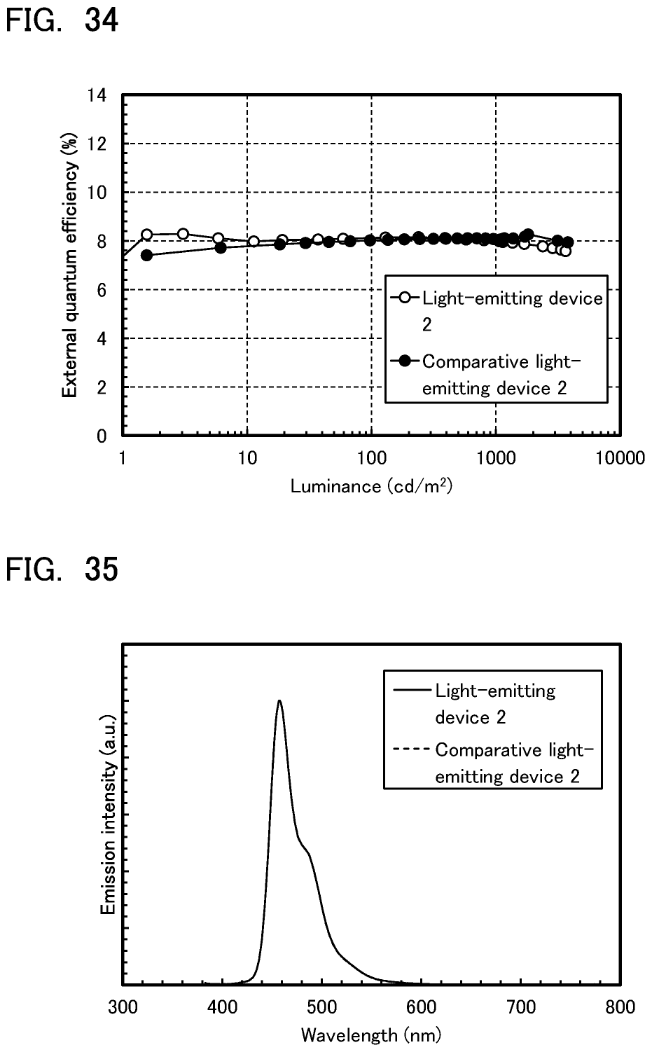

FIG. 34 is a graph showing luminance-external quantum efficiency characteristics of the light-emitting device 2 and the comparative light-emitting device 2. Note that the external quantum efficiency was calculated from luminance assuming that the light distribution characteristics of the light-emitting device are Lambertian type.

FIG. 35 is a graph showing emission spectra of the light-emitting device 2 and the comparative light-emitting device 2 each emitting light at a luminance of 1000 cd/m².

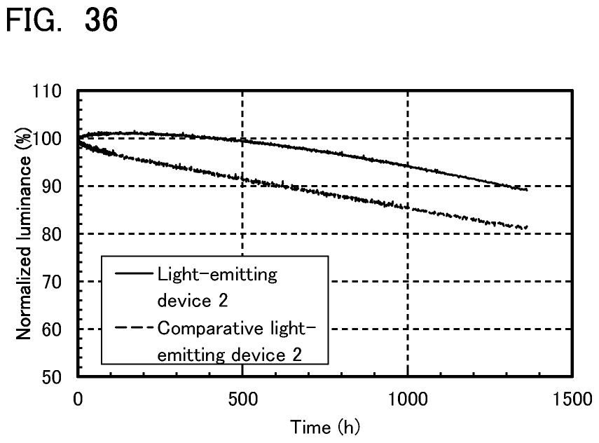

FIG. 36 is a graph showing normalized luminance-temporal change characteristics of the light-emitting device 2 and the comparative light-emitting device 2 each emitting light at a constant current density of 50 mA/cm².

### <Light-Emitting Device 2>

The fabricated light-emitting device 2, which is described in this example, has a structure similar to that of the light-emitting device 150 (see FIG. 21).

The light-emitting device 150 includes the electrode 101, the electrode 102, and the unit 103. The light-emitting device 150 includes the layer 105.

The electrode 102 includes a region overlapping with the electrode 101. Note that the electrode 102 includes a region extending outside the electrode 101.

The unit 103 includes a region positioned between the electrode 101 and the electrode 102, and the unit 103 includes the layer 111, the layer 112, and the layer 113.

The layer 111 includes a region positioned between the layer 112 and the layer 113, and the layer 111 contains a light-emitting material.

The layer 113 includes a region positioned between the layer 111 and the electrode 102, and the layer 113 is in contact with the layer 111.

The layer 113 contains the material ET, and the layer 113 contains an organometallic complex of an alkali metal or an organometallic complex of an alkaline earth metal.

The material ET has the refractive index n2, and the refractive index n2 is higher than or equal to 1.5 and lower than or equal to 1.75 in the wavelength range of 455 nm to 465 nm inclusive. Specifically, 2-{(3′,5′-di-tert-butyl)-1,1′-biphenyl-3-yl}−4,6-bis(3,5-di-tert-butylphenyl)-1,3,5-triazine (abbreviation: mmtBumBP-dmmtBuPTzn) was used as the material ET. FIG. 22 shows the refractive index of mmtBumBP-dmmtBuPTzn. The ordinary refractive index of mmtBumBP-dmmtBuPTzn was 1.57 at a wavelength of 633 nm. Note that a 50-nm-thick thin film was formed over a quartz substrate by a vacuum evaporation method, and the refractive index of the thin film was measured with a spectroscopic ellipsometer (M-2000U manufactured by J.A. Woollam Japan Corp.).

### <<Structure of Light-Emitting Device 2>>

Table 3 shows the structure of the light-emitting device 2.

TABLE 3

| | | | Compo- | Thick- |
|---|---|---|---|---|
| | Reference | | sition | ness/ |
| Structure | numeral | Material | ratio | nm |
| Electrode | 102 | Al | | 200 |
| Layer | 105 | Liq | | 1 |
| Region | 113B | mPn-mDMePyPTzn:Liq | 1:1 | 20 |
| Region | 113A | mmtBumBP- | 1:1 | 10 |
| | | dmmtBuPTzn:Liq | | |
| Layer | 111 | αN-βNPAnth:3, | 1:0.015 | 25 |
| | | 10PCA2Nbf(IV)-02 | | |
| Region | 112B | DBfBB1TP | | 10 |
| Region | 112A | PCBBiF | | 90 |
| Layer | 104 | PCBBiF:OCHD-001 | 1:0.05 | 10 |
| Electrode | 101 | ITSO | | 110 |

### <<Fabrication Method of Light-Emitting Device 2>>

The light-emitting device 2 described in this example was fabricated using a method including the following steps.

### [First Step]

In a first step, the electrode 101 was formed. Specifically, the electrode 101 was formed by a sputtering method using indium oxide-tin oxide containing silicon or silicon oxide (ITSO) as a target.

Note that the electrode 101 contains ITSO and has a thickness of 110 nm. The electrode 101 has an area of 4 mm² (2 mm×2 mm).

Next, a base material over which the electrode 101 was formed was washed with water, baked at 200° C. for an hour, and then subjected to UV ozone treatment for 370 seconds. Then, the substrate was transferred into a vacuum evaporation apparatus where the pressure was reduced to approximately 10⁻⁴ Pa, and vacuum baking was performed at 170° C. for 30 minutes in a heating chamber of the vacuum evaporation apparatus. Then, the substrate was cooled down for approximately 30 minutes.

### [Second Step]

In a second step, the layer 104 was formed over the electrode 101. Specifically, materials were co-deposited by a resistance-heating method.

Note that the layer 104 contains PCBBiF and OCHD-001 at PCBBiF:OCHD-001=1:0.05 (weight ratio), and has a thickness of 10 nm.

### [Third Step]

In a third step, the region 112A was formed over the layer 104. Specifically, a material was deposited by a resistance-heating method.

Note that the region 112A contains PCBBiF and has a thickness of 90 nm.

### [Fourth Step]

In a fourth step, the region 112B was formed over the region 112A. Specifically, a material was deposited by a resistance-heating method.

The region 112B contains DBfBB1TP and has a thickness of 10 nm.

### [Fifth Step]

In a fifth step, the layer 111 was formed over the region 112B. Specifically, materials were co-deposited by a resistance-heating method.

Note that the layer 111 contains aN-PNPAnth and 3,10PCA2Nbf(IV)-02 at aN-PNPAnth:3,10PCA2Nbf(IV)−02=1:0.015 (weight ratio) and has a thickness of 25 nm.

### [Sixth Step]

In a sixth step, the region 113A was formed over the layer 111. Specifically, materials were co-deposited by a resistance-heating method.

Note that the region 113A contains mmtBumBP-dmmtBuPTzn and Liq at mmtBumBP-dmmtBuPTzn:Liq=1:1 (weight ratio) and has a thickness of 10 nm.

### [Seventh Step]

In a seventh step, the region 113B was formed over the region 113A. Specifically, materials were co-deposited by a resistance-heating method.

Note that the region 113B contains 2-[3-(2,6-dimethyl-3-pyridinyl)-5-(9-phenanthrenyl)phenyl]-4,6-Diphenyl-1,3,5-Triazine (abbreviation: mPn-mDMePyPTzn) (abbreviation: mPn-mDMePyPTzn) and Liq at mPn-mDMePyPTzn:Liq=1:1 (weight ratio) and has a thickness of 20 nm. Note that mPn-mDMePyPTzn has an electron-transport property.

### [Eighth Step]

In an eighth step, the layer 105 was formed over the region 113B. Specifically, a material was deposited by a resistance-heating method.

Note that the layer 105 contains Liq and has a thickness of 1 nm.

### [Ninth Step]

In a ninth step, the electrode 102 was formed over the layer 105. Specifically, a material was deposited by a resistance-heating method.

Note that the electrode 102 contains Al and has a thickness of 200 nm.

### <<Operation Characteristics of Light-Emitting Device 2>>

When supplied with electric power, the light-emitting device 2 emitted the light EL1 (see FIG. 21). Operation characteristics of the light-emitting device 2 were measured with a spectroradiometer (UR-UL1R produced by TOPCON TECHNOHOUSE CORPORATION) (see FIG. 30 to FIG. 36). Note that the measurement was performed at room temperature.

Table 4 shows main initial characteristics of the light-emitting device 2 emitting light at a luminance of approximately 1000 cd/m². Note that initial characteristics of the comparative light-emitting device 2 are also shown in Table 4, and its structure will be described later.

TABLE 4

| | | | Current | | | Current | External |
|---|---|---|---|---|---|---|---|
| | Voltage | Current | density | Chromaticity | Chromaticity | efficiency | quantum |
| | (V) | (mA) | (mA/cm2) | x | y | (cd/A) | efficiency (%) |
| Light-emitting device 2 | 5.2 | 0.55 | 13.9 | 0.136 | 0.112 | 7.7 | 8.0 |
| Comparative light-emitting | 5.4 | 0.49 | 12.3 | 0.136 | 0.112 | 7.8 | 8.1 |
| device 2 | | | | | | | |

The light-emitting device 2 was found to have favorable characteristics. For example, the light-emitting device 2 exhibited the same luminance as the comparative light-emitting device 2 at a lower driving voltage than that of the comparative light-emitting device 2 (see FIG. 32). Furthermore, when the light-emitting device 2 kept emitting light at a constant current density of 50 mA/cm², the luminance of the light-emitting device 2 was less lowered than that of the comparative light-emitting device 2 (see FIG. 36). Specifically, improvement in a phenomenon of luminance reduction began right after start of light emission. For example, the light-emitting device 2 took 930 hours before its initial luminance decreased to 95% thereof. Note that the comparative light-emitting device 2 took 220 hours before its initial luminance decreased to 95% thereof. Thus, improvement in reliability was achieved in addition to reduction in power consumption in light emission at the same luminance. As a result, a novel light-emitting device that was highly convenient, useful, or reliable was successfully provided.

### Reference Example 2

Table 3 shows the structure of the comparative light-emitting device 2. The fabricated comparative light-emitting device 2 described in this example is different from the light-emitting device 2 in that Liq is not used and only mmtBumBP-dmmtBuPTzn is used for the region 113A.

### <<Fabrication Method of Comparative Light-Emitting Devices 2>>

The comparative light-emitting device 2 was fabricated using a method including the following steps.

Note that the fabrication method of the comparative light-emitting device 2 is different from the fabrication method of the light-emitting device 2 in that Liq is not used and only mmtBumBP-dmmtBuPTzn is used in the sixth step of forming the region 113A. Different portions are described in detail here, and the above description is referred to for portions formed by a similar method.

### [Sixth Step]

In the sixth step, the region 113A was formed over the layer 111. Specifically, a material was deposited by a resistance-heating method.

Note that the region 113A is formed using only mmtBumBP-dmmtBuPTzn and has a thickness of 10 nm.

### <<Operation Characteristics of Comparative Light-Emitting Devices 2>>

Operation characteristics of the comparative light-emitting device 2 were measured. Note that the measurement was performed at room temperature.

Table 4 shows main initial characteristics of the comparative light-emitting device 2.

### Synthesis Example 1

In this example, a method of synthesizing the electron-transport material with a low refractive index described in Embodiment 1 is described.

First, a method of synthesizing 2-{(3′,5′-di-tert-butyl)-1,1′-biphenyl-3-yl}−4,6-bis(3,5-di-tert-butylphenyl)-1,3,5-triazine (abbreviation: mmtBumBP-dmmtBuPTzn), which is an organic compound represented by Structural Formula (200) below, is described in detail. The structure of mmtBumBP-dmmtBuPTzn is shown below.

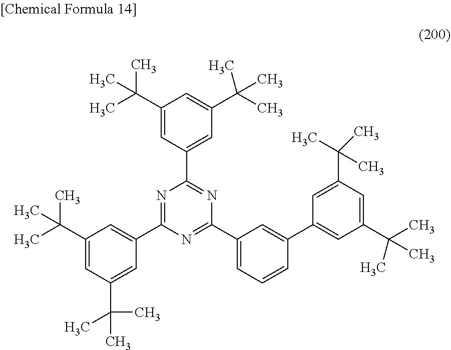 [SMILES: CC(C)(C)c1cc(-c2cccc(-c3nc(-c4cc(C(C)(C)C)cc(C(C)(C)C)c4)nc(-c4cc(C(C)(C)C)cc(C(C)(C)C)c4)n3)c2)cc(C(C)(C)C)c1]

### Step 1: Synthesis of 3-bromo-3′,5′-di-tert-butylbiphenyl

First, 1.0 g (4.3 mmol) of 3,5-di-t-butylphenylboronic acid, 1.5 g (5.2 mmol) of 1-bromo-3-iodobenzene, 4.5 mL of 2 mol/L aqueous solution of potassium carbonate, 20 mL of toluene, and 3 mL of ethanol were put into a three-neck flask and stirred under reduced pressure to be degassed. Furthermore, 52 mg (0.17 mmol) of tris(2-methylphenyl)phosphine (abbreviation: P(o-tolyl)₃) and 10 mg (0.043 mmol) of palladium(II) acetate were added to this mixture, and reacted under a nitrogen atmosphere at 80° C. for 14 hours. After the reaction, extraction was performed with toluene and the obtained organic layer was dried with magnesium sulfate. This mixture was subjected to gravity filtration and the resulting filtrate was purified by silica gel column chromatography (the developing solvent: hexane) to give 1.0 g of a target white solid (yield: 68%). The synthesis scheme of Step 1 is shown in the formula below.

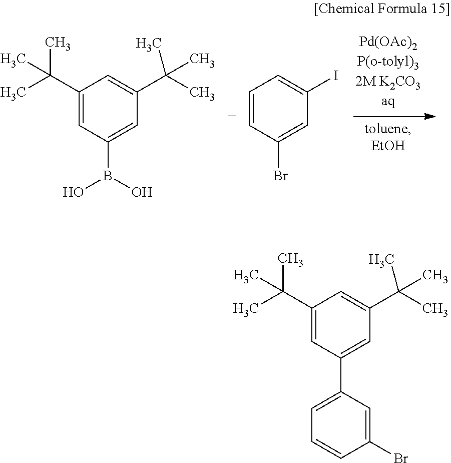 [SMILES: CC(C)(C)c1cc(B(O)O)cc(C(C)(C)C)c1 ; Brc1cccc(I)c1 ; CC(C)(C)c1cc(-c2cccc(Br)c2)cc(C(C)(C)C)c1]

### <Step 2: Synthesis of 2-(3′,5′-di-tert-butylbiphenyl-3-yl)-4,4,5,5-tetramethyl-1,3,2-dioxaborolane

First, 1.0 g (2.9 mmol) of 3-bromo-3′,5′-di-tert-butylbiphenyl, 0.96 g (3.8 mmol) of bis(pinacolato)diboron, 0.94 g (9.6 mmol) of potassium acetate, and 30 mL of 1,4-dioxane were put into a three-neck flask and stirred under reduced pressure to be degassed. To this mixture were added 0.12 g (0.30 mmol) of 2-dicyclohexylphosphino-2′,6′-dimethoxybiphenyl (abbreviation: SPhos) and 0.12 g (0.15 mmol) of [1,1′-bis(diphenylphosphino)ferrocene]palladium(II) dichloride dichloromethane adduct, and reaction was caused under a nitrogen atmosphere at 110° C. for 24 hours. After the reaction, extraction was performed with toluene and the obtained organic layer was dried with magnesium sulfate. This mixture was subjected to gravity filtration. The resulting filtrate was purified by silica gel column chromatography (the developing solvent: toluene) to give 0.89 g of a target yellow oil (yield: 78%). The synthesis scheme of Step 2 is shown in the formula below.

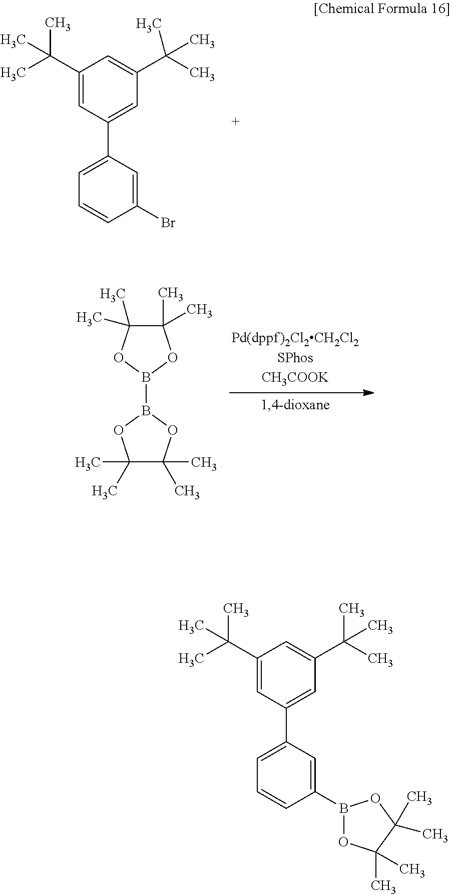

### Step 3: Synthesis of mmtBumBP-dmmtBuPTzn

Into a three-neck flask were put 0.8 g (1.6 mmol) of 4,6-bis(3,5-di-tert-butyl-phenyl)-2-chloro-1,3,5-triazine, 0.89 g (2.3 mmol) of 2-(3′,5′-di-tert-butylbiphenyl-3-yl)-4,4,5,5-tetramethyl-1,3,2-dioxaborolane, 0.68 g (3.2 mmol) of tripotassium phosphate, 3 mL of water, 8 mL of toluene, and 3 mL of 1,4-dioxane, and the mixture was degassed by being stirred under reduced pressure. To this mixture were added 3.5 mg (0.016 mmol) of palladium(II) acetate and 10 mg (0.032 mmol) of tris(2-methylphenyl)phosphine, and the mixture was heated and refluxed under a nitrogen atmosphere for 12 hours. After the reaction, extraction was performed with ethyl acetate and the obtained organic layer was dried with magnesium sulfate. This mixture was subjected to gravity filtration. The resulting filtrate was concentrated, followed by purification by silica gel column chromatography (the developing solvent: ethyl acetate:hexane=1:20) to give a solid. This solid was purified by silica gel column chromatography (the developing solvent: chloroform:hexane=5:1, which was then changed to 1:0). The obtained solid was recrystallized with hexane to give 0.88 g of a target white solid (yield: 76%). The synthesis scheme of Step 3 is shown in the formula below.

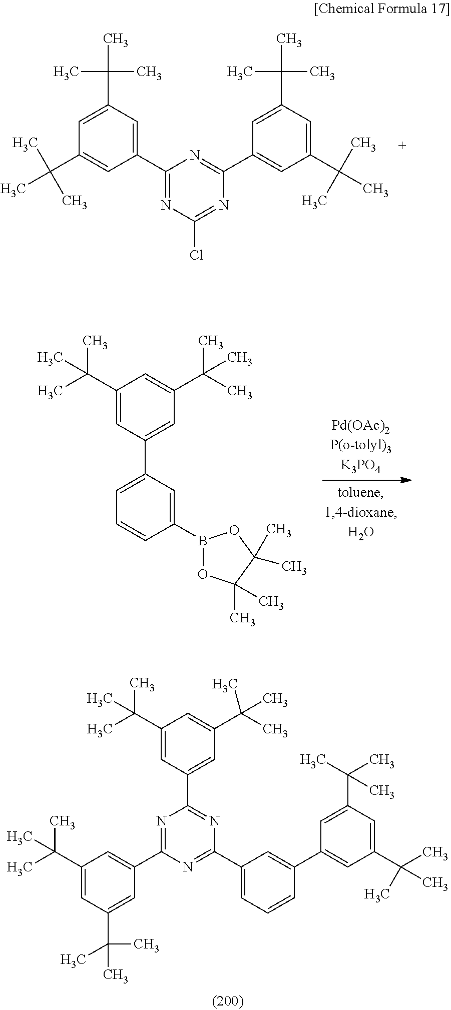

Then, 0.87 g of the obtained white solid was purified by a train sublimation method at 230° C. under a pressure of 5.8 Pa while an argon gas was made to flow. After the purification by sublimation, 0.82 g of a target white solid was obtained at a collection rate of 95%.

Results of analysis by nuclear magnetic resonance spectroscopy (¹H-NMR) of the white solid obtained in Step 3 are shown below. The results show that mmtBumBP-dmmtBuPTzn represented by Structural Formula (200) above was obtained in this synthesis example.

H¹NMR (CDCl₃, 300 MHz): δ=1.42-1.49 (m, 54H), 7.50 (s, 1H), 7.61-7.70 (m, 5H), 7.87 (d, 1H), 8.68-8.69 (m, 4H), 8.78 (d, 1H), 9.06 (s, 1H).

Similarly, organic compounds represented by Structural Formula (201) to Structural Formula (204) below were synthesized.

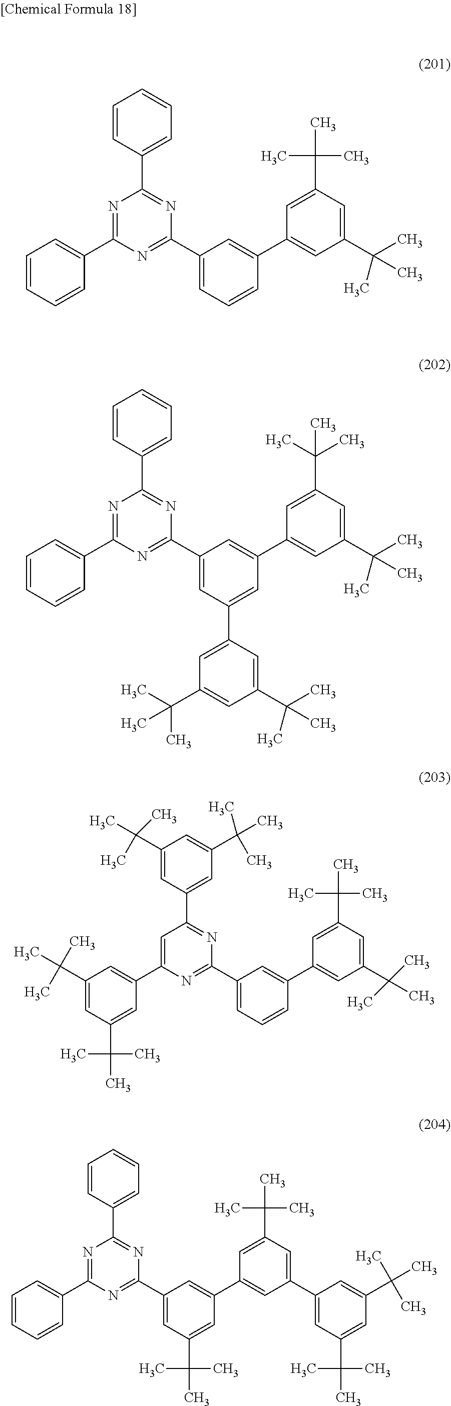

Analysis results by nuclear magnetic resonance spectroscopy (¹H-NMR) of the above organic compounds are shown below.

Structural Formula (201): 2-{(3′,5′-di-tert-butyl)-1,1′-biphenyl-3-yl}-4,6-diphenyl-1,3,5-triazine (abbreviation: mmtBumBPTzn) H¹NMR (CDCl₃, 300 MHz): δ=1.44 (s, 18H), 7.51-7.68 (m, 10H), 7.83 (d, 1H), 8.73-8.81 (m, 5H), 9.01 (s, 1H).

Structural Formula (202): 2-(3,3″,5,5″-tetra-tert-butyl-1,1′:3′,1″-phenyl-5′-yl)-4,6-diphenyl-1,3,5-triazine (abbreviation: mmtBumTPTzn) H¹NMR (CDCl₃, 300 MHz): δ=1.44 (s, 36H), 7.54-7.62 (m, 12H), 7.99 (t, 1H), 8.79 (d, 4H), 8.92 (d, 2H).

Structural Formula (203): 2-{(3′,5′-di-tert-butyl)-1,1′-biphenyl-3-yl}-4,6-bis(3,5-di-tert-butylphenyl)-1,3-pyrimidine (abbreviation: mmtBumBP-dmmtBuPPm) H¹NMR (CDCl₃, 300 MHz): δ=1.39-1.45 (m, 54H), 7.47 (t, 1H), 7.59-7.65 (m, 5H), 7.76 (d, 1H), 7.95 (s, 1H), 8.06 (d, 4H), 8.73 (d, 1H), 8.99 (s, 1H).

Structural Formula (204): 2-(3,3″, 5′,5″-tetra-tert-butyl-1,1′:3′,1″-terphenyl-5-yl)-4,6-diphenyl-1,3,5-triazine (abbreviation: mmtBumTPTzn-02) H¹NMR (CDCl₃, 300 MHz): δ=1.41 (s, 18H), 1.49 (s, 9H), 1.52 (s, 9H), 7.49 (s, 3H), 7.58-7.63 (m, 7H), 7.69-7.70 (m, 2H), 7.88 (t, 1H), 8.77-8.83 (m, 6H).

The substances described above each have an ordinary refractive index higher than or equal to 1.50 and lower than or equal to 1.75 in a blue light emission range (455 nm to 465 nm) or an ordinary refractive index higher than or equal to 1.45 and lower than or equal to 1.70 with respect to light of wavelength 633 nm, which is usually used for measurement of refractive indices.

### Synthesis Example 2

In this example, a method of synthesizing the hole-transport material with a low refractive index described in Embodiment 1 is described.

First, a method of synthesizing N,N-bis(4-cyclohexylphenyl)-N-(9,9-dimethyl-9H-fluoren-2yl)amine (abbreviation: dchPAF) is described in detail. The structure of dchPAF is shown below.

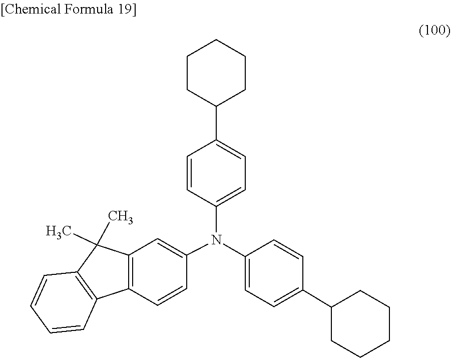 [SMILES: CC1(C)c2ccccc2-c2ccc(N(c3ccc(C4CCCCC4)cc3)c3ccc(C4CCCCC4)cc3)cc21]

### <Step 1: Synthesis of N,N-bis(4-cyclohexylphenyl)-N-(9,9-dimethyl-9H-fluoren-2yl)amine (abbreviation: dchPAF)

Into a three-neck flask were put 10.6 g (51 mmol) of 9,9-dimethyl-9H-fluoren-2-amine, 18.2 g (76 mmol) of 4-cyclohexyl-1-bromobenzene, 21.9 g (228 mmol) of sodium-tert-butoxide, and 255 mL of xylene. The mixture was degassed under reduced pressure, and then the air in the flask was replaced with nitrogen. The mixture was stirred while being heated to approximately 50° C. Then, 370 mg (1.0 mmol) of allylpalladium(II) chloride dimer (abbreviation: (AllylPdCl)₂) and 1660 mg (4.0 mmol) of di-tert-butyl(1-methyl-2,2-diphenylcyclopropyl)phosphine (abbreviation: cBRIDP (registered trademark)) were added, and the mixture was heated at 120° C. for approximately 5 hours. After that, the temperature of the flask was lowered to approximately 60° C., and approximately 4 mL of water was added to the mixture, so that a solid was precipitated. The precipitated solid was separated by filtration. The filtrate was concentrated, and the obtained solution was purified by silica gel column chromatography. The obtained solution was concentrated to give a condensed toluene solution. The toluene solution was dropped into ethanol for reprecipitation. The precipitate was filtrated at approximately 10° C. and the obtained solid was dried at approximately 80° C. under reduced pressure, so that 10.1 g of a target white solid was obtained in a yield of 40%. The synthesis scheme of dchPAF in Step 1 is shown below.

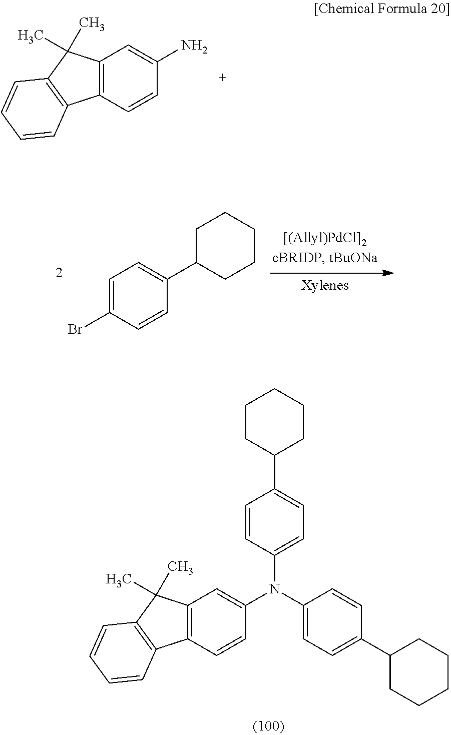 [SMILES: CC1(C)c2ccccc2-c2ccc(N)cc21 ; Brc1ccc(C2CCCCC2)cc1 ; CC1(C)c2ccccc2-c2ccc(N(c3ccc(C4CCCCC4)cc3)c3ccc(C4CCCCC4)cc3)cc21]

Analysis results by nuclear magnetic resonance spectroscopy (¹H-NMR) of the white solid obtained in Step 1 are shown below. The results show that dchPAF was synthesized in this synthesis example.

¹H-NMR. δ (CDCl₃): 7.60 (d, 1H, J=7.5 Hz), 7.53 (d, 1H, J=8.0 Hz), 7.37 (d, 2H, J=7.5 Hz), 7.29 (td, 1H, J=7.5 Hz, 1.0 Hz), 7.23 (td, 1H, J=7.5 Hz, 1.0 Hz), 7.19 (d, 1H, J=1.5 Hz), 7.06 (m, 8H), 6.97 (dd, 1H, J=8.0 Hz, 1.5 Hz), 2.41-2.51 (brm, 2H), 1.79-1.95 (m, 8H), 1.70-1.77 (m, 2H), 1.33-1.45 (brm, 14H), 1.19-1.30 (brm, 2H).

Similarly, organic compounds represented by Structural Formula (101) to Structural Formula (109) below were synthesized.

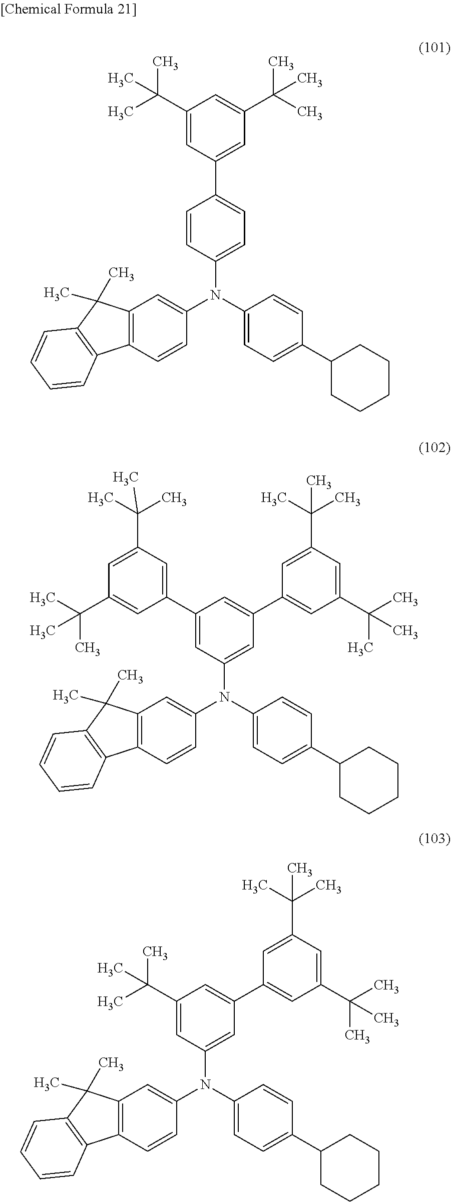 [SMILES: CC(C)(C)c1cc(-c2ccc(N(c3ccc(C4CCCCC4)cc3)c3ccc4c(c3)C(C)(C)c3ccccc3-4)cc2)cc(C(C)(C)C)c1 ; CC(C)(C)c1cc(-c2cc(-c3cc(C(C)(C)C)cc(C(C)(C)C)c3)cc(N(c3ccc(C4CCCCC4)cc3)c3ccc4c(c3)C(C)(C)c3ccccc3-4)c2)cc(C(C)(C)C)c1 ; CC(C)(C)c1cc(-c2cc(C(C)(C)C)cc(C(C)(C)C)c2)cc(N(c2ccc(C3CCCCC3)cc2)c2ccc3c(c2)C(C)(C)c2ccccc2-3)c1]

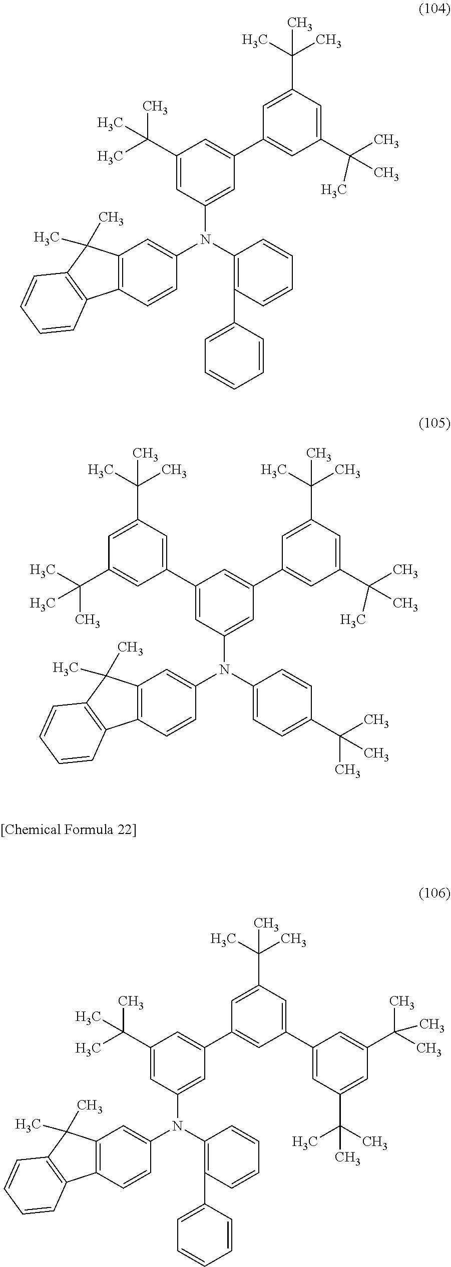 [SMILES: CC(C)(C)c1cc(-c2cc(C(C)(C)C)cc(C(C)(C)C)c2)cc(N(c2ccc3c(c2)C(C)(C)c2ccccc2-3)c2ccccc2-c2ccccc2)c1 ; CC(C)(C)c1ccc(N(c2cc(-c3cc(C(C)(C)C)cc(C(C)(C)C)c3)cc(-c3cc(C(C)(C)C)cc(C(C)(C)C)c3)c2)c2ccc3c(c2)C(C)(C)c2ccccc2-3)cc1 ; CC(C)(C)c1cc(-c2cc(N(c3ccc4c(c3)C(C)(C)c3ccccc3-4)c3ccccc3-c3ccccc3)cc(C(C)(C)C)c2)cc(-c2cc(C(C)(C)C)cc(C(C)(C)C)c2)c1]

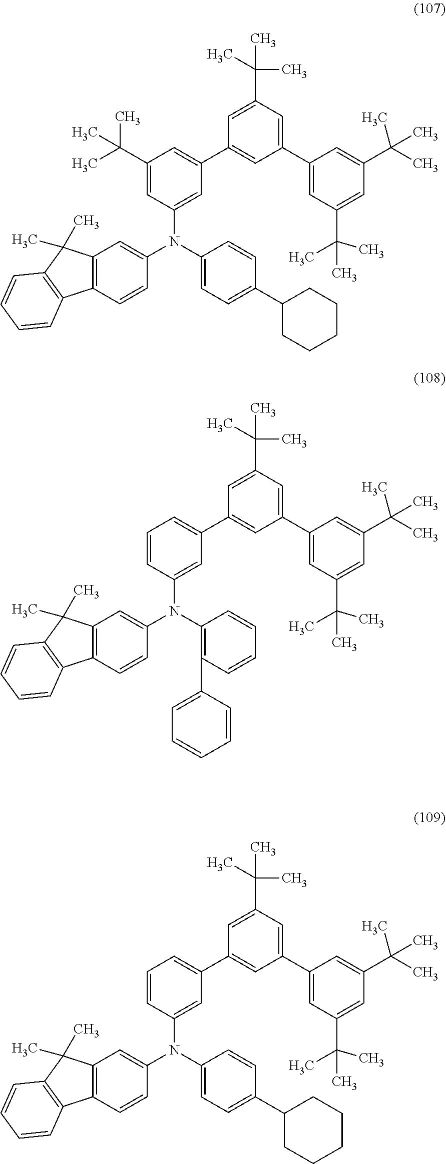 [SMILES: CC(C)(C)c1cc(-c2cc(N(c3ccc(C4CCCCC4)cc3)c3ccc4c(c3)C(C)(C)c3ccccc3-4)cc(C(C)(C)C)c2)cc(-c2cc(C(C)(C)C)cc(C(C)(C)C)c2)c1 ; CC(C)(C)c1cc(-c2cccc(N(c3ccc4c(c3)C(C)(C)c3ccccc3-4)c3ccccc3-c3ccccc3)c2)cc(-c2cc(C(C)(C)C)cc(C(C)(C)C)c2)c1 ; CC(C)(C)c1cc(-c2cccc(N(c3ccc(C4CCCCC4)cc3)c3ccc4c(c3)C(C)(C)c3ccccc3-4)c2)cc(-c2cc(C(C)(C)C)cc(C(C)(C)C)c2)c1]

Analysis results by nuclear magnetic resonance spectroscopy (¹H-NMR) of the above organic compounds are shown below.

Structural Formula (101): N-(4-cyclohexylphenyl)-N-(3″,5″-ditertiarybutyl-1,1″-biphenyl-4-yl)-N-(9,9-dimethyl-9H-fluoren-2yl)amine (abbreviation: mmtBuBichPAF) ¹H-NMR. δ (CDCl₃): 7.63 (d, 1H, J=7.5 Hz), 7.57 (d, 1H, J=8.0 Hz), 7.44-7.49 (m, 2H), 7.37-7.42 (m, 4H), 7.31 (td, 1H, J=7.5 Hz, 2.0 Hz), 7.23-7.27 (m, 2H), 7.15-7.19 (m, 2H), 7.08-7.14 (m, 4H), 7.05 (dd, 1H, J=8.0 Hz, 2.0 Hz), 2.43-2.53 (brm, 1H), 1.81-1.96 (m, 4H), 1.75 (d, 1H, J=12.5 Hz), 1.32-1.48 (m, 28H), 1.20-1.31 (brm, 1H).

Structural Formula (102): N-(3,3″,5,5″-tetra-t-butyl-1,1′:3′,1″-terphenyl-5′-yl)-N-(4-cyclohexylphenyl)-9,9-dimethyl-9H-flu oren-2-amine (abbreviation: mmtBumTPchPAF) ¹H-NMR (300 MHz, CDCl₃): δ=7.63 (d, J=6.6 Hz, 1H), 7.58 (d, J=8.1 Hz, 1H), 7.42-7.37 (m, 4H), 7.36-7.09 (m, 14H), 2.55-2.39 (m, 1H), 1.98-1.20 (m, 51H).

Structural Formula (103): N-[(3,3′, 5′-t-butyl)-1,1′-biphenyl-5-yl]-N-(4-cyclohexylphenyl)-9,9-dimethyl-9H-fluoren-2-amin e (abbreviation: mmtBumBichPAF) ¹H-NMR. δ (CDCl₃): 7.63 (d, 1H, J=7.5 Hz), 7.56 (d, 1H, J=8.5 Hz), 7.37-40 (m, 2H), 7.27-7.32 (m, 4H), 7.22-7.25 (m, 1H), 7.16-7.19 (brm, 2H), 7.08-7.15 (m, 4H), 7.02-7.06 (m, 2H), 2.43-2.51 (brm, 1H), 1.80-1.93 (brm, 4H), 1.71-1.77 (brm, 1H), 1.36-1.46 (brm, 10H), 1.33 (s, 18H), 1.22-1.30 (brm, 10H).

Structural Formula (104): N-(1,1′-biphenyl-2-yl)-N-[(3,3′,5′-tri-t-butyl)-1,1′-biphenyl-5-yl]-9,9-dimethyl-9H-fluoren-2-ami ne (abbreviation: mmtBumBioFBi) ¹H-NMR. δ (CDCl₃): 7.57 (d, 1H, J=7.5 Hz), 7.40-7.47 (m, 2H), 7.32-7.39 (m, 4H), 7.27-7.31 (m, 2H), 7.27-7.24 (m, 5H), 6.94-7.09 (m, 6H), 6.83 (brs, 2H), 1.33 (s, 18H), 1.32 (s, 6H), 1.20 (s, 9H).

Structural Formula (105): N-(4-tert-butylphenyl)-N-(3,3″,5,5″-tetra-t-butyl-1,1′:3,1″-terphenyl-5′-yl)-9,9-dimethyl-9H-fluor en-2-amine (abbreviation: mmtBumTPtBuPAF) ¹H-NMR. δ (CDCl₃): 7.64 (d, 1H, J=7.5 Hz), 7.59 (d, 1H, J=8.0 Hz), 7.38-7.43 (m, 4H), 7.29-7.36 (m, 8H), 7.24-7.28 (m, 3H), 7.19 (d, 2H, J=8.5 Hz), 7.13 (dd, 1H, J=1.5 Hz, 8.0 Hz), 1.47 (s, 6H), 1.32 (s, 45H).

Structural Formula (106): N-(1,1′-biphenyl-2-yl)-N-(3,3″,5′,5″-tetra-t-butyl-1,1′:3′,1″-terphenyl-5-yl)-9,9-dimethyl-9H-fluor en-2-amine (abbreviation: mmtBumTPoFBi-02) ¹H-NMR. δ (CDCl₃): 7.56 (d, 1H, J=7.4 Hz), 7.50 (dd, 1H, J=1.7 Hz), 7.33-7.46 (m, 11H), 7.27-7.29 (m, 2H), 7.22 (dd, 1H, J=2.3 Hz), 7.15 (d, 1H, J=6.9 Hz), 6.98-7.07 (m, 7H), 6.93 (s, 1H), 6.84 (d, 1H, J=6.3 Hz), 1.38 (s, 9H), 1.37 (s, 18H), 1.31 (s, 6H), 1.20 (s, 9H).

Structural Formula (107): N-(4-cyclohexylphenyl)-N-(3,3″, 5′,5″-tetra-t-butyl-1,1′:3′,1″-terphenyl-5-yl)-9,9-dimethyl-9H-flu oren-2-amine (abbreviation: mmtBumTPchPAF-02) ¹H-NMR. δ (CDCl₃): 7.62 (d, 1H, J=7.5 Hz), 7.56 (d, 1H, J=8.0 Hz), 7.50 (dd, 1H, J=1.7 Hz), 7.46-7.47 (m, 2H), 7.43 (dd, 1H, J=1.7 Hz), 7.37-7.39 (m, 3H), 7.29-7.32 (m, 2H), 7.23-7.25 (m, 2H), 7.20 (dd, 1H, J=1.7 Hz), 7.09-7.14 (m, 5H), 7.05 (dd, 1H, J=2.3 Hz), 2.46 (brm, 1H), 1.83-1.88 (m, 4H), 1.73-1.75 (brm, 1H), 1.42 (s, 6H), 1.38 (s, 9H), 1.36 (s, 18H), 1.29 (s, 9H).

Structural Formula (108): N-(1,1′-biphenyl-2-yl)-N-(3″,5′,5″-tri-t-butyl-1,1′:3′,1″-terphenyl-5-yl)-9,9-dimethyl-9H-fluoren-2-amine (abbreviation: mmtBumTPoFBi-03) ¹H-NMR. δ (CDCl₃): 7.55 (d, 1H, J=7.4 Hz), 7.50 (dd, 1H, J=1.7 Hz), 7.42-7.43 (m, 3H), 7.27-7.39 (m, 10H), 7.18-7.25 (m, 4H), 7.00-7.12 (m, 4H), 6.97 (dd, 1H, J=6.3 Hz, 1.7 Hz), 6.93 (d, 1H, J=1.7 Hz), 6.82 (dd, 1H, J=7.3 Hz, 2.3 Hz), 1.37 (s, 9H), 1.36 (s, 18H), 1.29 (s, 6H).

Structural Formula (109): N-(4-cyclohexylphenyl)-N-(3″,5′,5″-tri-t-butyl-1,1′:3′,1″-terphenyl-5-yl)-9,9-dimethyl-9H-fluoren-2-amine (abbreviation: mmtBumTPchPAF-03) ¹H-NMR. δ (CDCl₃): 7.62 (d, 1H, J=7.5 Hz), 7.56 (d, 1H, J=8.6 Hz), 7.51 (dd, 1H, J=1.7 Hz), 7.48 (dd, 1H, J=1.7 Hz), 7.46 (dd, 1H, J=1.7 Hz), 7.42 (dd, 1H, J=1.7 Hz), 7.37-7.39 (m, 4H), 7.27-7.33 (m, 2H), 7.23-7.25 (m, 2H), 7.05-7.13 (m, 7H), 2.46 (brm, 1H), 1.83-1.90 (m, 4H), 1.73-1.75 (brm, 1H), 1.41 (s, 6H), 1.37 (s, 9H), 1.35 (s, 18H).

The substances described above each have an ordinary refractive index higher than or equal to 1.50 and lower than or equal to 1.75 in a blue light emission range (455 nm to 465 nm) or an ordinary refractive index higher than or equal to 1.45 and lower than or equal to 1.70 with respect to light of wavelength 633 nm, which is usually used for measurement of refractive indices.

### Synthesis Example 3

A method of synthesizing 2-phenyl-3-[10-(3-pyridyl)-9-anthryl]phenylquinoxaline (abbreviation: PyA1PQ) described in Embodiment 2 is described in this example. The structure of PyA1PQ is shown below.

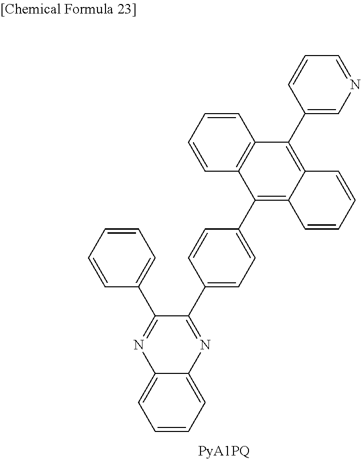 [SMILES: c1ccc(-c2nc3ccccc3nc2-c2ccc(-c3c4ccccc4c(-c4cccnc4)c4ccccc34)cc2)cc1]

Into a 50 mL three-neck flask were put 0.74 g (2.2 mmol) of 3-(10-bromo-9-anthryl)pyridine, 0.26 g (0.85 mmol) of tri(ortho-tolyl)phosphine, 0.73 g (2.3 mmol) of 4-(3-phenylquinoxalin-2-yl)phenylboronic acid, 1.3 g (9.0 mmol) of an aqueous solution of potassium carbonate, 40 mL of ethylene glycol dimethyl ether (DME), and 4.4 mL of water. The mixture was degassed by being stirred under reduced pressure, and the air in the flask was replaced with nitrogen.

To this mixture in the flask was added 65 mg (0.29 mmol) of palladium(II) acetate, and the mixture was stirred at 80° C. under a nitrogen stream for 11 hours. After the stirring, water was added to the mixture in the flask, followed by extraction with toluene. The obtained solution of the extract was washed with saturated saline, and drying with magnesium sulfate was performed. The mixture was subjected to gravity filtration, and the filtrate was concentrated to give an oily substance. The obtained oily substance was purified twice by silica gel column chromatography (chloroform) and (toluene:ethyl acetate=5:1) and recrystallized with toluene/hexane to give 0.43 g of a target yellow solid in a yield of 36%. The synthesis scheme is shown in the formula below.

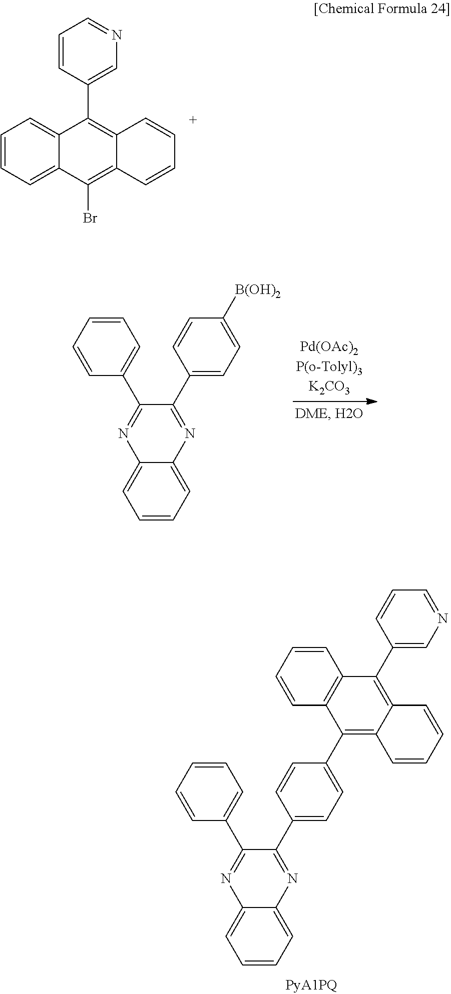 [SMILES: Brc1c2ccccc2c(-c2cccnc2)c2ccccc12 ; OB(O)c1ccc(-c2nc3ccccc3nc2-c2ccccc2)cc1 ; c1ccc(-c2nc3ccccc3nc2-c2ccc(-c3c4ccccc4c(-c4cccnc4)c4ccccc34)cc2)cc1]

By a train sublimation method, 0.44 g of the obtained yellow solid was purified by sublimation. The purification by sublimation was performed for 18 hours under the heating conditions of a pressure of 10 Pa, an argon flow rate of 5.0 mL/min, and a temperature of 260° C. After the purification by sublimation, 0.35 g of a target yellow solid was obtained at a collection rate of 79%.

Results of analysis by nuclear magnetic resonance spectroscopy (¹H-NMR) of the yellow solid obtained in the above reaction are shown below. The results show that PyA1PQ represented by the above structural formula was obtained in this example.

¹H NMR (CDCl₃, 300 MHz): δ=7.37-7.50 (m, 9H), 7.56-7.78 (m, 9H), 7.82-7.86 (m, 3H), 8.24-8.30 (m, 2H), 8.75 (dd, J=1.8 Hz, 0.9 Hz, 1H), 8.84 (dd, J=4.8 Hz, 1.8 Hz, 1H).

### REFERENCE NUMERALS

ANO: conductive film, CAP: layer, CP: conductive material, FPC1: flexible printed circuit, G1: conductive film, MD: transistor, M21: transistor, N21: node, N22: node, Slg: conductive film, SW21: switch, SW23: switch, TCF: conductive film, VCOM2: conductive film, V0: conductive film, 101: electrode, 102: electrode, 103: unit, 104: layer, 105: layer, 106: intermediate layer, 106A: layer, 106B: layer, 111: layer, 112: layer, 112A: region, 112B: region, 113: layer, 113A: region, 113B: region, 150: light-emitting device, 231: region, 400: substrate, 401: first electrode, 403: EL layer, 404: second electrode, 405: sealant, 406: sealant, 407: sealing substrate, 412: pad, 420: IC chip, 501C: insulating film, 501D: insulating film, 504: conductive film, 506: insulating film, 508: semiconductor film, 508A: region, 508B: region, 508C: region, 510: base material, 512A: conductive film, 512B: conductive film, 516: insulating film, 516A: insulating film, 516B: insulating film, 518: insulating film, 519B: terminal, 520: functional layer, 521: insulating film, 521A: insulating film, 521B: insulating film, 524: conductive film, 528: insulating film, 530G: pixel circuit, 550G: light-emitting device, 550W: light-emitting device, 551G: electrode, 551W: electrode, 552: electrode, 553: EL layer, 553G: layer, 573: insulating film, 573A: insulating film, 573B: insulating film, 591G: opening portion, 601: source line driver circuit, 602: pixel portion, 603: gate line driver circuit, 604: sealing substrate, 605: sealant, 607: space, 608: lead wiring, 610: element substrate, 611: switching FET, 612: current control FET, 613: first electrode, 614: insulator, 616: EL layer, 617: second electrode, 618: light-emitting device, 623: FET, 700: functional panel, 702B: pixel, 702G: pixel, 702R: pixel, 702W: pixel, 703: pixel, 705: sealant, 720: functional layer, 770: base material, 770P: functional film, 771: insulating film, 951: substrate, 952: electrode, 953: insulating layer, 954: partition layer, 955: EL layer, 956: electrode, 1001: substrate, 1002: base insulating film, 1003: gate insulating film, 1006: gate electrode, 1007: gate electrode, 1008: gate electrode, 1020: first interlayer insulating film, 1021: second interlayer insulating film, 1022: electrode, 1024B: first electrode, 1024G: first electrode, 1024R: first electrode, 1024W: first electrode, 1025: partition, 1028: EL layer, 1029: second electrode, 1031: sealing substrate, 1032: sealant, 1033: base material, 1034B: coloring film, 1034G: coloring film, 1034R: coloring film, 1035: black matrix, 1036: overcoat layer, 1037: third interlayer insulating film, 1040: pixel portion, 1041: driver circuit portion, 1042: peripheral portion, 2001: housing, 2002: light source, 2100: robot, 2101: illuminance sensor, 2102: microphone, 2103: upper camera, 2104: speaker, 2105: display, 2106: lower camera, 2107: obstacle sensor, 2108: moving mechanism, 2110: arithmetic device, 3001: lighting device, 5000: housing, 5001: display portion, 5002: display portion, 5003: speaker, 5004: LED lamp, 5006: connection terminal, 5007: sensor, 5008: microphone, 5012: support, 5013: earphone, 5100: cleaning robot, 5101: display, 5102: camera, 5103: brush, 5104: operation button, 5120: dust, 5140: portable electronic device, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: display portion, 7401: housing, 7402: display portion, 7403: operation button, 7404: external connection port, 7405: speaker, 7406: microphone, 9310: portable information terminal, 9311: functional panel, 9313: hinge, 9315: housing.

1. A light-emitting device comprising:
a first electrode;
a second electrode;
a first unit; and
a first layer,
wherein the second electrode comprises a region overlapping with the first electrode,
wherein the first unit comprises a region positioned between the first electrode and the second electrode,
wherein the first unit comprises a second layer, a third layer, and a fourth layer,
wherein the second layer comprises a region positioned between the third layer and the fourth layer,
wherein the second layer comprises a light-emitting material,
wherein the third layer comprises a region positioned between the second layer and the second electrode,
wherein the third layer is in contact with the second layer,
wherein the third layer comprises a first material, and an organometallic complex of an alkali metal or an organometallic complex of an alkaline earth metal,
wherein the fourth layer comprises a region positioned between the first electrode and the second layer,
wherein the fourth layer comprises a second material,
wherein the first layer comprises a region positioned between the first electrode and the first unit,
wherein the first layer comprises the second material and a material having an electron acceptor property,
wherein the second material has a first refractive index,
wherein the first refractive index is higher than or equal to 1.5 and lower than or equal to 1.75 in a wavelength range of 455 nm to 465 nm inclusive,
wherein the second material has a first HOMO level, and
wherein the first HOMO level is higher than or equal to −5.7 eV and lower than or equal to −5.3 eV.

2. The light-emitting device according to claim 1,
wherein the fourth layer comprises a first region and a second region,
wherein the second region comprises a portion positioned between the second layer and the first region,
wherein the first region comprises the second material,
wherein the second region comprises a third material,
wherein the third material has a second HOMO level, and
wherein the second HOMO level differs from the first HOMO level by higher than or equal to −0.2 eV and lower than or equal to 0 eV.

3. The light-emitting device according to claim 1,
wherein the first material has a second refractive index, and
wherein the second refractive index is higher than or equal to 1.5 and lower than or equal to 1.75 in a wavelength range of 455 nm to 465 nm inclusive.

4. A light-emitting device comprising:
a first electrode;
a second electrode; and
a first unit,
wherein the second electrode comprises a region overlapping with the first electrode,
wherein the first unit comprises a region positioned between the first electrode and the second electrode,
wherein the first unit comprises a first layer, a second layer, and a third layer,
wherein the first layer comprises a region positioned between the second layer and the third layer,
wherein the first layer comprises a light-emitting material,
wherein the third layer comprises a region positioned between the first layer and the second electrode,
wherein the third layer is in contact with the first layer,
wherein the third layer comprises a first material, and an organometallic complex of an alkali metal or an organometallic complex of an alkaline earth metal,
wherein the first material has a second refractive index, and
wherein the second refractive index is higher than or equal to 1.5 and lower than or equal to 1.75 in a wavelength range of 455 nm to 465 nm inclusive.

5. The light-emitting device according to claim 1,
wherein the first material has an electron mobility higher than or equal to 1×10⁻⁷ cm²/Vs and lower than or equal to 5×10⁻⁵ cm²/Vs when a square root of an electric field strength [V/cm] is 600.

6. The light-emitting device according to claim 1, further comprising:
a second unit; and
an intermediate layer,
wherein the second unit comprises a region positioned between the intermediate layer and the second electrode,
wherein the intermediate layer comprises a region positioned between the first unit and the second unit, and
wherein the intermediate layer is configured to supply a hole to one of the first unit and the second unit and supply an electron to the other.

7. A functional panel comprising:
a pixel; and
a functional layer,
wherein the pixel comprises the light-emitting device according to claim 1, and a pixel circuit, and
wherein the functional layer comprises the pixel circuit.

8.-9. (canceled)

10. A light-emitting apparatus comprising:
the light-emitting device according to claim 1; and
at least one of a transistor and a substrate.

11. A display device comprising:
the light-emitting device according to claim 1; and
at least one of a transistor and a substrate.

12. A lighting device comprising:
the light-emitting apparatus according to claim 10; and
a housing.

13. An electronic device comprising:
the display device according to claim 11; and
at least one of a sensor, an operation button, a speaker, and a microphone.

14. The light-emitting device according to claim 4,
wherein the first material has an electron mobility higher than or equal to 1×10⁻⁷ cm²/Vs and lower than or equal to 5×10⁻⁵ cm²/Vs when a square root of an electric field strength [V/cm] is 600.

15. The light-emitting device according to claim 4, further comprising:
a second unit; and
an intermediate layer,
wherein the second unit comprises a region positioned between the intermediate layer and the second electrode,
wherein the intermediate layer comprises a region positioned between the first unit and the second unit, and
wherein the intermediate layer is configured to supply a hole to one of the first unit and the second unit and supply an electron to the other.

16. A functional panel comprising:
a pixel; and
a functional layer,
wherein the pixel comprises the light-emitting device according to claim 4, and a pixel circuit, and
wherein the functional layer comprises the pixel circuit.

17. A light-emitting apparatus comprising:
the light-emitting device according to claim 4; and
at least one of a transistor and a substrate.

18. A display device comprising:
the light-emitting device according to claim 4; and
at least one of a transistor and a substrate.

19. A lighting device comprising:
the light-emitting apparatus according to claim 17; and
a housing.

20. An electronic device comprising:
the display device according to claim 18; and
at least one of a sensor, an operation button, a speaker, and a microphone.
